(19) United States
(12) Patent Application Publication
(10) Pub. No.: US 2008/0290494 A1
(43) Pub. Date: Nov. 27, 2008

(54) Backside release and/or encapsulation of microelectromechanical structures and method of manufacturing same

(76) Inventors: Markus Lutz, Los Altos, CA (US); Aaron Partridge, Cupertino, CA (US); Paul Merritt Hagelin, Saratoga, CA (US)

Correspondence Address: NEIL STEINBERG, 2300 M STREET, N.W., Suite 800, WASHINGTON, DC, 20037, US

(21) Appl. No.: 11/804,912

(22) Filed: May 21, 2007

(51) Int. Cl. H01L 23/12; H01L 21/64

(52) U.S. Cl. 257/690; 438/127; 257/E23.125; 257/E21.502

(57) ABSTRACT

There are many inventions described and illustrated herein. In one aspect, the present inventions relate to devices, systems and/or methods of encapsulating and fabricating electromechanical structures or elements, for example, accelerometer, gyroscope or other transducer (for example, pressure sensor, strain sensor, tactile sensor, magnetic sensor and/or temperature sensor), filter or resonator. The fabricating or manufacturing microelectromechanical systems of the present invention, and the systems manufactured thereby, employ backside substrate release and/or seal or encapsulation techniques.

### BACKGROUND

There are many inventions described and illustrated herein. The inventions relate to seal, encapsulation and/or release of mechanical structures, for example, microelectromechanical and/or nanoelectromechanical structure (collectively hereinafter “microelectromechanical structures”) and devices/systems including same; and more particularly, in one aspect, the inventions relate to fabricating or manufacturing microelectromechanical systems having mechanical structures that are released and sealed using one or more backside release and seal techniques, and devices/systems incorporating same.

Microelectromechanical systems (for example, gyroscopes, resonators and accelerometers) utilize micromachining techniques (i.e., lithographic and other precision fabrication techniques) to reduce mechanical components to a scale that is generally comparable to microelectronics. Microelectromechanical systems typically include a mechanical structure fabricated from or on, for example, a silicon substrate using micromachining techniques.

The mechanical structures are typically formed, released and thereafter sealed in a chamber. The delicate mechanical structure may be sealed in, for example, a hermetically sealed metal or ceramic container or bonded to a semiconductor or glass-like substrate having a chamber to house, accommodate or cover the mechanical structure. In the context of the hermetically sealed metal or ceramic container, the substrate on, or in which, the mechanical structure resides may be disposed in and affixed to the metal or ceramic container. The hermetically sealed metal or ceramic container often also serves as a primary package as well.

In the context of the semiconductor or glass-like substrate packaging technique, the substrate of the mechanical structure may be bonded to another substrate (i.e., a “cover” wafer) whereby the bonded substrates form a chamber within which the mechanical structure resides. In this way, the operating environment of the mechanical structure may be controlled and the structure itself protected from, for example, inadvertent contact.

The mechanical structure may also be sealed in a chamber via thin film encapsulation techniques. In this regard, the mechanical structures are typically formed and a sacrificial layer is disposed in/on the structures. One or more thin film encapsulation layers are deposited on the sacrificial layer. The mechanical structures are thereafter released via removal of certain portions of the sacrificial layer through one or more of thin film encapsulation layers. Thereafter, the chamber is sealed via deposition of one or more layers on the thin film encapsulation layers. (See, for example, U.S. Pat. Nos. 6,936,491, 6,936,902 and 7,075,160).

### SUMMARY OF THE INVENTIONS

There are many inventions described and illustrated herein. The present inventions are neither limited to any single aspect nor embodiment thereof, nor to any combinations and/or permutations of such aspects and/or embodiments. Moreover, each of the aspects of the present inventions, and/or embodiments thereof, may be employed alone or in combination with one or more of the other aspects of the present inventions and/or embodiments thereof. For the sake of brevity, many of those permutations and combinations will not be discussed separately herein.

In one aspect, the present inventions are directed to a microelectromechanical device (for example, an accelerometer, a gyroscope or other transducer (for example, pressure sensor, strain sensor, tactile sensor, magnetic sensor and/or temperature sensor), a filter and/or a resonator) including a first substrate, a chamber, and a micromachined mechanical structure, wherein the micromachined mechanical structure is (i) disposed over the first substrate or (ii) formed from at least a portion of the first substrate, wherein at least a portion of the micromachined mechanical structure is partially disposed in the chamber. The microelectromechanical device further includes a cover, disposed over the micromachined mechanical structure and the first substrate, wherein a surface of the cover forms a wall of the chamber, one or more backside vents or holes, etched into the first substrate, wherein the one or more backside vents or holes provide (i) access to at least a portion of the micromachined mechanical structure and (ii) release thereof, and a seal material, disposed over or in the one or more backside vents or holes, to seal the chamber.

The seal material may include a plurality of layers of the same or different materials. For example, the seal material may include at least two layers of the plurality of layers comprising different materials.

The cover may be a second substrate which is physically coupled to the first substrate via bonding.

The microelectromechanical device of this aspect of the invention may further include a contact formed in the first substrate and/or the cover to electrically connect to a fixed electrode of the micromachined mechanical structure. Indeed, a trench may be formed or disposed in the first substrate and/or the cover (as the case may be) and around at least a portion of the contact. The trench may include an insulative material disposed therein.

The first substrate may be a semiconductor on insulator substrate having a semiconductor layer which is disposed on the insulator which is disposed on a base substrate; the micromachined mechanical structure may be formed from at least a portion of the semiconductor layer of the semiconductor on insulator.

In one embodiment, the microelectromechanical device may include a first sacrificial layer which is disposed on or above the micromachined mechanical structure. In this embodiment, the cover may be a second substrate which is physically coupled to the first sacrificial layer via bonding (for example, fusion bonding, anodic-like bonding, silicon direct bonding, soldering, thermo compression, thermo-sonic, laser bonding and/or glass reflow).

In another principal aspect, the present inventions are directed to a method of manufacturing a microelectromechanical device comprising a substrate. The method comprises forming a micromachined mechanical structure, wherein the micromachined mechanical structure is (i) disposed over the substrate or (ii) formed from at least a portion of the substrate, wherein at least a portion of the micromachined mechanical structure is partially disposed in the chamber. The method further includes providing a first sacrificial layer on the micromachined mechanical structure, providing a cover over the first sacrificial layer, forming one or more backside vents or holes in the substrate, and removing the first sacrificial layer through the one or more backside vents or holes to: (i) release at least a portion of the micromachined mechanical structure and (ii) form a chamber. The method also includes applying a sealing material (for example, one or more layers of the same or different materials), over or in the one or more backside vents or holes, to seal the chamber.

In one embodiment, the method further includes physically coupling, via bonding, the cover to the substrate. The bonding may include one or more of a fusion bonding, anodic-like bonding, silicon direct bonding, soldering, thermo compression, thermo-sonic, laser bonding and/or glass reflow bonding.

In another embodiment, the method may further include forming a contact in the substrate and/or the cover wherein the contact is electrically connected to a fixed electrode of the micromachined mechanical structure. The method of this embodiment may include forming a trench in the substrate and/or the cover (as the case may be) and around at least a portion of the contact. Indeed, an insulative material may be deposited in the trench.

The method may also include reducing the thickness of the substrate before and/or after forming one or more backside vents or holes in the substrate.

In one embodiment, the method includes providing a base sacrificial layer on the substrate and providing a semiconductor layer on the base sacrificial layer, wherein the micromachined mechanical structure is formed from at least a portion of the semiconductor layer. The method of this embodiment may include removing the base sacrificial layer through the one or more backside vents or holes to: (i) release at least a portion of the micromachined mechanical structure and (ii) form a chamber. Again, applying the seal material may include applying a plurality of layers, for example, at least two layers of different materials.

In another principal aspect, the present inventions are directed to a method of manufacturing a microelectromechanical device comprising a substrate and a base sacrificial layer which is a portion of the substrate or disposed on the substrate. The method includes forming a micromachined mechanical structure, wherein the micromachined mechanical structure is (i) disposed over the substrate or (ii) formed from at least a portion of the substrate, wherein at least a portion of the micromachined mechanical structure is disposed in the chamber and on the base sacrificial layer. The method further includes providing a cover over the micromachined mechanical structure, forming one or more backside vents or holes in the substrate, removing the base sacrificial layer through the one or more backside vents or holes to: (i) release at least a portion of the micromachined mechanical structure and (ii) form a chamber, and applying a sealing material (for example, one or more layers of the same or different materials), over or in the one or more backside vents or holes, to seal the chamber.

In one embodiment, the method further includes physically coupling, via bonding, the cover to the substrate. The bonding may include one or more of a fusion bonding, anodic-like bonding, silicon direct bonding, soldering, thermo compression, thermo-sonic, laser bonding and/or glass reflow bonding.

In another embodiment, the method may further include forming a contact in the substrate and/or the cover wherein the contact is electrically connected to a fixed electrode of the micromachined mechanical structure. The method of this embodiment may include forming a trench in the substrate and/or the cover (as the case may be) and around at least a portion of the contact. Indeed, an insulative material may be deposited in the trench.

In one embodiment, the method includes providing a base sacrificial layer on the substrate and providing a semiconductor layer on the base sacrificial layer, wherein the micromachined mechanical structure is formed from at least a portion of the semiconductor layer. The method of this embodiment may include removing the base sacrificial layer through the one or more backside vents or holes to: (i) release at least a portion of the micromachined mechanical structure and (ii) form a chamber. Again, applying the seal material may include applying a plurality of layers, for example, at least two layers of different materials.

The method may include reducing the thickness of the substrate before and/or after forming one or more backside vents or holes in the substrate.

In one embodiment, the method includes providing a first sacrificial layer on the micromachined mechanical structure. The method of this embodiment may include removing the first sacrificial layer through the one or more backside vents or holes to: (i) release at least a portion of the micromachined mechanical structure and (ii) form a chamber.

Again, there are many inventions, and aspects of the inventions, described and illustrated herein. This Summary of the Inventions is not exhaustive of the scope of the present inventions. Moreover, this Summary of the Inventions is not intended to be limiting of the inventions and should not be interpreted in that manner. While certain embodiments have been described and/or outlined in this Summary of the Inventions, it should be understood that the present inventions are not limited to such embodiments, description and/or outline, nor are the claims limited in such a manner. Indeed, many others embodiments, which may be different from and/or similar to, the embodiments presented in this Summary, will be apparent from the description, illustrations and claims, which follow. In addition, although various features, attributes and advantages have been described in this Summary of the Inventions and/or are apparent in light thereof, it should be understood that such features, attributes and advantages are not required whether in one, some or all of the embodiments of the present inventions and, indeed, need not be present in any of the embodiments of the present inventions.

### BRIEF DESCRIPTION OF THE DRAWINGS

In the course of the detailed description to follow, reference will be made to the attached drawings. These drawings show different aspects of the present inventions and, where appropriate, reference numerals illustrating like structures, components, materials and/or elements in different figures are labeled similarly. It is understood that various combinations of the structures, components, materials and/or elements, other than those specifically shown, are contemplated and are within the scope of the present inventions.

Moreover, there are many inventions described and illustrated herein. The present inventions are neither limited to any single aspect nor embodiment thereof, nor to any combinations and/or permutations of such aspects and/or embodiments. Moreover, each of the aspects of the present inventions, and/or embodiments thereof, may be employed alone or in combination with one or more of the other aspects of the present inventions and/or embodiments thereof. For the sake of brevity, many of those permutations and combinations will not be discussed or illustrated separately herein.

FIG. 1A is a block diagram representation of a mechanical structure disposed on a substrate and fabricated using one or more of the techniques described herein;

FIG. 1B is a block diagram representation of a mechanical structure and circuitry, each disposed on one or more substrates and fabricated using one or more of the techniques described herein;

FIG. 2 illustrates a top view of a portion of a mechanical structure of a conventional resonator, including moveable electrode, fixed electrode, and a contact;

FIG. 3 is a cross-sectional view (sectioned along dotted line A-A of FIG. 2) of a portion of the moveable electrode, fixed electrode, and the contact of FIG. 2 of an exemplary embodiment of the present inventions wherein the first substrate employs an SOI wafer;

FIGS. 4A-4M illustrate cross-sectional views (sectioned along dotted line A-A of FIG. 2) of the fabrication of the mechanical structure of FIGS. 2 and 3 at various stages of an exemplary process that employs release and encapsulation techniques according to certain aspects of the present inventions;

FIGS. 5A-5E illustrate cross-sectional views of a portion of the encapsulated backside vent or hole of the mechanical structure of FIGS. 2 and 3 of an exemplary process that employs release and encapsulation techniques according to an exemplary embodiment of certain aspects of the present inventions;

FIGS. 6A-6D illustrate cross-sectional views (sectioned along dotted line A-A of FIG. 2) of a portion of the fabrication of the mechanical structure of FIG. 2 disposed on or fabricated in/on a “bulk” type substrate at various stages of an exemplary process that employs release and encapsulation techniques according to an exemplary embodiment of certain aspects of the present inventions;

FIGS. 7A-7C illustrate cross-sectional views of the fabrication of the portion of the microelectromechanical system of FIG. 2 at various stages of an exemplary process that employs, among other things, release and encapsulation techniques according to an exemplary embodiment of certain aspects of the present inventions;

FIGS. 8A-8C illustrate cross-sectional views of the fabrication of the portion of the microelectromechanical system of FIG. 2 at various stages of an exemplary process that employs, among other things, release and encapsulation techniques according to an exemplary embodiment of certain aspects of the present inventions;

FIG. 9 illustrates a cross-sectional view (sectioned along dotted line A-A of FIG. 2) of a portion of the moveable electrode, fixed electrode, and the contact of FIG. 2, wherein microelectromechanical system includes electronic or electrical circuitry in conjunction with micromachined mechanical structure of FIG. 2, in accordance with an exemplary embodiment of the present inventions;

FIGS. 10A-10F illustrate cross-sectional views of the fabrication of the portion of the microelectromechanical system of FIG. 9 at various stages of an exemplary process that employs release and encapsulation techniques according to an exemplary embodiment of certain aspects of the present inventions;

FIG. 11 illustrates a cross-sectional view (sectioned along dotted line A-A of FIG. 2) of a portion of the moveable electrode, fixed electrode, and the contact of FIG. 2, wherein microelectromechanical system includes electronic or electrical circuitry in conjunction with micromachined mechanical structure of FIG. 2, in accordance with an exemplary embodiment of the present inventions;

FIGS. 12A-12M illustrate cross-sectional views of the fabrication of the portion of the microelectromechanical system of FIG. 11 at various stages of an exemplary process that employs release and encapsulation techniques according to an exemplary embodiment of certain aspects of the present inventions;

FIG. 13 illustrates a cross-sectional view (sectioned along dotted line A-A of FIG. 2) of a portion of the moveable electrode, fixed electrode, and the contact of FIG. 2, wherein microelectromechanical system includes electronic or electrical circuitry in conjunction with micromachined mechanical structure of FIG. 2, in accordance with an exemplary embodiment of the present inventions;

FIG. 14 illustrates a cross-sectional view (sectioned along dotted line A-A of FIG. 2) of a portion of the moveable electrode, fixed electrode, and the contact of FIG. 2, wherein the cover is bonded to a second portion of the microelectromechanical system, wherein in this embodiment is the substrate (including the micromachined mechanical structure), in accordance with an exemplary embodiment of the present inventions;

FIGS. 15A-15L illustrate cross-sectional views of the fabrication of the portion of the microelectromechanical system of FIG. 14 at various stages of an exemplary process that employs release and encapsulation techniques according to an exemplary embodiment of certain aspects of the present inventions;

FIGS. 16A-16C illustrate cross-sectional views (sectioned along dotted line A-A of FIG. 2) of a portion of the moveable electrode, fixed electrode, and the contact of FIG. 2, wherein the cover is to be bonded to a second portion of the microelectromechanical system and wherein the second substrate may include the contact (FIG. 16A), the contact, insulation layer and conductive layer (FIG. 16B), and the contact, insulation layer, conductive layer and passivation layer 38 (FIG. 16C), in accordance with exemplary embodiments of certain aspects of the present inventions;

FIG. 17 illustrates a cross-sectional view (sectioned along dotted line A-A of FIG. 2) of a portion of the moveable electrode, fixed electrode, and the contact of FIG. 2, wherein the cover is bonded to a second portion of the microelectromechanical system and wherein electronic or electrical circuitry (after fabrication) is formed in the second substrate, in accordance with an exemplary embodiment of certain aspects of the present inventions;

FIGS. 18A-18H illustrate cross-sectional views of the fabrication of the portion of the microelectromechanical system of FIG. 17 at various stages of an exemplary process that employs release and encapsulation techniques, according to certain aspects of the present inventions, in conjunction forming electronic or electrical circuitry in the second substrate in accordance with exemplary embodiment of the present inventions;

FIGS. 19A-19H illustrate cross-sectional views of the fabrication of the portion of the microelectromechanical system of FIG. 17 at various stages of an exemplary process that employs release and encapsulation techniques, according to certain aspects of the present inventions, in conjunction forming electronic or electrical circuitry in the second substrate in accordance with another exemplary embodiment of the present inventions;

FIGS. 20A-20F illustrate cross-sectional views of the fabrication of the portion of the microelectromechanical system of FIG. 17 at various stages of an exemplary process that employs release and encapsulation techniques, according to certain aspects of the present inventions, in conjunction forming electronic or electrical circuitry in the second substrate in accordance with another exemplary embodiment of the present inventions;

FIGS. 21A-21E illustrate cross-sectional views of the fabrication of the portion of the microelectromechanical system of FIG. 17 at various stages of an exemplary process that employs release and encapsulation techniques, according to certain aspects of the present inventions, in conjunction forming electronic or electrical circuitry in the second substrate in accordance with another exemplary embodiment of the present inventions;

FIG. 22 illustrates a cross-sectional view (sectioned along dotted line A-A of FIG. 2) of a portion of the moveable electrode, fixed electrode, and the contact of FIG. 2, wherein the microelectromechanical system includes a sealing screen layer to facilitate sealing the chamber in conjunction with wherein electronic or electrical circuitry, in accordance with an exemplary embodiment of certain aspects of the present inventions;

FIGS. 23A-23J illustrate cross-sectional views of the fabrication of the portion of the microelectromechanical system of FIG. 22 at various stages of an exemplary process that employs release and encapsulation techniques, according to an exemplary embodiment of certain aspects of the present inventions;

FIG. 24 illustrates a cross-sectional view (sectioned along dotted line A-A of FIG. 2) of a portion of the moveable electrode, fixed electrode, and the contact of FIG. 2, wherein the microelectromechanical system includes a sealing screen layer to facilitate sealing the chamber in conjunction with wherein electronic or electrical circuitry, in accordance with an exemplary embodiment of certain aspects of the present inventions;

FIGS. 25A-25H illustrate cross-sectional views of the fabrication of the portion of the microelectromechanical system of FIG. 24 at various stages of an exemplary process that employs release and encapsulation techniques, according to an exemplary embodiment of certain aspects of the present inventions;

FIGS. 26 and 29 illustrate cross-sectional views (sectioned along dotted line A-A of FIG. 2) of a portion of the moveable electrode, fixed electrode, and the contact of FIG. 2, wherein the microelectromechanical system includes an electrical contact in the first substrate layer, in accordance with exemplary embodiments of certain aspects of the present inventions;

FIGS. 27A-27G illustrate cross-sectional views of the fabrication of the portion of the microelectromechanical system of FIG. 2 at various stages of an exemplary process that employs release and encapsulation techniques, according to certain aspects of the present inventions, in conjunction with a electrical contact disposed in the first substrate layer which is formed therein before release of the micromachined mechanical structure and encapsulation of the chamber;

FIGS. 28A-28D illustrate cross-sectional views of the fabrication of the portion of the microelectromechanical system of FIG. 2 at various stages of an exemplary process that employs release and encapsulation techniques, according to certain aspects of the present inventions, in conjunction with a electrical contact disposed in the first substrate which is formed therein after release of the micromachined mechanical structure and encapsulation of the chamber;

FIGS. 30A-30D illustrate cross-sectional views (sectioned along dotted line A-A of FIG. 2) of a portion of the moveable electrode, fixed electrode, and the contact of the microelectromechanical system of FIG. 2, wherein the microelectromechanical system includes an internal electrical connection or wiring, in accordance with an exemplary embodiment of certain aspects of the present inventions;

FIGS. 31A-31C illustrate cross-sectional views of a portion of a microelectromechanical system, having one or more plurality of micromechanical structures, which are monolithically integrated on or within a device that is released and/or encapsulated in accordance with certain aspects of the present inventions wherein the cover is deposited, formed and/or grown on a substrate, or layers deposited thereon (see, FIGS. 31A and 31C) or fixed or secured as a substrate cover to a substrate, or layers deposited thereon (see, FIG. 31B);

FIG. 32A illustrates a cross-sectional view of a portion of a package (for example, a lead frame) having an adhesive material disposed thereon;

FIG. 32B illustrates a cross-sectional view of a portion of a microelectromechanical system, having a micromechanical structure, which is released, encapsulated and secured to the package of FIG. 32A, according to certain aspects of the present inventions;

FIG. 33A illustrates a cross-sectional view of a portion of a package (for example, a ball grid array) having an adhesive material disposed thereon;

FIG. 33B illustrates a cross-sectional view of a portion of a microelectromechanical system, having a micromechanical structure, which is released, encapsulated and secured to the package of FIG. 33A, according to certain aspects of the present inventions;

FIG. 34A illustrates a cross-sectional view of a portion of a package (for example, a ball grid array) having an adhesive material disposed thereon;

FIG. 34B illustrates a cross-sectional view of a portion of a microelectromechanical system, having a micromechanical structure, which is released, encapsulated and secured to the package of FIG. 34A, according to certain aspects of the present inventions;

FIG. 35A illustrates a cross-sectional view of a portion of a package (for example, a lead frame having an adhesive material disposed thereon;

FIG. 35B illustrates a cross-sectional view of a portion of a microelectromechanical system having a substrate cover that is fixed to the underlying substrate (or layer disposed thereon), wherein the micromechanical structure is released, encapsulated and secured to the package of FIG. 35A, according to certain aspects of the present inventions;

FIGS. 36 and 37A-37F are block diagram illustrations of various embodiments of the microelectromechanical systems of the present inventions wherein the microelectromechanical systems includes at least three substrates wherein one or more substrates include one or more micromachined mechanical structures and/or electronic or electrical circuitry, according to exemplary embodiments of certain aspects of the present inventions;

FIGS. 38A-38E illustrate cross-sectional views (sectioned along dotted line A-A of FIG. 2) of a portion of the moveable electrode, fixed electrode, and the contact of FIG. 2, wherein the cover is to be bonded to a first substrate (or one or more layers disposed thereon), in accordance with an exemplary embodiment of certain aspects of the present inventions;

FIG. 39 illustrates a cross-sectional view (sectioned along dotted line A-A of FIG. 2) of a portion of the moveable electrode, fixed electrode, and the contact of FIG. 2, wherein the microelectromechanical system, wherein the trenches are formed in the substrate to isolate the contact, in accordance with an exemplary embodiment of certain aspects of the present inventions; and

FIGS. 40A-40L illustrate cross-sectional views (sectioned along dotted line A-A of FIG. 2) of the fabrication of the mechanical structure of FIGS. 2 and 3 at various stages of an exemplary process that employs release and encapsulation techniques according to an exemplary embodiment of certain aspects of the present inventions.

### DETAILED DESCRIPTION

There are many inventions described and illustrated herein. In one aspect, the present inventions relate to devices, systems and/or methods of releasing, sealing and manufacturing electromechanical structures, for example, accelerometer, gyroscope or other transducer (for example, pressure sensor, strain sensor, tactile sensor, magnetic sensor and/or temperature sensor), filter or resonator. The fabricating or manufacturing microelectromechanical systems of the present invention, and the systems manufactured thereby, employ backside substrate release and/or seal or encapsulation techniques.

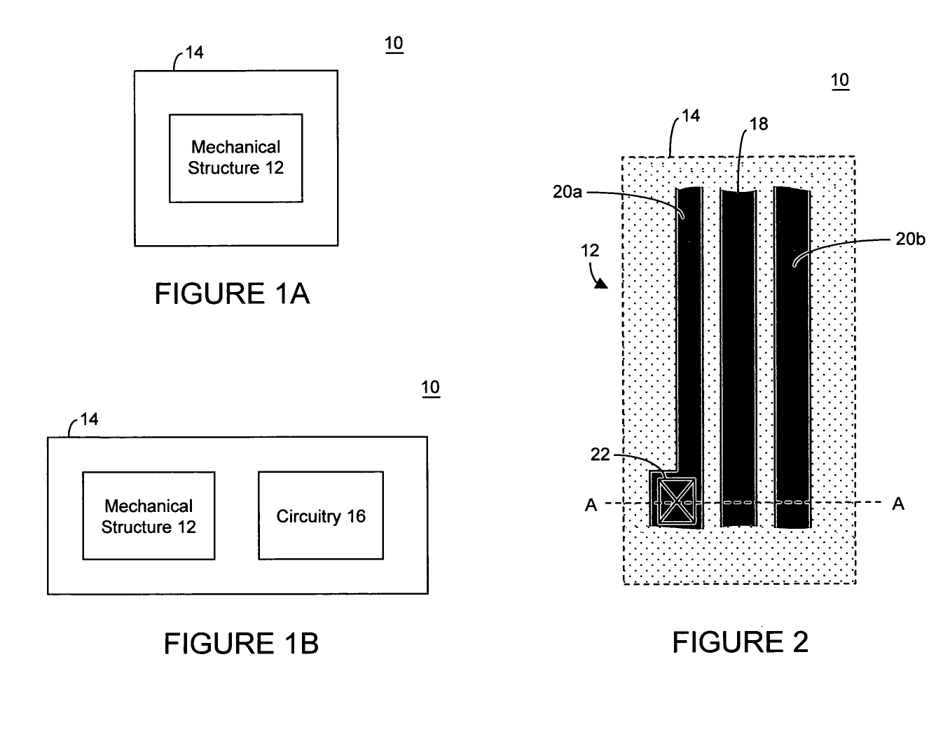

With reference to FIGS. 1A, 1B and 2, in one exemplary embodiment, microelectromechanical device 10 includes micromachined mechanical structure 12 that is disposed on substrate 14, for example, a semiconductor, glass, or insulator material. The microelectromechanical device 10 may include electronics or electrical circuitry 16 (hereinafter collectively “circuitry 16”) to, for example, drive mechanical structure 12, sense information from mechanical structure 12, process or analyze information generated by, and/or control or monitor the operation of micromachined mechanical structure 12. In addition, circuitry 16 (for example, CMOS circuitry) may generate output signals, for example, clock signals using, among other things, an output signal of micromachined mechanical structure 12, which may be a resonator type electromechanical structure. Under these circumstances, circuitry 16 may include frequency and/or phase compensation or adjustment circuitry (hereinafter “compensation circuitry”), which receives an output signal of the resonator and adjusts, compensates (for example, increases or decreases), corrects and/or controls the frequency and/or phase of the output signal. In this regard, compensation circuitry uses the output of resonator to provide an adjusted, corrected, compensated and/or controlled output signal having, for example, a desired, selected and/or predetermined frequency and/or phase. (See, for example, “Oscillator System Having a Plurality of Microelectromechanical Resonators and Method of Designing, Controlling or Operating Same”, application Ser. No. 11/399,176, filed Apr. 6, 2006, and “Temperature Measurement System Having a Plurality of Microelectromechanical Resonators and Method of Operating Same”, application Ser. No. 11/453,314, filed Jun. 14, 2006; the contents of both application are incorporated herein by reference).

Notably, circuitry 16 may include interface circuitry to provide information (from, for example, micromachined mechanical structure 12) to an external device (not illustrated), for example, a computer, controller, indicator/display and/or sensor.

With continued reference to FIGS. 1A, 1B and 2, micromachined mechanical structure 12 may include and/or be fabricated from, for example, materials in column IV of the periodic table, for example, silicon, germanium, carbon; also combinations of these, for example, silicon germanium, or silicon carbide; also of III-V compounds for example, gallium phosphide, aluminum gallium phosphide, or other III-V combinations; also combinations of III, IV, V, or VI materials, for example, silicon nitride, silicon oxide, aluminum carbide, or aluminum oxide; also metallic suicides, germanides, and carbides, for example, nickel silicide, cobalt silicide, tungsten carbide, or platinum germanium silicide; also doped variations including phosphorus, arsenic, antimony, boron, or aluminum doped silicon or germanium, carbon, or combinations like silicon germanium; The materials may include various crystal structures, including single crystalline, polycrystalline, nanocrystalline, or amorphous, or combinations thereof, for example, regions of single crystalline structure(s) and regions of polycrystalline structure(s) (whether doped or undoped).

As mentioned above, micromachined mechanical structure 12 illustrated in FIG. 2 may be a portion of an accelerometer, gyroscope or other transducer (for example, pressure sensor, strain sensor, tactile sensor, magnetic sensor and/or temperature sensor), filter and/or resonator. The micromachined mechanical structure 12 may also include mechanical structures of a plurality of transducers or sensors including one or more accelerometers, gyroscopes, pressure sensors, tactile sensors and temperature sensors. In the illustrated embodiment, micromachined mechanical structure 12 includes moveable electrode 18 and fixed electrodes 20a and 20b.

With continued reference to FIG. 2, micromachined mechanical structure 12 may also include contact 22 disposed on or in substrate 14. The contact 22 may provide an electrical path between micromachined mechanical structure 12 and circuitry 16 and/or an external device (not illustrated). The contact 22 may include and/or be fabricated from, for example, a semiconductor or conductive material, including, for example, silicon, (whether doped or undoped), germanium, silicon/germanium, silicon carbide, and gallium arsenide, and combinations and/or permutations thereof.

Notably, micromachined mechanical structure 12 and circuitry 16 may include a plurality of contacts 22. Such electrical contacts may be disposed on a top portion of device 10 and/or on a bottom portion (backside) of device 10 and provide a contact or connection point for electrical conductors. Indeed, electrical contacts may be configured to facilitate electrical connection between various elements via conductors disposed or embedded within device 10.

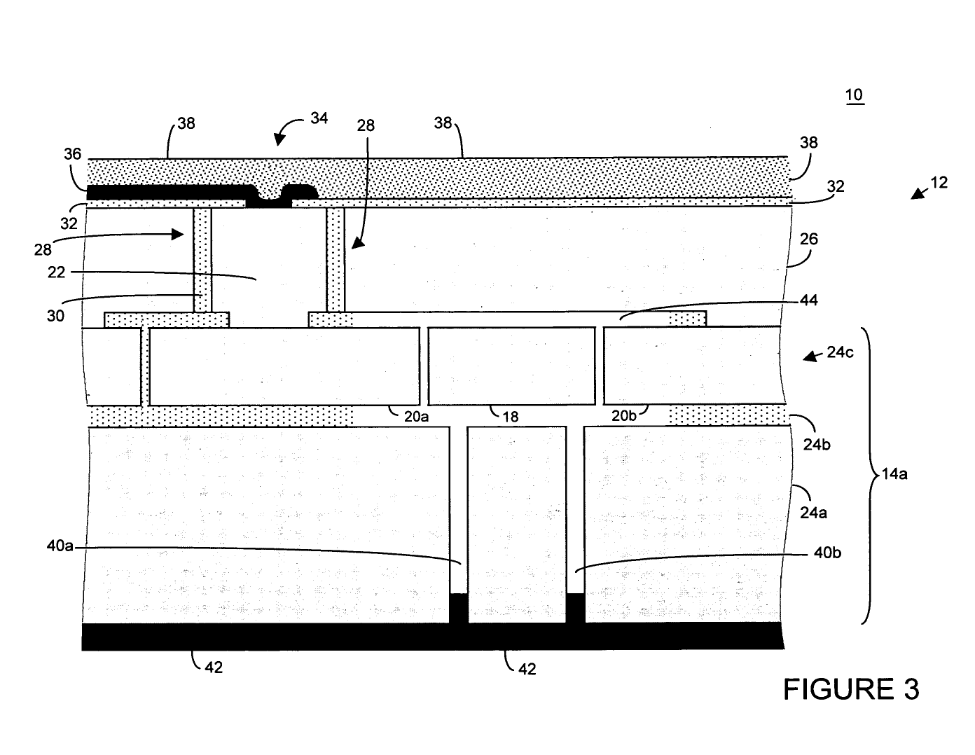

In one embodiment, the present inventions employ backside substrate release and encapsulation techniques to release micromachined mechanical structure 12 (for example, moveable electrode 18) and seal micromachined mechanical structure 12 in an operating chamber. For example, with reference to FIG. 3, in one embodiment, microelectromechanical system 10 includes semiconductor on insulator (“SOI”) substrate 14a, micromachined mechanical structure 12 wholly or partially disposed, fabricated and/or formed therein and/or thereon. The SOI substrate 14a includes substrate layer 24a, insulation or sacrificial layer 24b and semiconductor layer 24c. In this embodiment, a significant portion of micromachined mechanical structure 12, including moveable electrode 18 and fixed electrode 20, is disposed, fabricated and/or formed in semiconductor layer 24c of SOI substrate 14a.

The microelectromechanical system 10 of this embodiment further includes cover 26. The cover 26 may be, for example, fabricated using deposition, lithographic and/or other processing techniques on substrate 14a (or a layer disposed thereon). In another embodiment, cover 26 may be a substrate which is secured (for example, bonded) to exposed surface of substrate 14a (or a layer disposed thereon or affixed thereto). The cover 26 may be comprised of a semiconductor material (for example, materials in column IV of the periodic table, such as silicon, germanium, carbon, and/or combinations of these, for example, silicon germanium, or silicon carbide, and/or compounds of material in column III-V, for example, gallium phosphide, aluminum gallium phosphide, or other III-V combinations; also combinations of II, IV, V, or VI), or conductive material (for example, a metal).

In this embodiment, contact 22 is disposed, fabricated and/or formed in cover 26. In addition, in this embodiment, trenches 28 which may contain insulative material 30 (for example, a silicon dioxide or a silicon nitride) may provide electrical isolation and/or definition of contact 22 relative to other portions of cover 26.

The microelectromechanical system 10 may further include insulation layer 32 which is deposited, formed and/or grown on cover 26. The insulation layer 32 may include contact opening 34 formed or etched in insulation layer 32 to facilitate electrical contact/connection of conductive layer 36 (for example, a heavily doped polysilicon, metal (such as aluminum, chromium, gold, silver, molybdenum, platinum, palladium, tungsten, titanium, and/or copper), metal stacks, complex metals and/or complex metal stacks) may then be deposited (and/or formed) to contact 22.

A passivation layer 38 may be deposited, formed or grown on the exposed surfaces of conductive layer 36 and insulating layer 32 to protect an/or insulate microelectromechanical system 10. The passivation layer 38 may include one or more layers including, for example, polymers, a silicon dioxide and/or a silicon nitride. Indeed, passivation layer 38 may include a combination of silicon dioxide and a silicon nitride in a stack configuration; notably, all materials and deposition, formation or growth techniques, whether now known or later developed, are intended to be within the scope of the present inventions.

With continued reference to FIG. 3, microelectromechanical system 10 further includes backside vents or holes 40 to facilitate release of certain portions of micromachined mechanical structure 12 (for example, moveable electrode 18). After release of micromachined mechanical structure 12, one or more sealing materials 42 may be deposited, applied, formed and/or grown to seal or close chamber 44. The one or more sealing materials 42 may be deposited, applied, formed and/or grown (i) on first substrate layer 24a and/or (ii) over and/or in backside vents or holes 40.

The one or more sealing materials 42 may be any materials that may be deposited, applied, formed and/or grown (i) on first substrate layer 24a and/or (ii) over and/or in backside vents or holes 40 to seal chamber 44 including, for example, spin on layers (such as polymers), plasma deposited materials (such as oxides, nitrides, TEOS) and/or sputtered materials such as metals. The sealing material 42 may be a silicon-based material, for example, a monocrystalline silicon, polycrystalline silicon, amorphous silicon or porous polycrystalline silicon (whether doped or undoped), germanium, silicon/germanium, silicon carbide, and gallium arsenide (and combinations thereof. The silicon may be deposited using, for example, an epitaxial, a sputtering or a CVD-based reactor (for example, low pressure (“LP”) chemically vapor deposited (“CVD”) process (in a tube or EPI reactor) or plasma enhanced (“PE”) CVD process and sealing material 42 may be a doped polycrystalline silicon deposited using an atmospheric pressure (“AP”) CVD process). The deposition, formation and/or growth may be by a conformal process or non-conformal process.

The one or more sealing materials 42 may be the same as or different from the material comprising first substrate layer 24a. It may be advantageous, however, to employ the same material to, for example, closely “match” the thermal expansion rates of first substrate layer 24a and sealing material 42. This notwithstanding, all materials and deposition techniques for closing or sealing chamber 44, whether now known or later developed, are intended to be within the scope of the present inventions.

As noted above, the sealing material may include one or more materials and/or layers thereof. For example, the encapsulation or sealing process of the chamber may include two or more sealing materials and/or layers thereof. In this regard, a first sealing material may be deposited to partially or fully seal or close the backside vents or holes. Thereafter, a second sealing material may be deposited on the first sealing material to more fully seal or close backside vents or holes. In one exemplary embodiment, the second sealing material may be a semiconductor material (for example, silicon, silicon carbide, silicon-germanium or germanium) or metal bearing material (for example, suicides or TiW), which is deposited using, for example, an epitaxial, a sputtering or a CVD-based reactor (for example, APCVD, LPCVD or PECVD). The deposition, formation and/or growth may be by a conformal process or non-conformal process. Again, all materials and deposition techniques for sealing the chamber (via closing the backside vents or holes), whether now known or later developed, are intended to be within the scope of the present inventions.

Notably, the one or more sealing materials may be and/or include an adhesive (for example, a die attach material), a paste, a solder, a metal, for example, a material that facilitates mechanical or electrical connection of the microelectromechanical system to a frame (for example, lead frame) or substrate (for example, a circuit board or rigid platform).

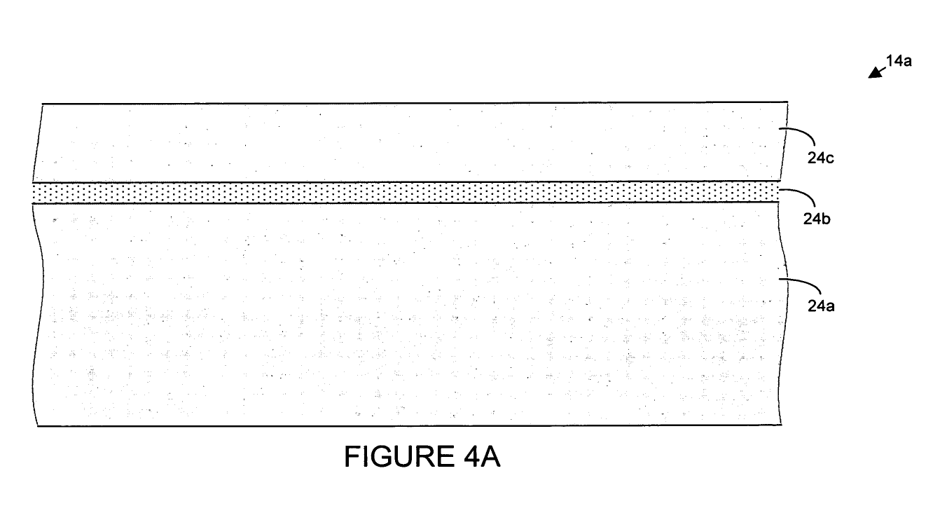

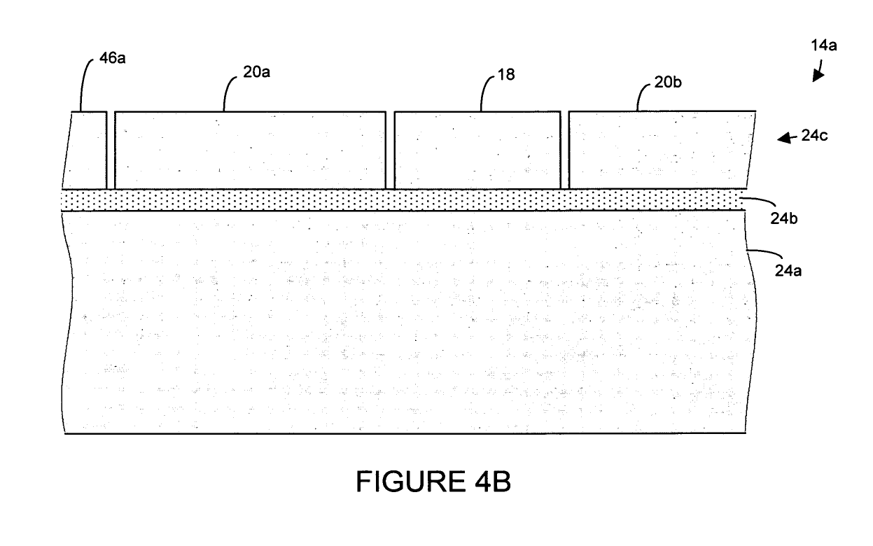

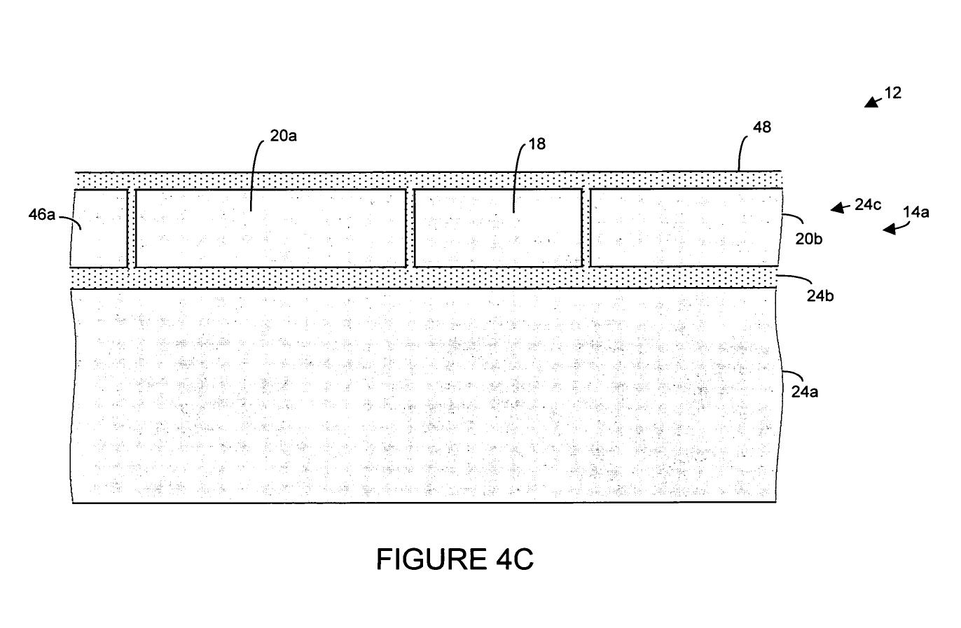

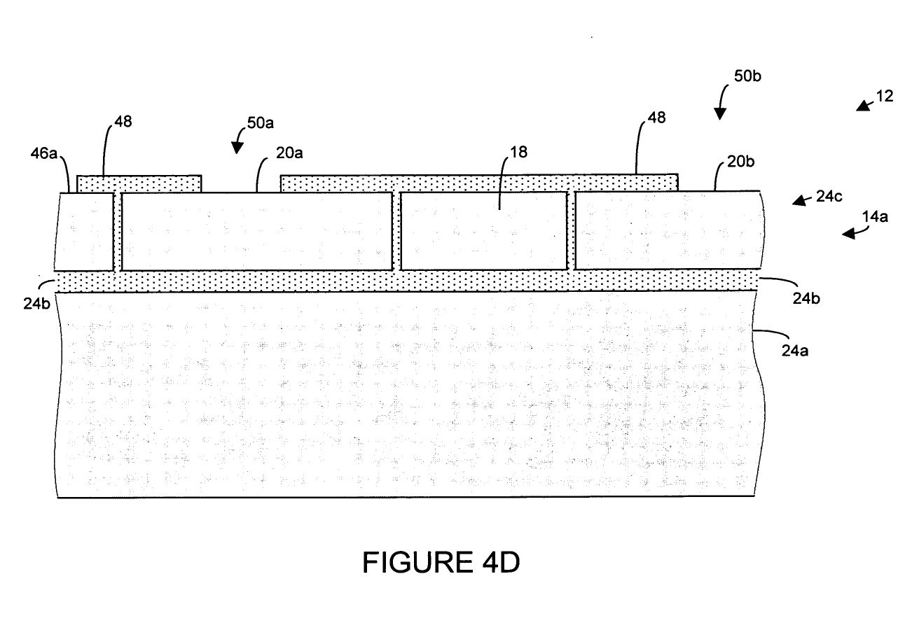

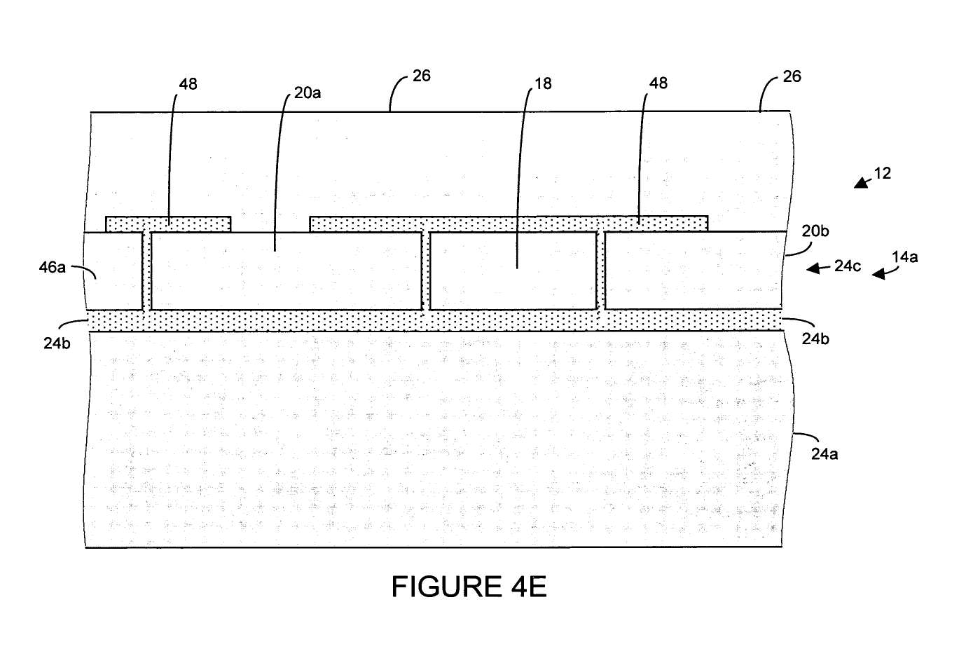

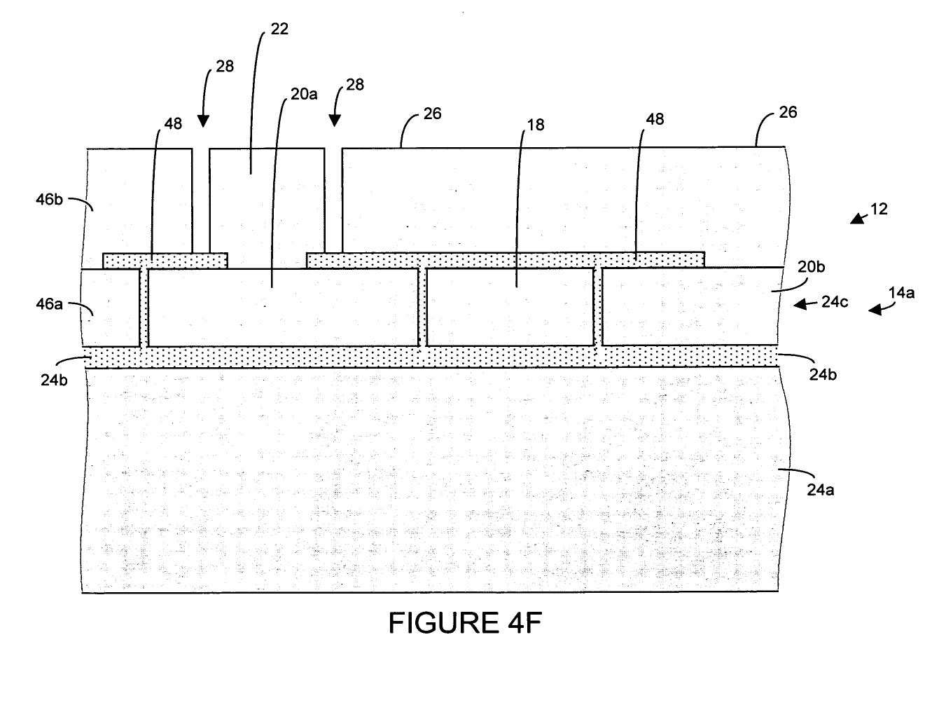

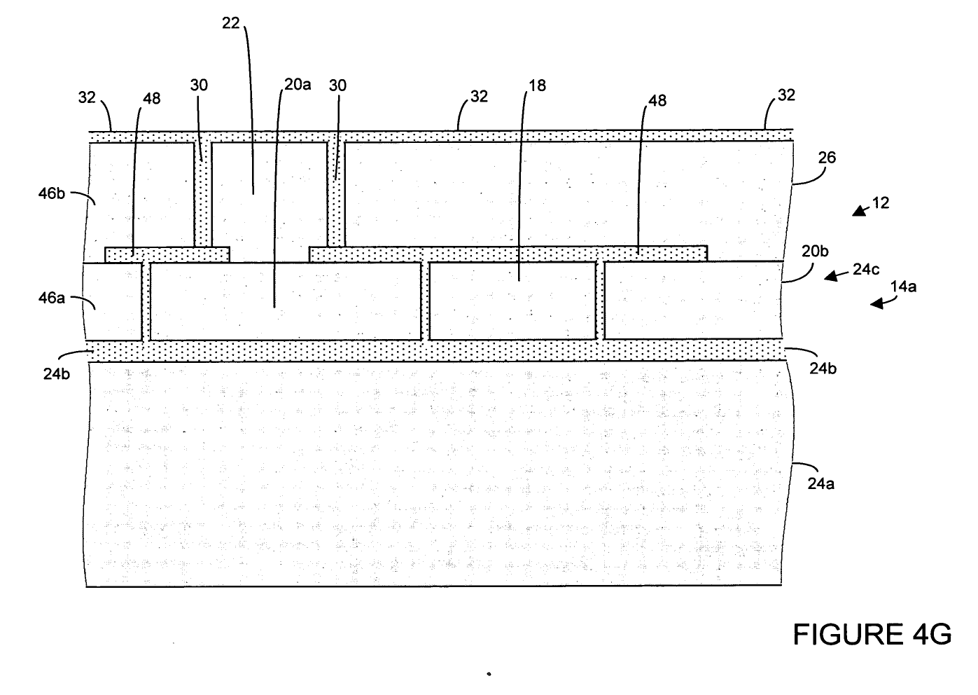

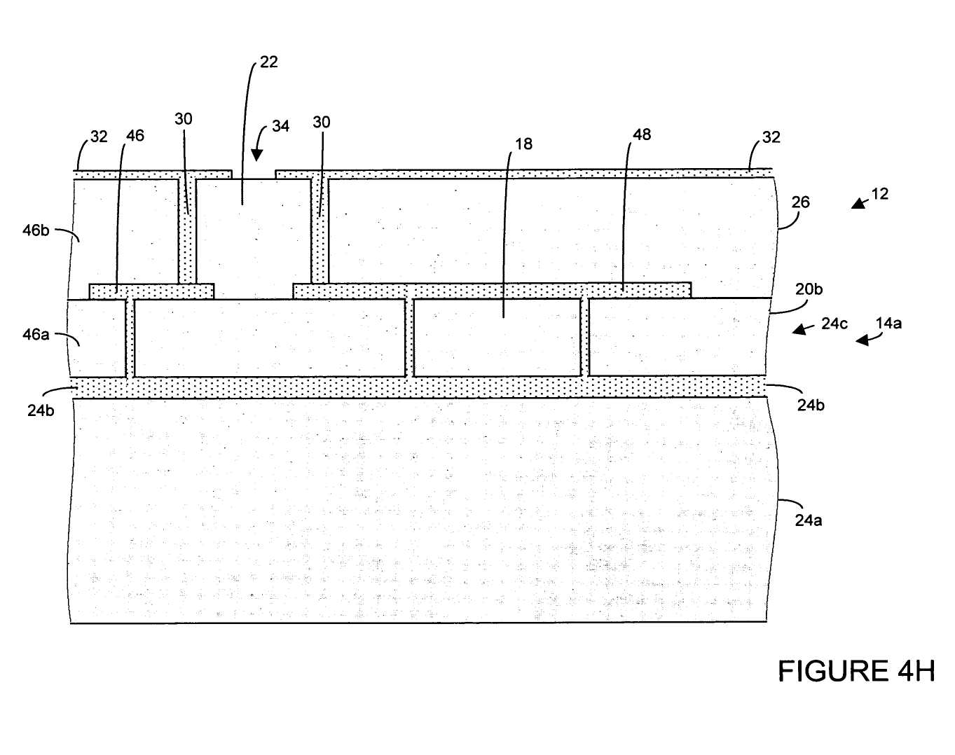

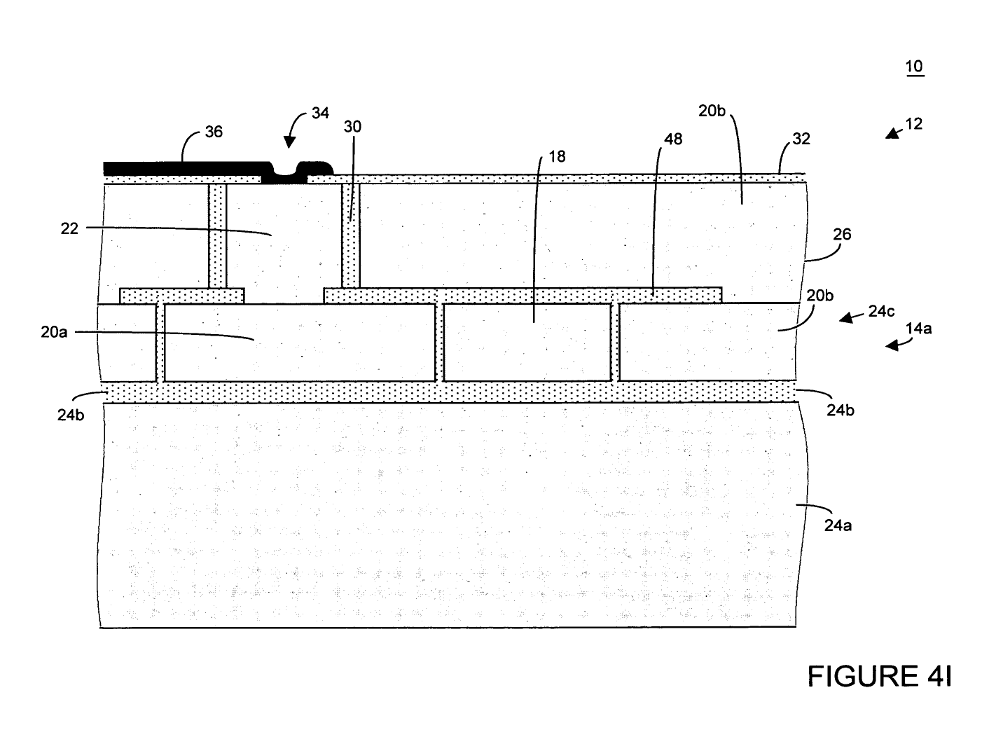

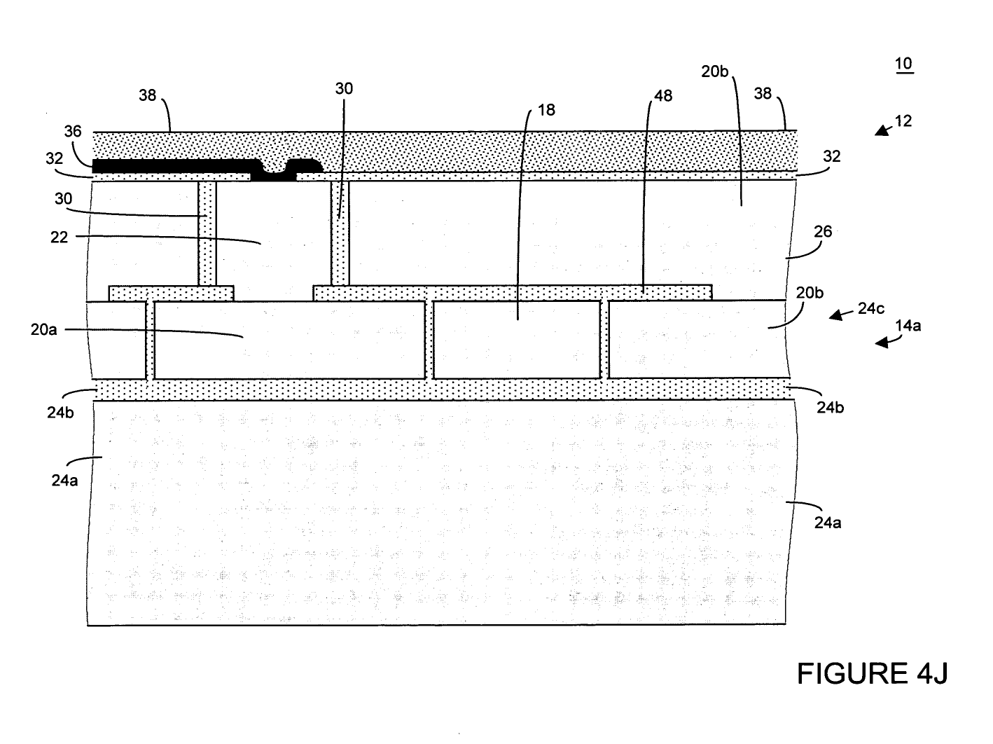

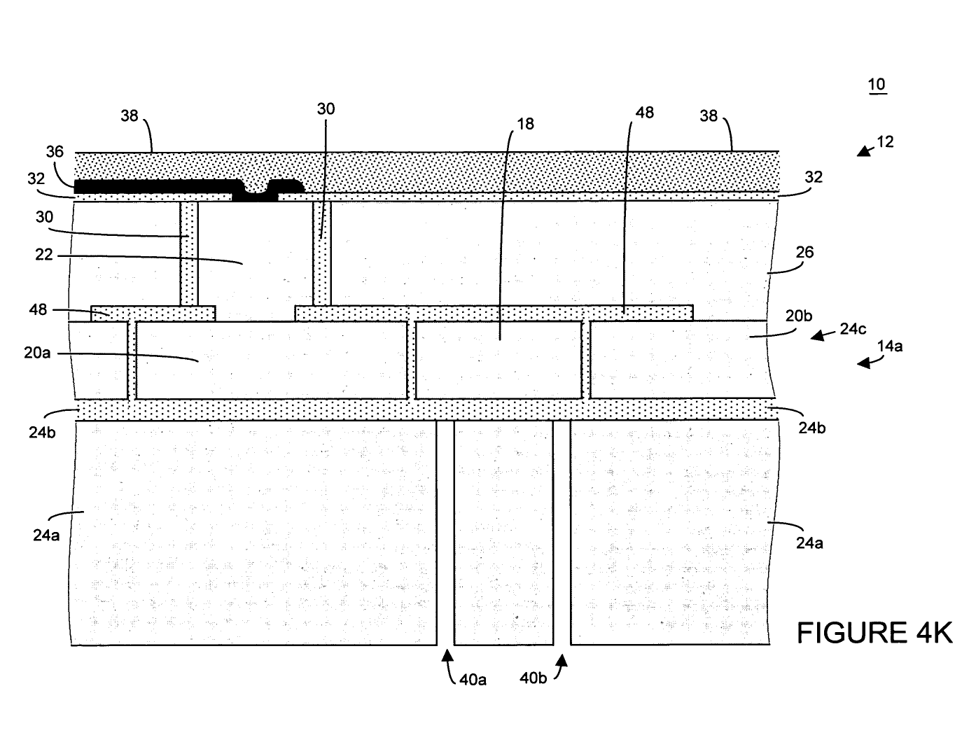

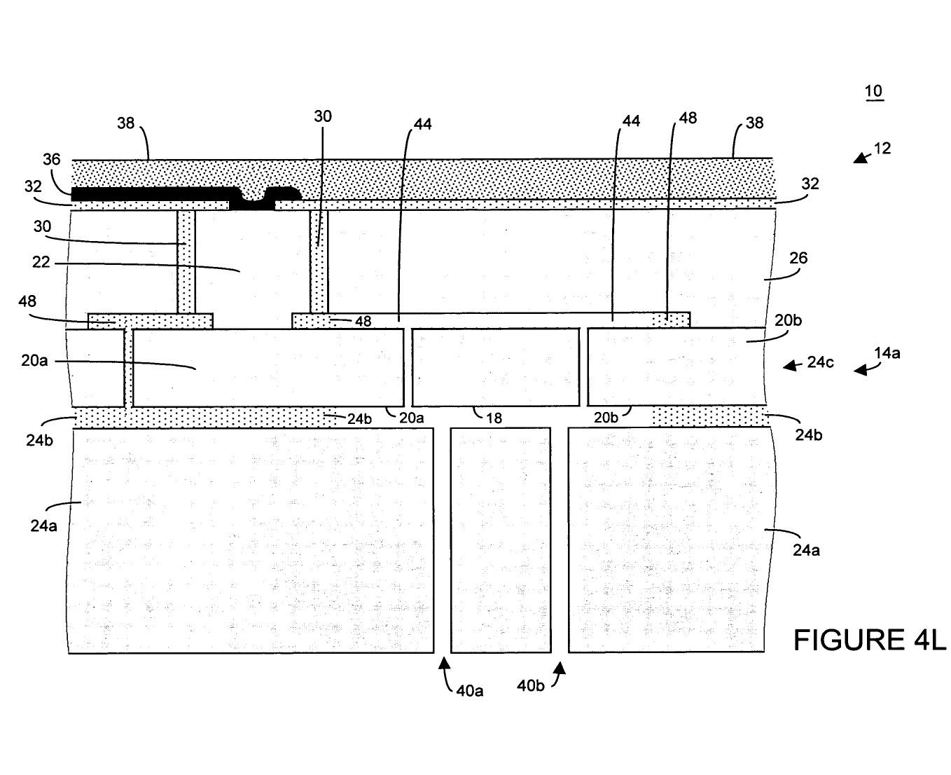

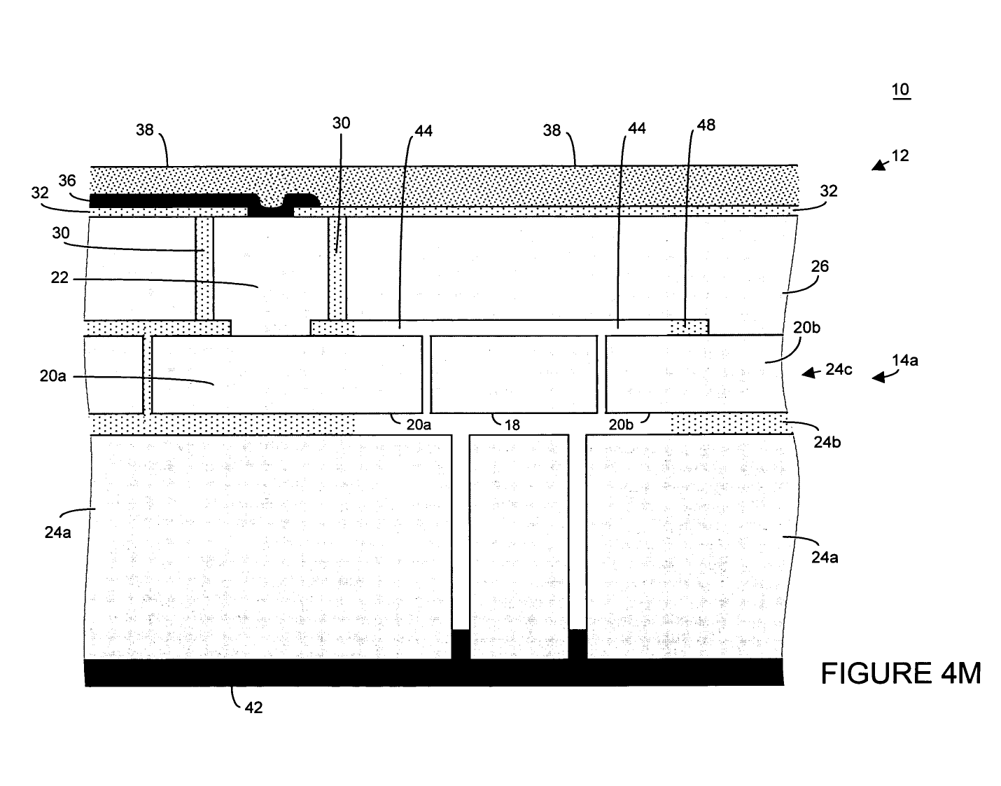

With reference to FIGS. 4A and 4B, an exemplary method of fabricating or manufacturing a micromachined mechanical structure 12 may begin with forming mechanical structures 12 in semiconductor layer 24c (for example, semiconductors such as silicon, germanium, silicon-germanium, gallium-arsenide or combinations thereof which is disposed on first sacrificial layer 24b (for example, a silicon dioxide or a silicon nitride material). The mechanical structures 12, including moveable electrode 18 and fixed electrodes 20a and 20b, may be formed in semiconductor layer 24c using well-known deposition, lithographic, etching and/or doping techniques as well as from well-known materials.

Moreover, field region 46 and first sacrificial layer 26a may be formed using well-known semiconductor-on-insulator fabrication techniques (FIG. 4A) or well-known formation, lithographic, etching and/or deposition techniques using a standard or over-sized (“thick”) wafer. Notably, mechanical structure 12 and field region 46a may be comprised of single or monocrystalline structures (for example, monocrystalline silicon), polycrystalline structures, or both monocrystalline and polycrystalline structures (for example, moveable electrode 18 and/or fixed electrodes 20a and 20b are formed from a polycrystalline material, such as polycrystalline silicon, and field region 46 formed from or include a single or monocrystalline material(s), such as, monocrystalline silicon. Indeed, all techniques, materials and crystal structures for providing a partially or fully formed mechanical structure 12, whether now known or later developed, are intended to be within the scope of the present inventions.

With reference to FIG. 4C, following formation of moveable electrode 18 and fixed electrodes 20a and 20b, second sacrificial layer 48 (for example, a silicon dioxide, a silicon nitride, and doped and undoped glass-like materials, such as a phosphosilicate (“PSG”) or a borophosphosilicate (“BPSG”)) and a spin on glass (“SOG”)) may be deposited and/or formed to secure, space and/or protect mechanical structures 20a-d during subsequent processing. In addition, openings 50a and 50b may be etched or formed into second sacrificial layer 48 to provide for electrical connection to electrical contact 22. (See, FIGS. 3 and 4D). The openings 50a and 50b may be provided using, for example, well-known masking techniques (such as a nitride mask) prior to and during deposition and/or formation of second sacrificial layer 48, and/or well-known lithographic and etching techniques after deposition and/or formation of second sacrificial layer 48.

With reference to FIG. 4E, one or more layers may be deposited, formed and/or grown on second sacrificial layer 48. The one or more layers may form cover 26. In one embodiment, the thickness of cover 26 in the region overlying second sacrificial layer 48 may be, for example, between 1 μm and 25 μm. The external environmental stress on, and internal stress of cover 26 after etching second sacrificial layer 48 (as discussed in detail below) may impact the thickness of cover 26. Slightly tensile films may self-support better than compressive films which may adversely change shape over time, for example, buckle.

The one or more layers of cover 26 may be comprised of one or more semiconductor materials (for example, materials in column IV of the periodic table, such as silicon, germanium, carbon, and/or combinations of these, for example, silicon germanium, or silicon carbide, and/or compounds of material in column III-V, for example, gallium phosphide, aluminum gallium phosphide, or other III-V combinations; also combinations of II, IV, V, or VI), conductive material (for example, a metal such as aluminum), combinations of II, IV, V, or VI materials (for example, aluminum carbide, or aluminum oxide), metallic silicides, germanides, and carbides (for example, nickel silicide, cobalt silicide, tungsten carbide, or platinum germanium silicide), doped variations of the above (for example, doped with phosphorus, arsenic, antimony, boron, or aluminum doped silicon or germanium, carbon, or combinations like silicon germanium). The one or more layers of cover 26 may include various crystal structures, including single crystalline, polycrystalline, nanocrystalline, or amorphous, or combinations thereof, for example, regions of single crystalline structure(s) and regions of polycrystalline structure(s) (whether doped or undoped).

The deposition, formation and/or growth of the one or more layers of cover 26 may be by a conformal process or non-conformal process. The material may be the same as or different from the material comprising semiconductor layer 24c.

Notably, it may be advantageous that cover 26 be comprised of a semiconductor material that facilitates fabrication of contact 22 therein as well as, in certain embodiments, integrated circuits. For example, in one embodiment, cover 26 may be comprised of silicon (which may be doped to enhance conductivity and/or to enhance electrical isolation from surrounding or neighboring portions of cover 26). In this way, a portion of cover 26 which is disposed in opening 50a and disposed on fixed electrode 20a (i.e., contact 22) may provide sufficient or suitable electrical connection to fixed electrode 20a.

In addition, the portion of cover 26 which is disposed on field region 46 may provide an area of microelectromechanical system 10 in which high performance integrated circuits may be fabricated or disposed therein. In this regard, to facilitate integration of high performance integrated circuits in or on the substrate including micromachined mechanical structure 12, it may be advantageous to include field region 46b which is comprised of monocrystalline silicon in or on which such integrated circuits may be fabricated. The monocrystalline silicon may be deposited and/or may be recrystallized thereby “converting” or re-arranging the crystal structure of the polycrystalline material to that of a monocrystalline or substantially monocrystalline material. (See, for example, FIG. 4F). In this way, as discussed in detail below, transistors or other active components of, for example, data processing electronics 16 may be integrated in/on field regions 46b of a common substrate with micromachined mechanical structure 12 of microelectromechanical system 10.

With reference to FIG. 4F, in this exemplary embodiment, trenches 28 may be formed in cover 26, using, for example, well-known lithographic and etching techniques. Thereafter, insulating material 30 may be deposited and/or grown in trenches 28. (See, FIG. 4G). In this way, contact 22 may be electrically isolated from surrounding or neighboring portions of cover 26.

Notably, trench 28 may include a slight taper in order to facilitate deposition or formation of insulating material 30 in trench 28. In this regard, insulating material 30 may be deposited in trench 28 to form electrical isolation regions. The insulating material may be any material that electrically isolates contact 22 from surrounding or neighboring portions of cover 26, for example, a silicon dioxide, a silicon nitride, a BPSG, a PSG, or an SOG. It may be advantageous to employ silicon nitride because silicon nitride may be deposited in a conformal manner. Moreover, silicon nitride is compatible with integrated circuit processing, in the event that microelectromechanical system 10 includes integrated circuits.

Notably, it may also be advantageous to employ multiple materials and/or layers to provide insulating material 30 in trench 28, for example, silicon dioxide and silicon nitride or silicon dioxide and silicon. In this way, suitable dielectric isolation is provided in view of manufacturability considerations.

After formation of isolation regions in cover 26 to form contact 22, it may be advantageous to substantially planarize micromachined mechanical structure 12 to provide a relatively “smooth” surface layer and/or (substantially) planar surface using, for example, polishing techniques (for example, chemical mechanical polishing (“CMP”). In this way, the exposed planar surface of micromachined mechanical structure 12 may be a better prepared base upon which integrated circuits (for example, CMOS transistors) and/or micromachined mechanical structure 12 may be fabricated on or in using well-known fabrication techniques and equipment.

Thereafter, insulating material 32 may be deposited, grown or formed (FIG. 4G), window 34 formed therein (FIG. 4H), and conductive material 36 (for example, a low electrical resistance material, such as a metal) may then be deposited and/or formed to provide electrical connection to contact 24 (FIG. 4I).

Notably, the isolation regions in cover 26 may be formed or completed while processing the “back-end” of the integrated circuit fabrication of microelectromechanical system 10. In this regard, with reference to FIG. 4G, during deposition, formation and/or growth of insulating material 32, trenches 28 may also be fully or partially filled with insulative material 30 to form the isolation regions in cover 26. Thereafter, opening 34 may be etched to facilitate electrical connection to contact 22 and fixed electrode 20a (see, FIG. 4H). Thus, in this embodiment, the processing pertaining to formation of isolation regions in cover 26 may be “combined” with the insulating and contact formation step of the “back-end” of the integrated circuit fabrication (if any) and/or microelectromechanical system 10. In this way, fabrication time and costs may be reduced.

With reference to FIG. 4J, passivation layer 38 may then be deposited, grown or formed. The passivation layer 38 may be any material that protects the upper surface of microelectromechanical system 10, including, for example, spin on layers (such as polymers) and/or plasma deposited materials (such as a silicon dioxide and/or a silicon nitride). All materials and deposition techniques for sealing and/or protecting the upper surface of microelectromechanical system 10, whether now known or later developed, are intended to be within the scope of the present inventions. Notably, the passivation layer 38 may include more than one material and/or layer. For example, passivation layer 38 may include two materials and/or layers, including a layer of silicon oxide and a layer of silicon nitride.

With reference to FIG. 4K, in this embodiment, mechanical structure 12 (for example, moveable electrode 18) is “released” by first etching backside vents or holes 40a and 40b in first substrate layer 24a. In one exemplary embodiment, backside vents or holes 40a and 40b have a diameter or aperture size of between 0.1 μm to 10 μm, and preferably between 1 μm and 5 μm. Notably, all techniques for forming or fabricating vents or holes 40a and 40b, whether now known or later developed, are intended to be within the scope of the present inventions.

The backside vents or holes 40a and 40b facilitate etching and/or removal of at least selected portions of sacrificial layers 24b and 48, respectively, (see, FIG. 4L) and formation of chamber 44. For example, in one embodiment, where sacrificial layers 24b and 48 are comprised of a silicon dioxide, selected portions of layers 24b and 48 may be removed/etched using well-known wet etching techniques and buffered HF mixtures (i.e., a buffered oxide etch) or well-known vapor etching techniques using vapor HF. Proper design of aspects of mechanical structure 12 (for example, moveable electrode 18) and sacrificial layers 24b and 48, and control of the HF etching process parameters facilitates etching of all or substantially all of layers 24b and 48 around or neighboring certain features of mechanical structure 12 (for example, moveable electrode 18 and portions of fixed electrodes 20a and 20b) to permit proper operation of microelectromechanical system 10.

In another embodiment, where sacrificial layers 24b and 48, respectively, are comprised of silicon nitride, selected portions of layers 24b and 48 may be removed/etched using phosphoric acid. Again, proper design of mechanical structure 12 and sacrificial layers 24b and 48, and control of the wet etching process parameters may permit portions of sacrificial layers 24b and 48 to be etched to remove all or substantially all of sacrificial layers 24b and 48 around moveable electrode 18 and portions of fixed electrodes 20a and 20b.

It should be noted that there are (1) many suitable materials for layers 24b and/or 48 (for example, silicon dioxide, silicon nitride, and doped and undoped glass-like materials, such as a PSG, a BPSG″, and an SOG), (2) many suitable/associated etchants (for example, a buffered oxide etch, phosphoric acid, and alkali hydroxides such as, for example, NaOH and KOH), and (3) many suitable etching or removal techniques (for example, wet, plasma, vapor or dry etching), to eliminate, remove and/or etch sacrificial layers 24b and/or 48. Indeed, layers 24b and/or 48 may be a doped or undoped semiconductor (for example, polycrystalline silicon, silicon/germanium or germanium), for example, in those instances where mechanical structure 12 is the same or similar semiconductor (i.e., processed, etched or removed similarly) provided that mechanical structure 12 is not adversely affected by the etching or removal processes (for example, where structure 12 is “protected” during the etch or removal process (for example, an oxide layer protecting a silicon based structures 18, 20a and 20b) or where structure 12 is comprised of a material that is adversely affected by the etching or removal process of layers 24b and/or 48). Accordingly, all materials, etchants and etch techniques, and permutations thereof, for eliminating, removing and/or etching, whether now known or later developed, are intended to be within the scope of the present inventions.

Notably, fixed electrode 20a and/or 20b may remain partially, substantially or entirely surrounded by sacrificial layers 24b and/or 48. For example, with reference to FIG. 4L, while moveable electrode 18 is released from its respective underlying sacrificial layers 24b and/or 48 beneath or underlying structures 20a and 20b may provide additional physical support.

With reference to FIG. 4M, after releasing mechanical structure 12 (for example, moveable electrode 18), sealing materials 42 may be deposited, applied, formed and/or grown to seal or close chamber 44. The one or more sealing materials 42 may be deposited, applied, formed and/or grown (i) on first substrate material 24a and/or (ii) over and/or in backside vents or holes 40. The sealing materials 42 may be deposited, applied, formed and/or grown in a conformal or non-conformal manner.

As noted above, sealing material 42 may be any material that may be deposited, applied, formed and/or grown (i) on first substrate material 24a and/or (ii) over and/or in backside vents or holes 40 to seal chamber 44 including, for example, spin on materials such as polymers, plasma deposited materials such as a silicon oxide, a silicon nitride, a PSG, a BPSG, an SOG and/or TEOS. The one or more sealing materials 42 may be and/or include an adhesive (for example, a die attach material), a paste, a solder, a metal, and/or a material that facilitates mechanical or electrical connection of system 10 to a package (for example, lead frame) or a substrate (for example, a circuit board or rigid platform).

Further, the one or more sealing materials 42 may be a semiconductor material, for example, a monocrystalline silicon, polycrystalline silicon, amorphous silicon or porous polycrystalline silicon (whether doped or undoped), germanium, silicon/germanium, silicon carbide, and/or gallium arsenide (and combinations thereof. The semiconductor may be deposited using, for example, an epitaxial, a sputtering or a CVD-based process (for example, LP, PE or AP type CVD). The deposition, formation and/or growth may be a conformal process or non-conformal process. The material may be the same as or different from first substrate layer 24a. However, it may be advantageous to employ the same material to, for example, closely “match” the thermal expansion rates of first substrate layer 24a and sealing material 42. Notably, all materials and deposition, growth, application and/or formation techniques for encapsulating or sealing chamber 44, whether now known or later developed, are intended to be within the scope of the present inventions.

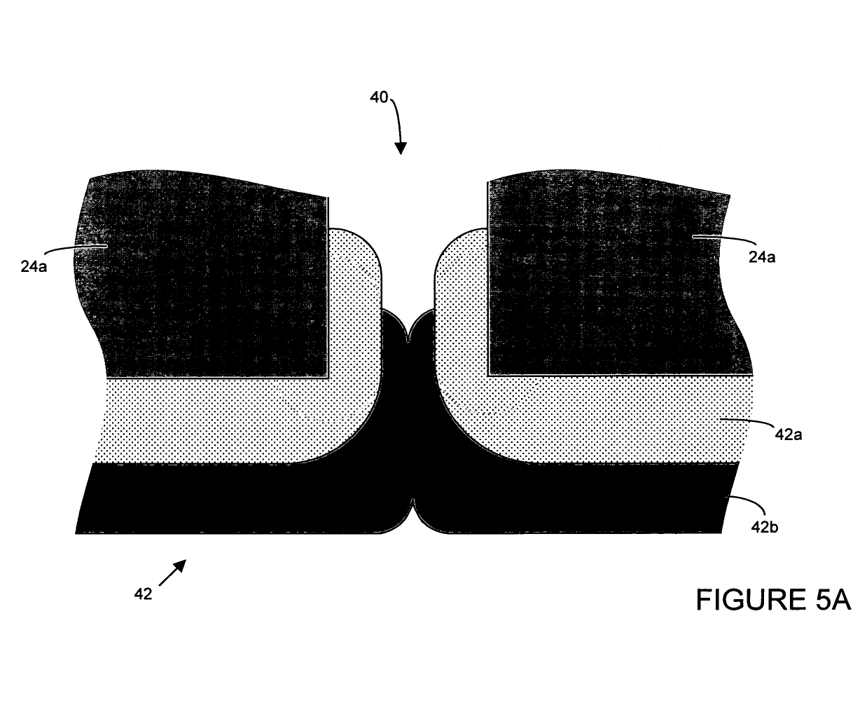

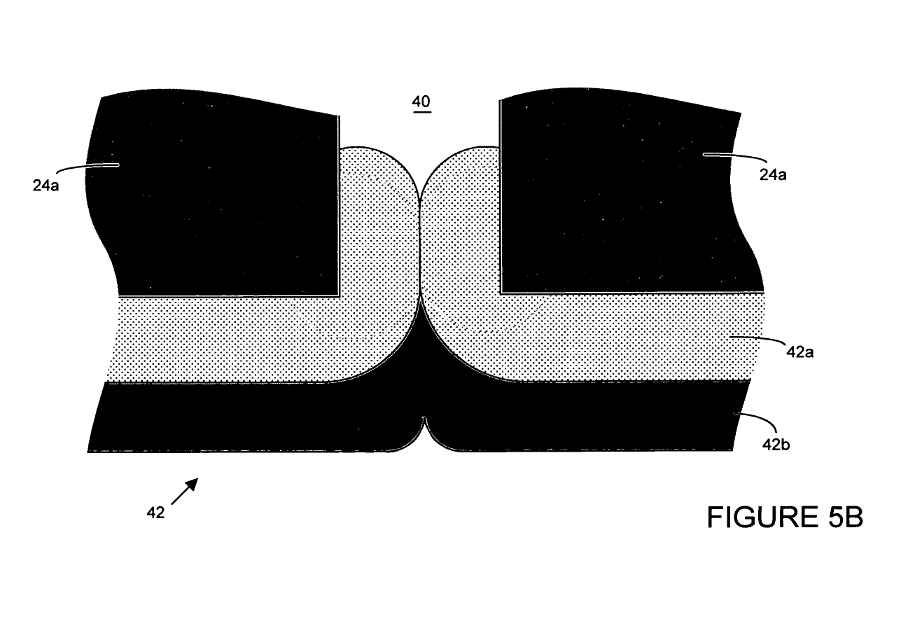

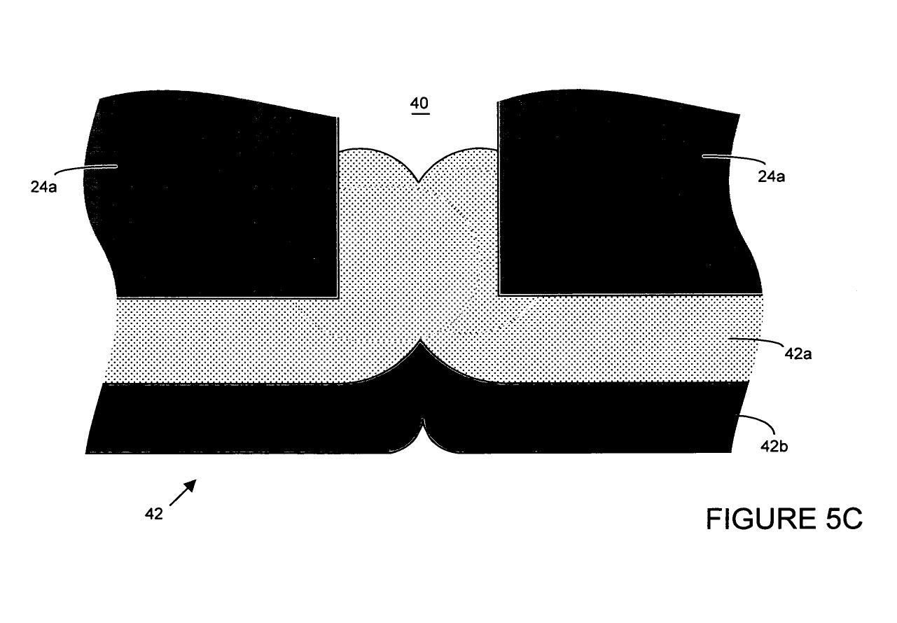

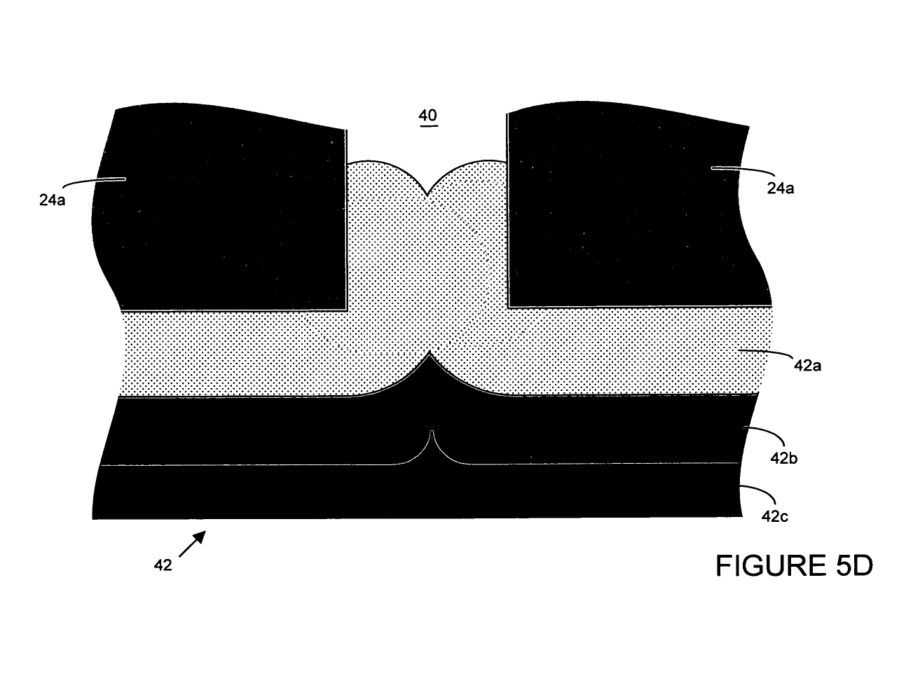

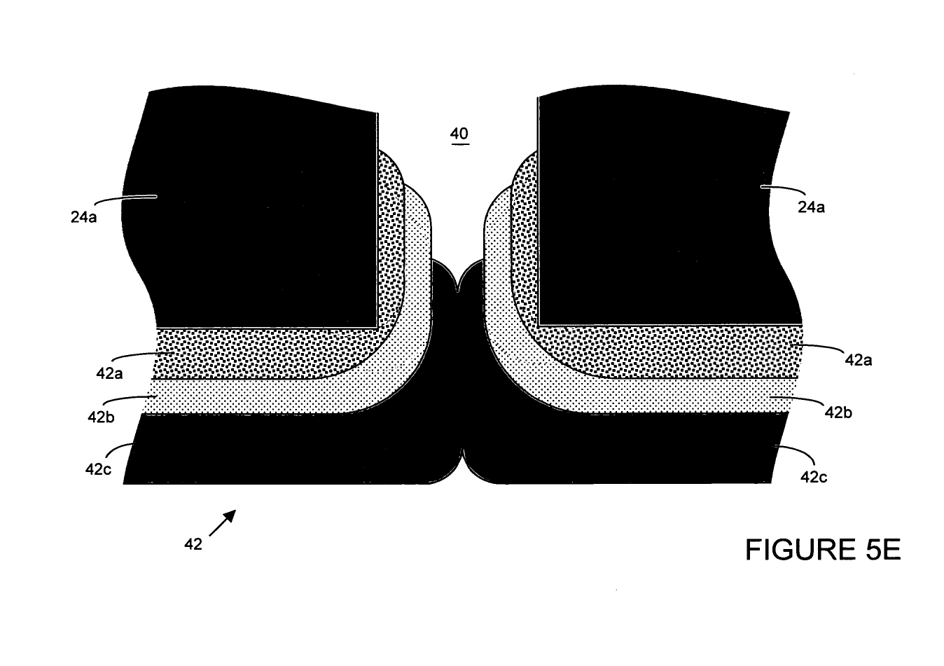

The sealing material 42 may include one or more materials and/or layers thereof. For example, the encapsulation or sealing process of chamber 44 may include two or more sealing materials of the same or different materials. In this regard, a first sealing material may be deposited to partially or fully seal or close backside vents or holes 40. Thereafter, a second sealing material may be deposited on the first sealing material to more fully seal or close backside vents or holes 40. (See, for example, FIGS. 5A-5C). In one exemplary embodiment, the second sealing material may be a semiconductor material (for example, silicon, silicon carbide, silicon-germanium or germanium) or metal bearing material (for example, silicides or TiW), which is deposited using, for example, an epitaxial, a sputtering or a CVD-based reactor (for example, APCVD, LPCVD or PECVD). The deposition, formation and/or growth may be by a conformal process or non-conformal process. Notably, more than two materials may be employed to seal or close backside vents or holes 40. (See, for example, FIGS. 5D and 5E). Again, all materials and techniques of sealing material 42 to encapsulate or seal chamber 44, whether now known or later developed, are intended to be within the scope of the present inventions.

In conjunction with encapsulating or sealing chamber 44, the atmosphere (including its characteristics) in which moveable electrode 18 operates may also be defined while encapsulating or sealing chamber 44 or thereafter. In this regard, the atmosphere in chamber 44 may be defined when one or more sealing materials 42 are deposited, applied, formed and/or grown (i) on first substrate material 24a and/or (ii) over and/or in backside vents or holes 40, or after further processing (for example, an annealing step may be employed to adjust the pressure). Notably, all techniques of defining the atmosphere, including the pressure thereof, during the process of encapsulating or sealing chamber 44, whether now known or later developed, are intended to be within the scope of the present inventions.

For example, sealing materials 42 are deposited, applied, formed and/or grown in a nitrogen, oxygen and/or inert gas environment (for example, helium). The pressure of the fluid (gas or vapor) may be selected, defined and/or controlled to provide a suitable and/or predetermined pressure of the fluid in chamber 44 immediately after encapsulating or sealing chamber 44, after one or more subsequent processing steps (for example, an annealing step), and/or after completion of micromachined mechanical structure 12 and/or microelectromechanical system 10.

Notably, the gas(es) employed during these processes may provide predetermined reactions (for example, oxygen molecules may react with silicon to provide a silicon oxide); all such techniques, gasses and/or materials are intended to fall within the scope of the present inventions. Moreover, gases (for example, organic-type gases) or other materials may be included or incorporated to provide an anti-stiction layer (for example, a monolayer or self-assembled layer) on certain portions of the mechanical structure (for example, the moveable structures or fixed structures adjacent the moveable structures. In one embodiment, such gases or other materials are capable of maintaining a predetermined form and/or suitable integrity to provide anti-stiction quality or characteristics notwithstanding further processing (for example, processing that includes significantly high temperatures).

As mentioned above, micromachined mechanical structure 12 may be fabricated on or using many different types of substrates comprised of many different types of materials. For example, micromachined mechanical structure 12 may be fabricated using a semiconductor on insulator type substrate (see, for example, substrate 14a of FIGS. 4A-M) or a bulk-type substrate. Briefly, as described above, micromachined mechanical structure 12 may be formed in or on SOI substrate 14a. The SOI substrate 14a may include first substrate layer 24a (for example, a semiconductor (such as silicon), glass or sapphire), insulation layer 24b (for example, a silicon dioxide or silicon nitride layer) and first semiconductor layer 24c (for example, a materials in column IV of the periodic table, for example, silicon, germanium, carbon, as well as combinations of such materials, for example, silicon germanium, or silicon carbide).

In one embodiment, SOI substrate 14a is a SIMOX wafer. Where SOI substrate 36 is a SIMOX wafer, such wafer may be fabricated using well-known techniques including those disclosed, mentioned or referenced in U.S. Pat. Nos. 5,053,627; 5,080,730; 5,196,355; 5,288,650; 6,248,642; 6,417,078; 6,423,975; and 6,433,342 and U.S. Published Patent Applications 2002/0081824 and 2002/0123211, the contents of which are hereby incorporated by reference.

In another embodiment, SOI substrate 14a may be a conventional SOI wafer having a relatively thin semiconductor layer 24c. In this regard, SOI substrate 14a having a relatively thin semiconductor layer 24c may be fabricated using a bulk silicon wafer which is implanted and oxidized by oxygen to thereby form a relatively thin silicon dioxide layer 24b on a monocrystalline wafer surface 24a. Thereafter, another wafer (illustrated as layer 24c) is bonded to layer 24b. In one exemplary embodiment, semiconductor layer 24c (i.e., monocrystalline silicon) is disposed on insulation layer 24b (i.e. silicon dioxide), having a thickness of approximately 350 nm, which is disposed on a first substrate layer 24a (for example, monocrystalline silicon), having a thickness of approximately 190 nm.

Notably, all techniques for providing or fabricating SOI substrate 14a, whether now known or later developed, are intended to be within the scope of the present inventions.

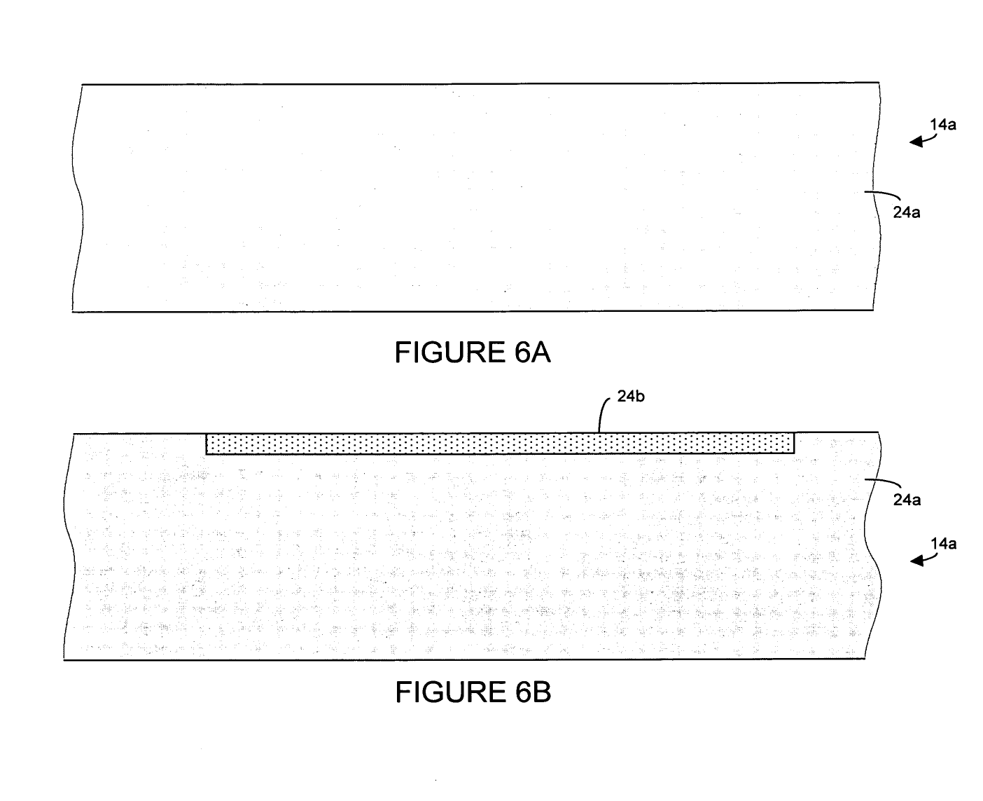

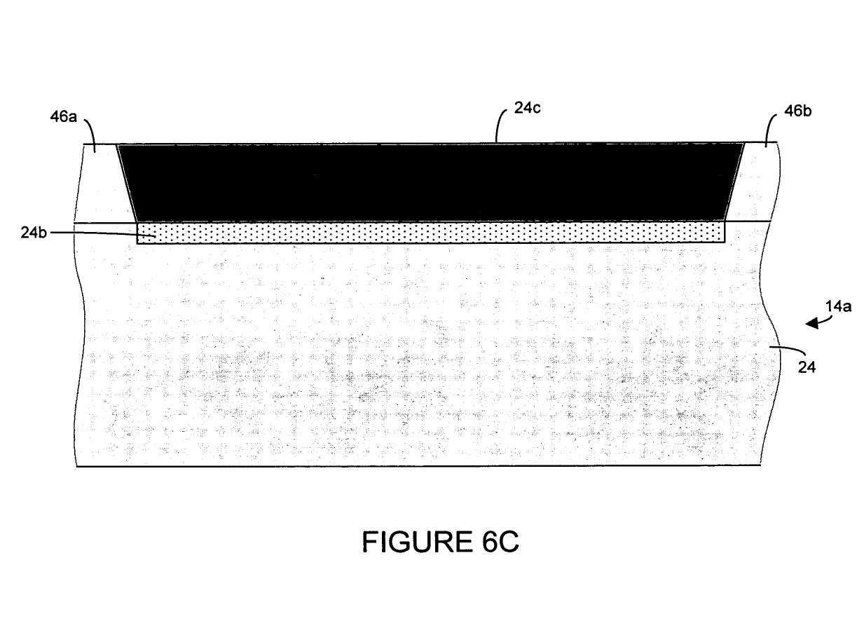

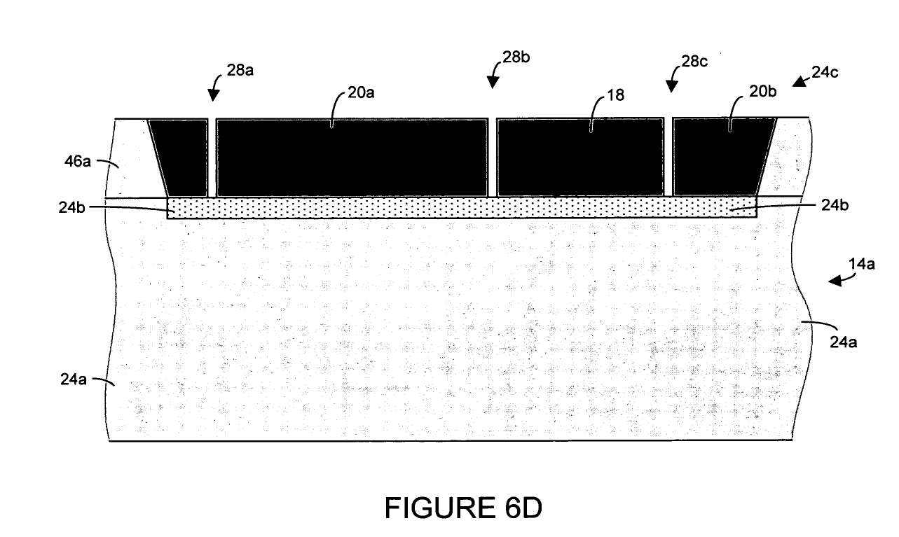

The micromachined mechanical structure 12 may also be fabricated on or in a standard or over-sized (“thick”) wafer (FIG. 6A) including substrate 24a. The substrate 24a may be comprised of materials in column IV of the periodic table, for example, silicon, germanium, carbon; also combinations of these, for example, silicon germanium, or silicon carbide; also of III-V compounds for example, gallium phosphide, aluminum gallium phosphide, or other III-V combinations; also combinations of III, IV, V, or VI materials, for example, silicon nitride, silicon oxide, aluminum carbide, or aluminum oxide; also metallic silicides, germanides, and carbides, for example, nickel silicide, cobalt silicide, tungsten carbide, or platinum germanium silicide; also doped variations including phosphorus, arsenic, antimony, boron, or aluminum doped silicon or germanium, carbon, or combinations like silicon germanium. In addition, substrate 24a may be comprised of materials with various crystal structures, including single crystalline, polycrystalline, nanocrystalline, amorphous, or combinations thereof (for example, having regions of single crystalline and polycrystalline structure (whether doped or undoped)).

In this embodiment, micromachined mechanical structure 12 may be formed using well-known lithographic, etching, deposition and/or doping techniques as well as from well-known materials (for example, semiconductors such as silicon, germanium, silicon-germanium or gallium-arsenide). (See, for example, FIGS. 6B-6D). The micromachined mechanical structure 12 may be formed from material(s) having polycrystalline structure which is/are deposited on insulation or sacrificial layer 24b. However, all techniques, materials and crystal structures for creating a partially formed device including micromachined mechanical structure 12 disposed on first sacrificial layer 24b, whether now known or later developed, are intended to be within the scope of the present inventions. Notably, field regions 46a and 46b may be comprised of single or monocrystalline structures (for example, monocrystalline silicon), polycrystalline structures, or both monocrystalline and polycrystalline structures.

The fabrication techniques described above and illustrated in FIGS. 4C-4M may be employed to micromachined mechanical structure 12 fabricated on or in a standard or over-sized (“thick”) wafer, including substrate 24a, of FIGS. 6A-6D. For the sake of brevity, those discussions will not be repeated.

Indeed, micromachined mechanical structure 12 fabricated on or in a standard or over-sized wafer of FIGS. 6A-6D may also employ the multiple layer encapsulation techniques described above and illustrated in FIGS. 5A-5E. For the sake of brevity, those discussions, in connection with the embodiments of FIG. 6, will not be repeated.

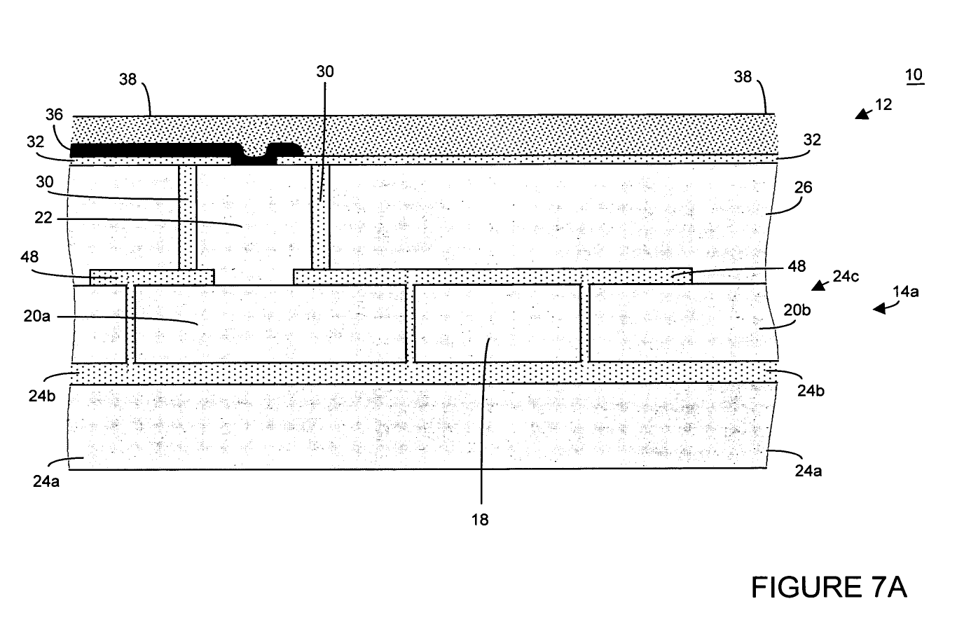

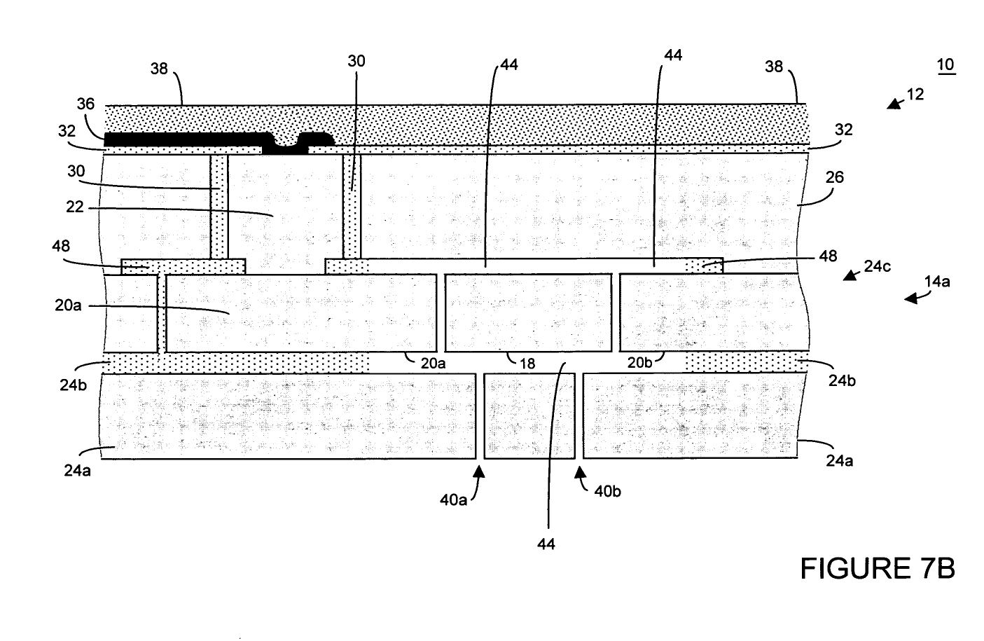

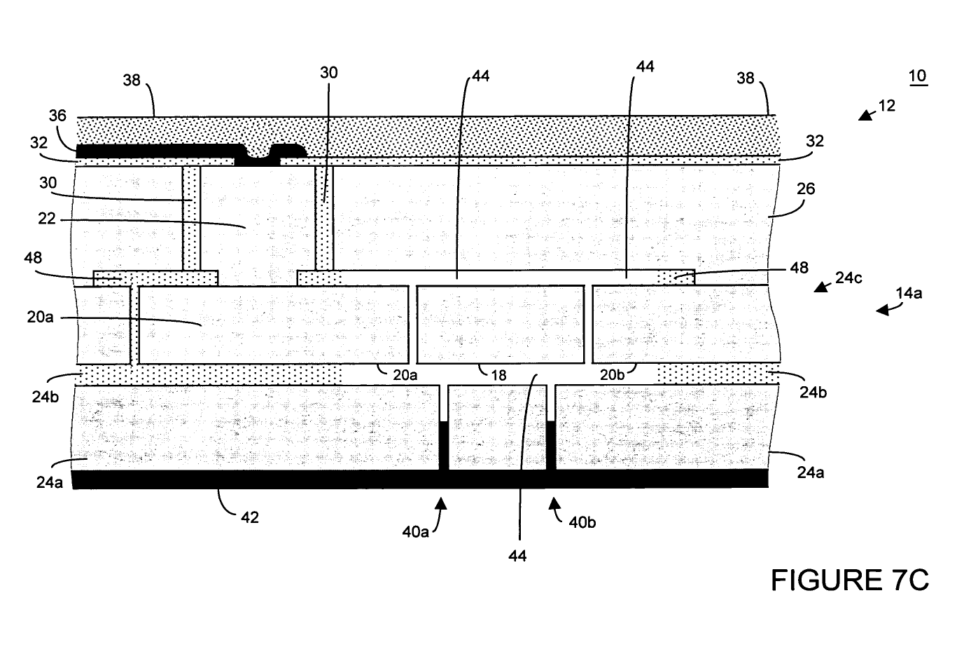

It may be advantageous to reduce the thickness of first substrate 14a prior to forming backside vents or holes 40 in first substrate 14a or after forming backside vents or holes 40 in first substrate 14a. Where the thickness of first substrate 14a prior to forming backside vents or holes 40 in first substrate 14a, the processing costs/time to form backside vents or holes 40, as well as the aperture/diameter of backside vents or holes 40 may be reduced. Moreover, smaller backside vents or holes 40 may facilitate filling of backside vents or holes 40 after release of mechanical structure 12 (for example, moveable electrode 18). For example, with reference to FIGS. 4J and 7A, in one embodiment, substrate 24a may be ground (using, for example, well-known chemical mechanical polishing (“CMP”) techniques) to reduce the thickness of substrate 24a.

Thereafter, mechanical structure 12 (for example, moveable electrode 18) is “released” by first etching backside vents or holes 40a and 40b in first substrate layer 24a (using, for example, anisotropic etching) and then etching and/or removal of at least selected portions of sacrificial layers 24b and 48 (using any of the techniques described herein such as buffered HF mixtures (i.e., a buffered oxide etch), well-known vapor etching techniques using vapor HF, or phosphoric acid). (See, for example, FIG. 7B). In this embodiment, backside vents or holes 40a and 40b may have an aperture/diameter of between 0.1 μm to 1 μm.

With reference to FIG. 7C, after releasing mechanical structure 12, sealing materials 42 may be deposited, applied, formed and/or grown to seal or close chamber 44. As described above, the one or more sealing materials 42 may be deposited, applied, formed and/or grown (i) on first substrate material 24a and/or (ii) over and/or in backside vents or holes 40. The materials and techniques employed to deposit, apply, form and/or grow sealing materials 42 may be the same as or similar to any described in connection with FIGS. 4 and 5. For the sake of brevity, those discussions will not be repeated. In this embodiment, however, smaller aperture/diameter backside vents or holes 40 may be implemented without increasing the aspect ratio (and complicating the manufacturability). Such aperture/diameter backside vents or holes 40 may be more easily and reliability closed and/or filled via sealing materials 42.

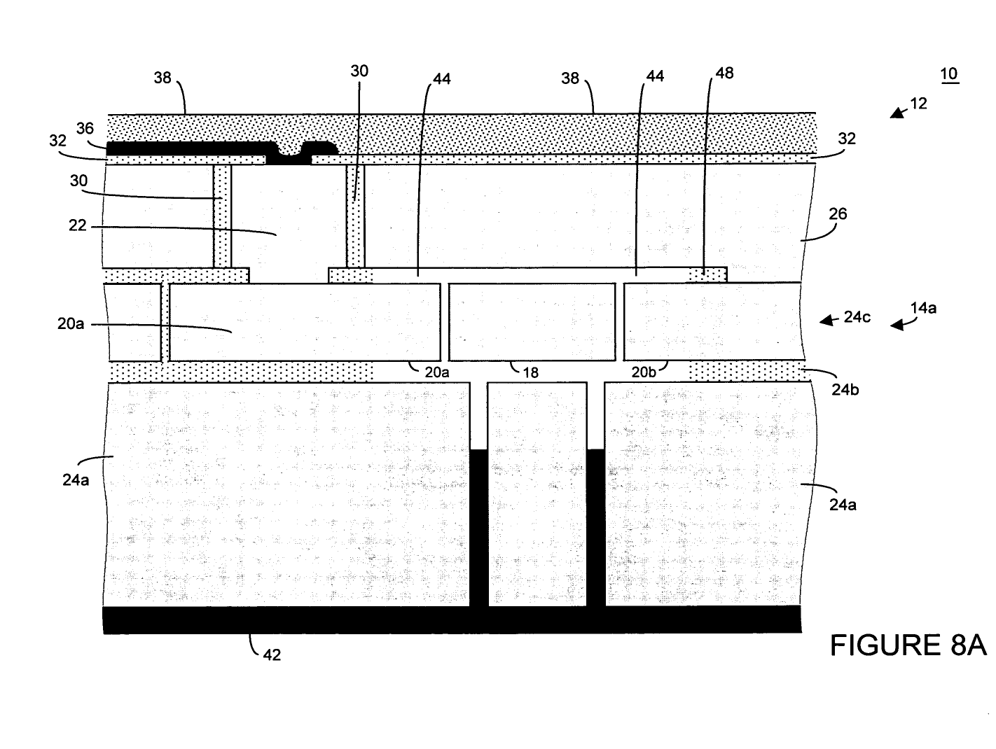

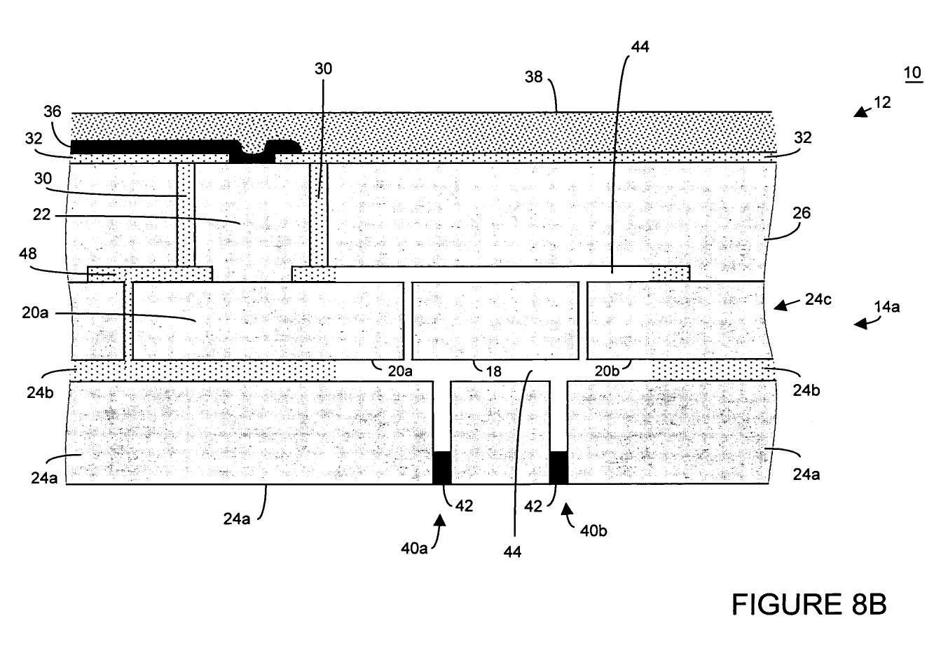

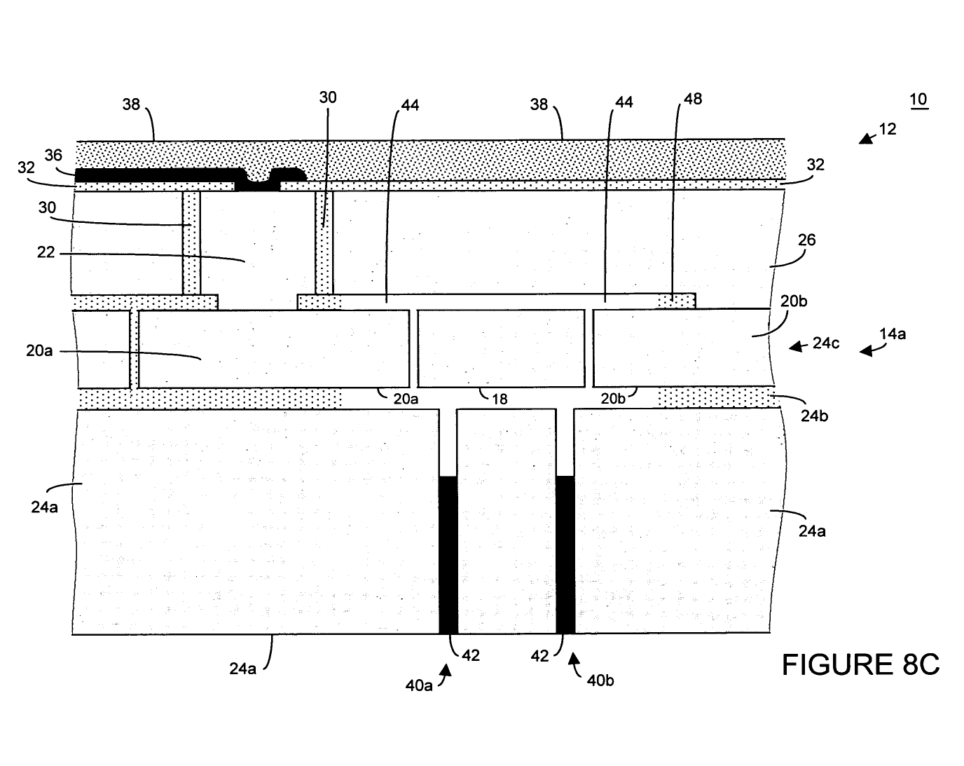

It may be advantageous to reduce the thickness of first substrate 14a after forming and sealing/closing backside vents or holes 40 in first substrate 14a. In this way, the overall thickness of microelectromechanical system 10 may be reduced. For example, with reference to FIGS. 8A and 8B, in one embodiment, after mechanical structure 12 (for example, moveable electrode 18) is “released” and sealing materials 42 is deposited, applied, formed and/or grown in backside vents or holes 40, sealing materials 42 and substrate 24a may be ground (using, for example, well-known chemical mechanical polishing (“CMP”) techniques) to remove sealing material 42 from the major surface of substrate 24a and thereafter reduce the thickness of substrate 24a. A suitable amount of sealing material 42 may remain within backside vents or holes 40 after grinding to adequately seal chamber 44. (See, FIG. 8B).

Notably, in one embodiment, one or more sealing materials 42 are removed from the major surface of substrate 24a to expose that surface of substrate 24a without reducing (for example, substantially or significantly reducing) the thickness of substrate 24a. (See, FIG. 8C).

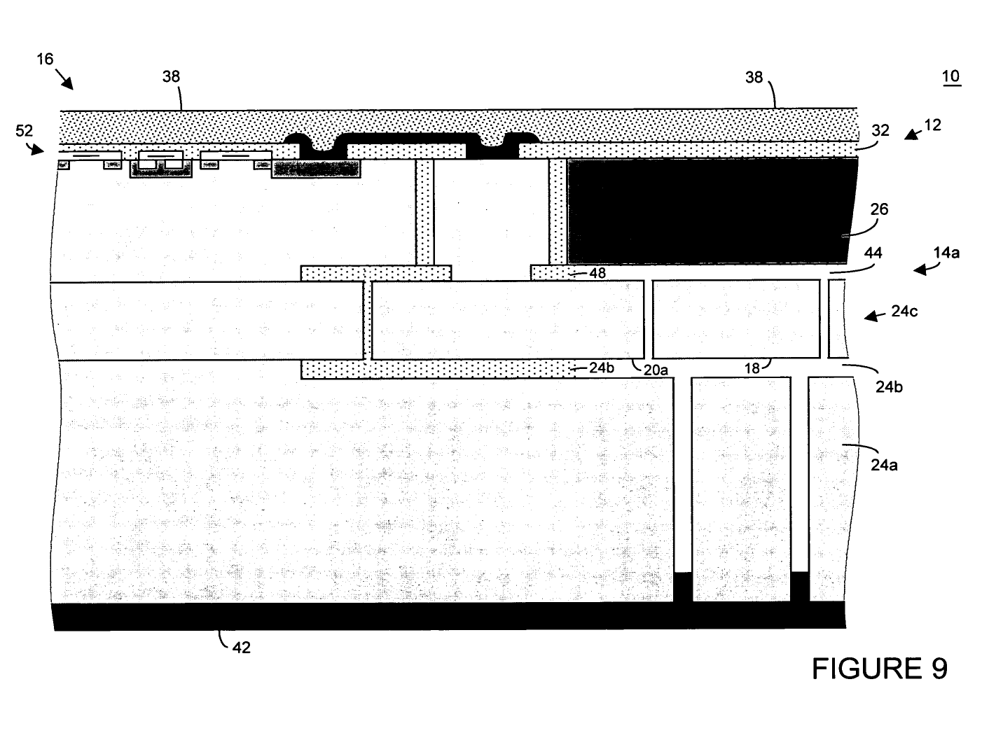

Prior to or after deposition, application, formation and/or growth of sealing materials 42 in backside vents or holes 40, additional micromachined mechanical structures 12 and/or transistors of circuitry 16 may be formed and/or provided (i) in cover 26 or (ii) in other substrates that may be fixed to substrate 14. In this regard, the exposed major surface of cover 26 may be a suitable base upon which integrated circuits (for example, CMOS transistors) and/or additional micromachined mechanical structures 12 may be fabricated on or in. Such integrated circuits may be fabricated using well-known techniques and equipment, and from well-known materials. For example, with reference to FIG. 9, in one embodiment, transistor regions 52, which may include integrated circuits (for example, CMOS transistors) of circuitry 16, may be provided, formed and/or fabricated in cover 26. The transistor regions 36 may be provided, formed and/or fabricated before or after deposition, application, formation and/or growth of sealing materials 42 in backside vents or holes 40 (and, as such, before or after release of micromachined mechanical structures 12).

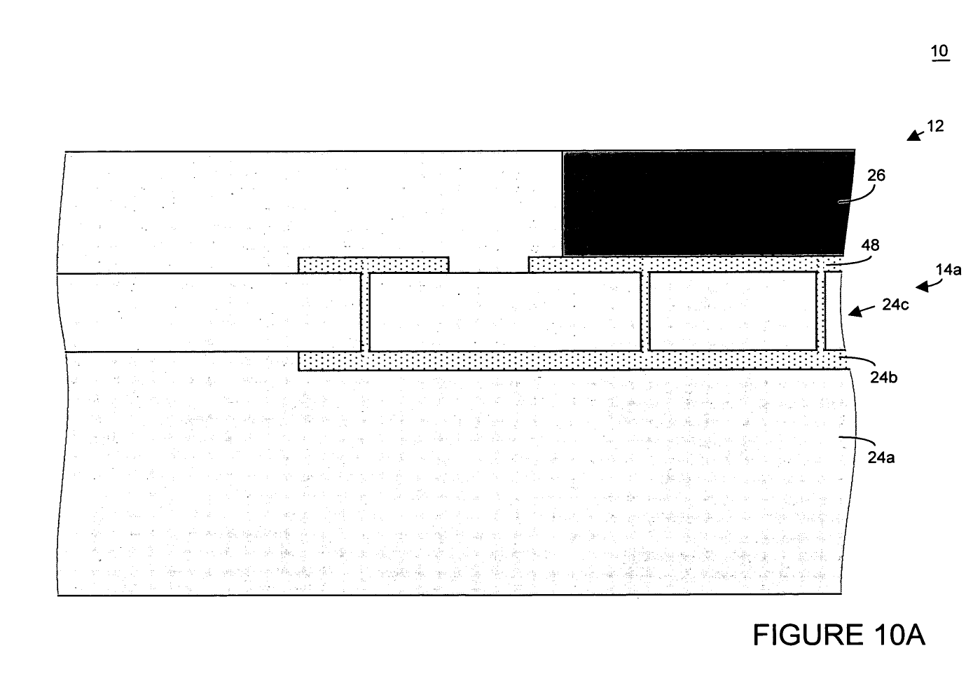

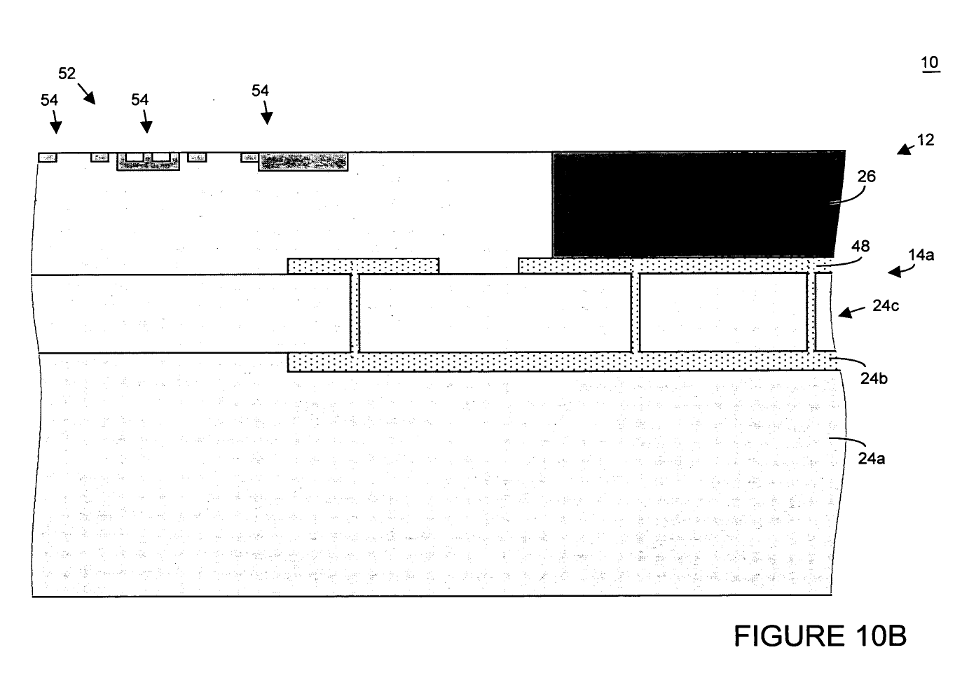

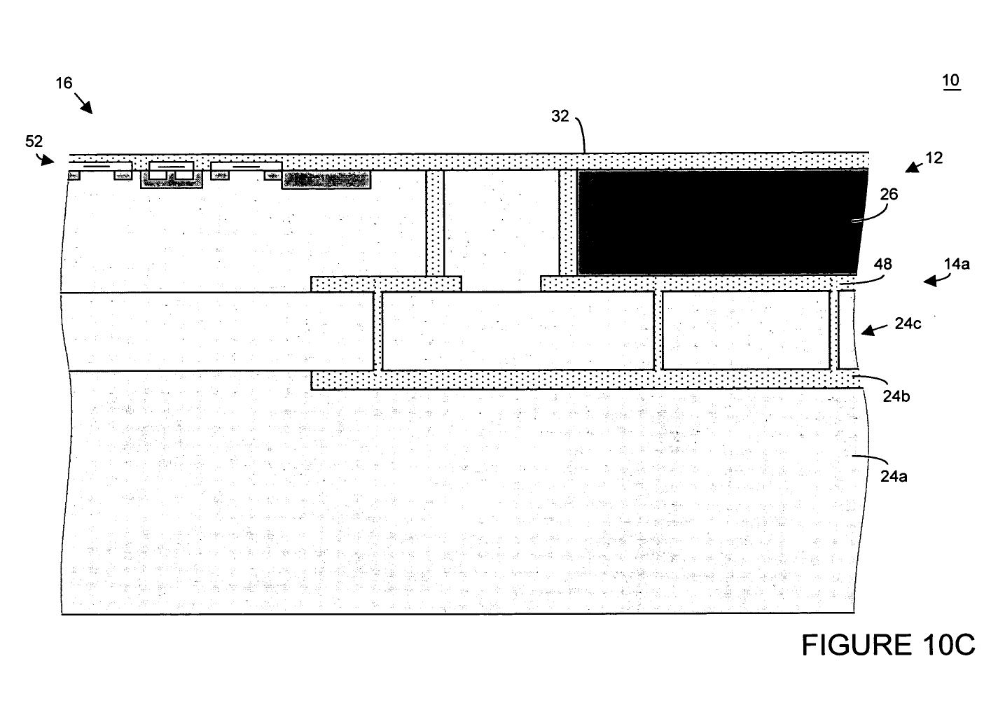

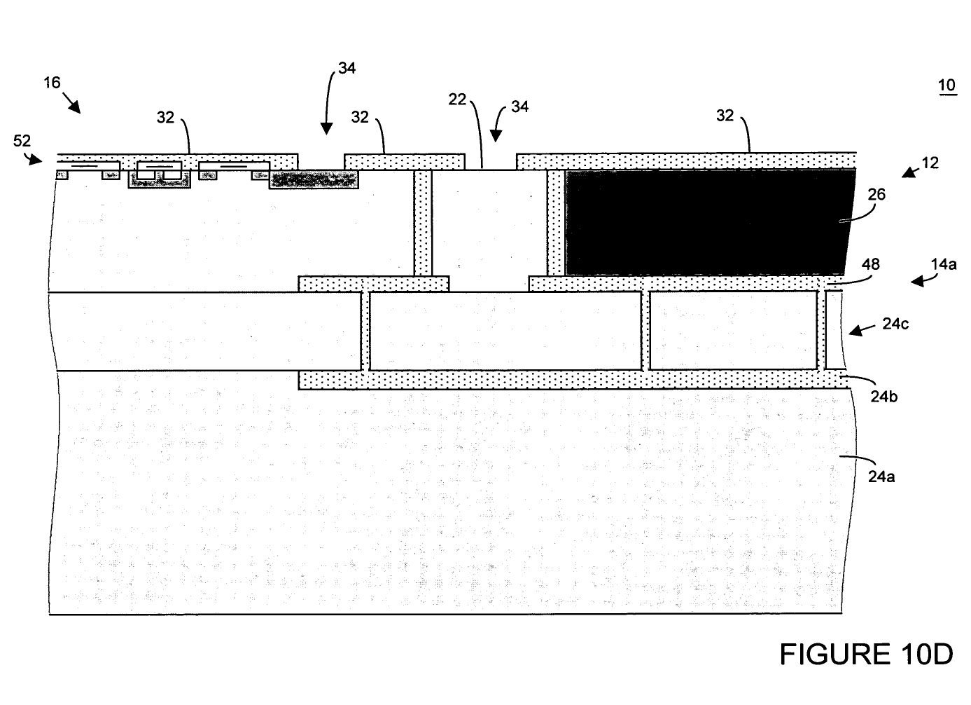

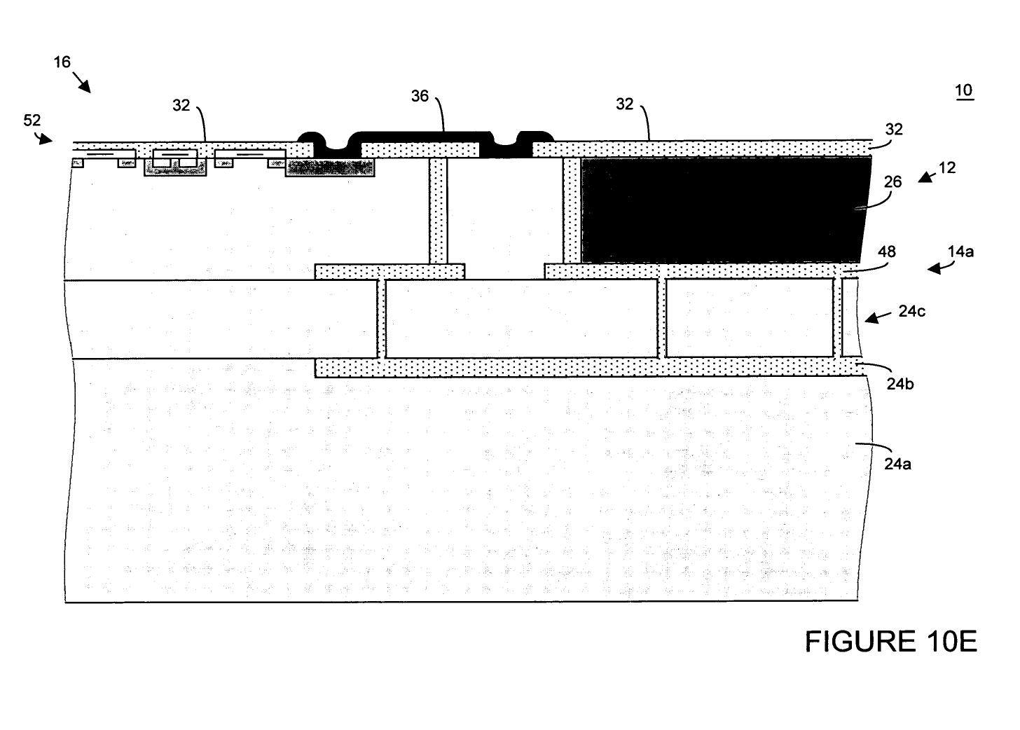

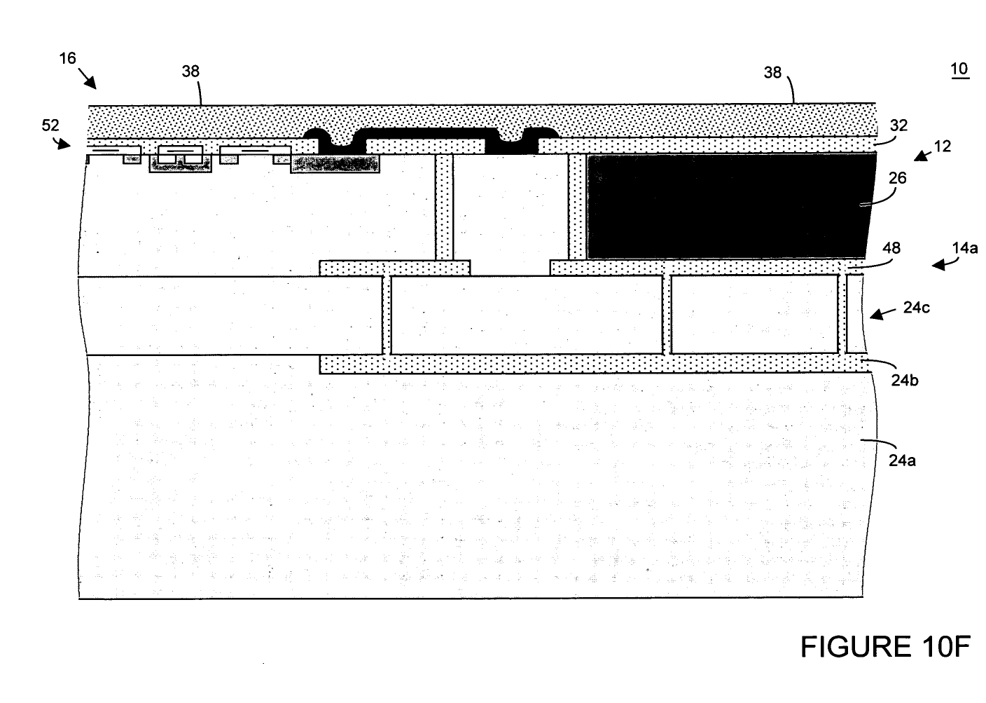

For example, with reference to FIGS. 10A and 10B, in one embodiment, transistor regions 52 include transistor implants 54 which may be formed using well-known lithographic and implant processes. Thereafter, conventional transistor processing (for example, formation of gate and gate insulator) may be employed to complete the transistors of circuitry 16. (See, FIGS. 10C-10F). Following transistor fabrication, the “back-end” processing of microelectromechanical system 10 (for example, formation, growth and/or deposition of insulation layer 32 and conductive layer 36) may be performed using the same processing techniques as described above. In particular, insulation layer 32 may be deposited, formed and/or grown. The insulating layer 32 may be, for example, a silicon dioxide, a silicon nitride, a BPSG, a PSG, or an SOG, or combinations thereof. (See, for example, FIG. 10C). It may be advantageous to employ silicon nitride because silicon nitride may be deposited in a more conformal manner than silicon oxide. Moreover, silicon nitride is compatible with CMOS processing, in the event that microelectromechanical system 10 includes CMOS integrated circuits.

Thereafter, insulation layer 32 may be patterned and, conductive layer 36 (for example, a heavily doped polysilicon, metal (such as aluminum, chromium, gold, silver, molybdenum, platinum, palladium, tungsten, titanium, and/or copper), metal stacks, complex metals and/or complex metal stacks) may be deposited and/or formed thereon. (See, for example, FIGS. 10D and 10E). In the illustrative embodiments, contact 22 is accessed directly by the transistors of circuitry 16 via conductive layer 36. Here, conductive layer 36 may be a low resistance electrical path that is deposited and patterned to facilitate connection of micromachined mechanical structure 12 and circuitry 16. (See, FIG. 10E).

After formation of conductive layer 36, passivation layer 38 may deposited on the exposed surfaces of conductive layer 36 and insulating layer 32 to protect an/or insulate microelectromechanical system 10. (See, FIG. 10F). As noted above, passivation layer 38 may include one or more layers including, for example, polymers, a silicon dioxide and/or a silicon nitride.

With reference to FIGS. 9 and 10F, the fabrication processes described and illustrated above may be employed to release micromachined mechanical structure 12 and to seal or close chamber 44 (via deposition, application, formation and/or growth of one or more sealing materials 42 on first substrate material 24a and/or over and/or in backside vents or holes 40. (See, for example, FIGS. 4K-4M and 5A-5E). For the sake of brevity, those discussions will not be repeated.

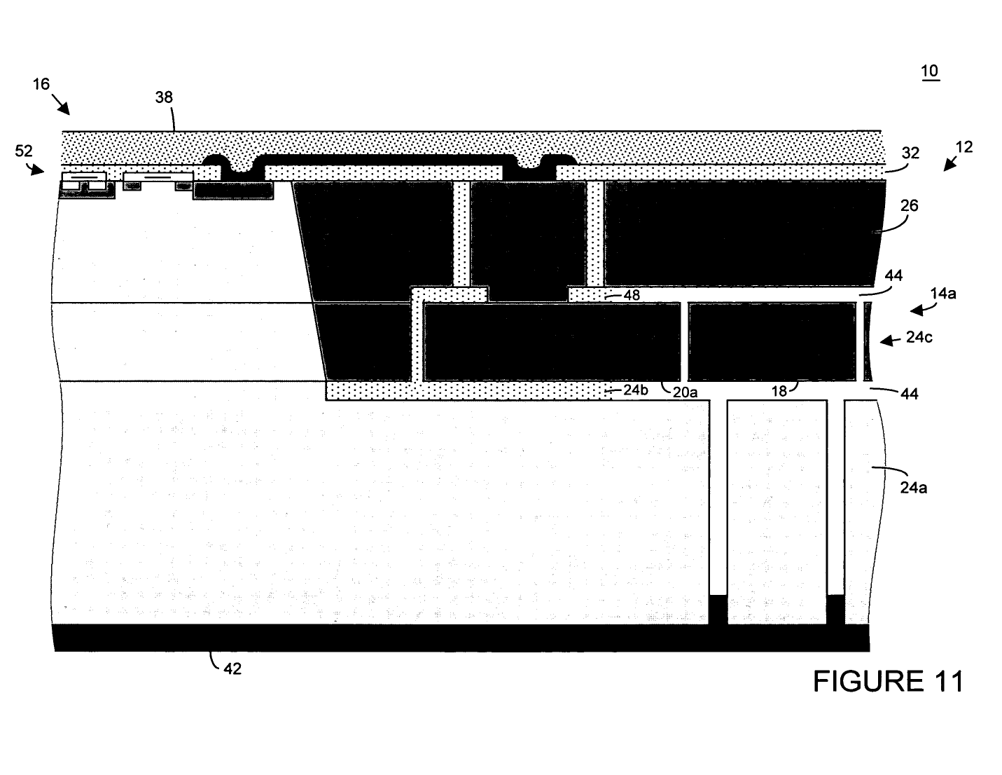

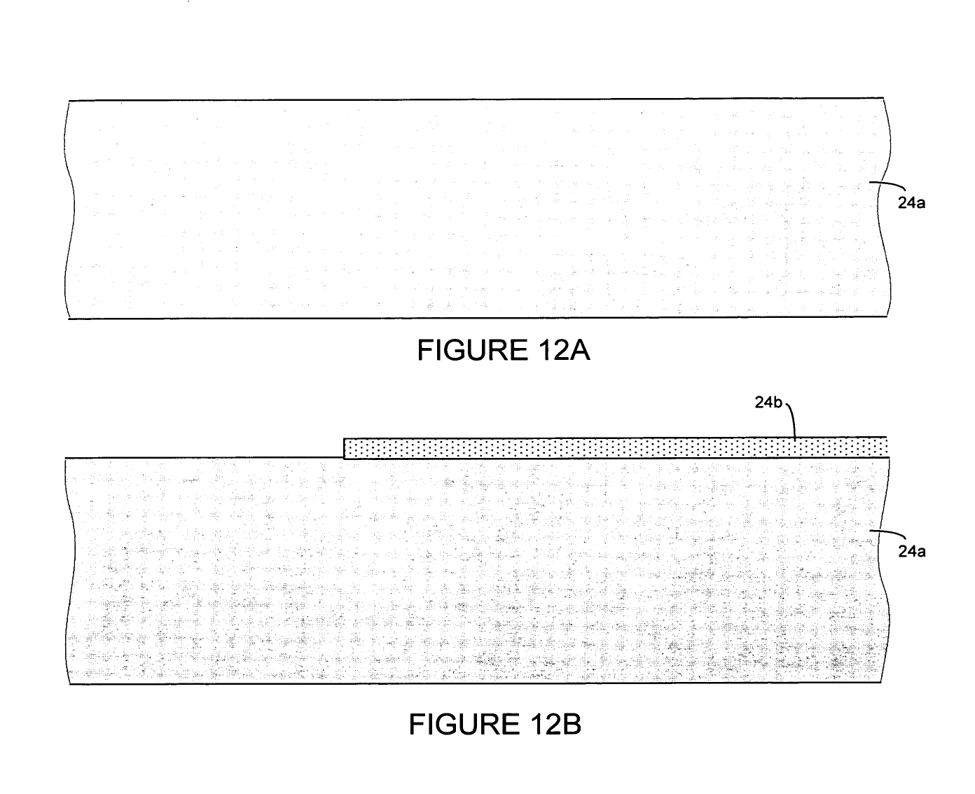

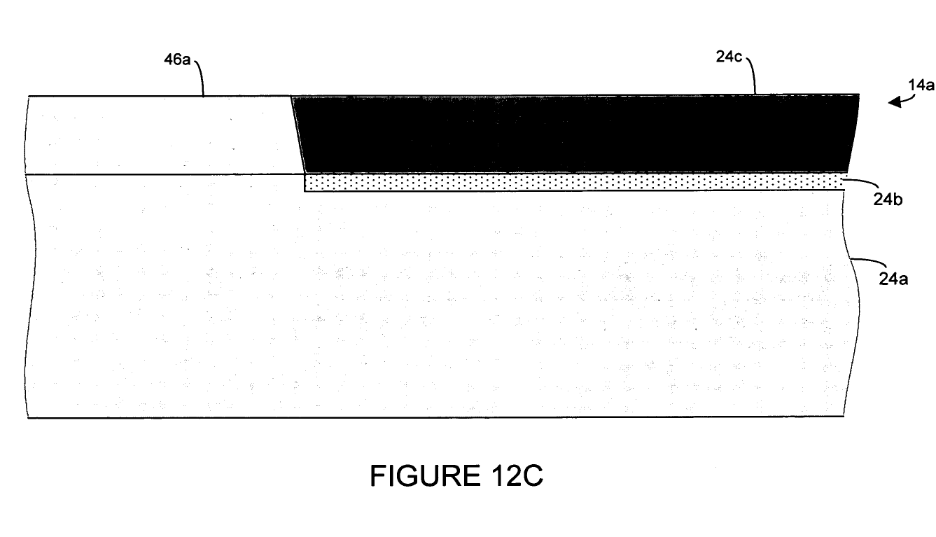

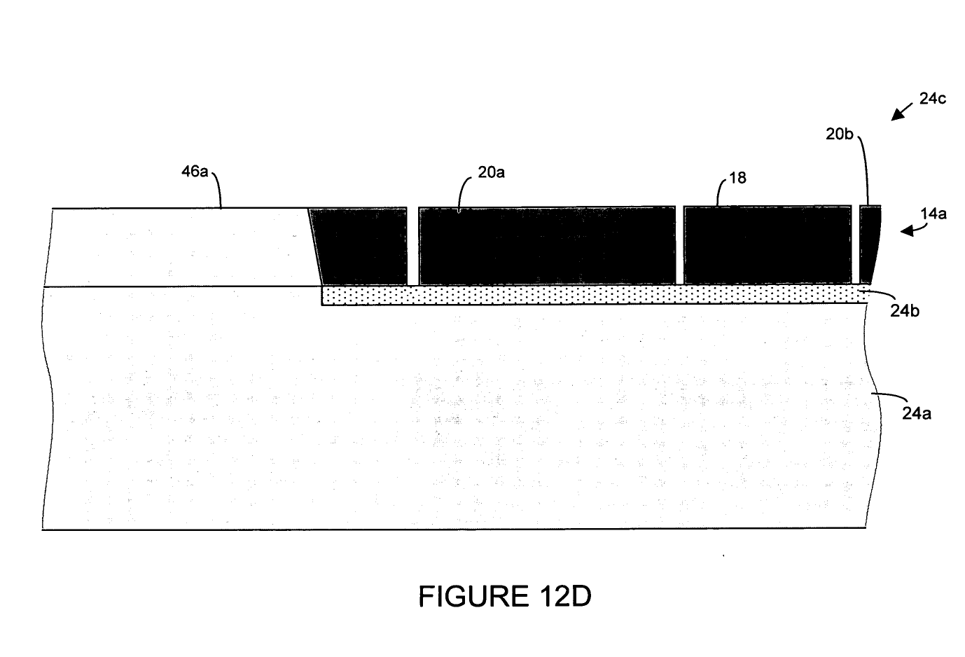

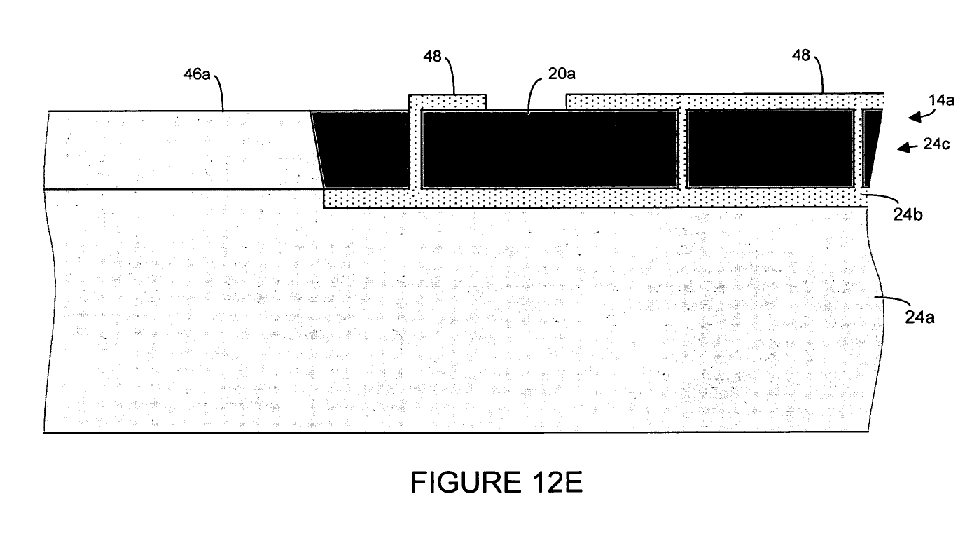

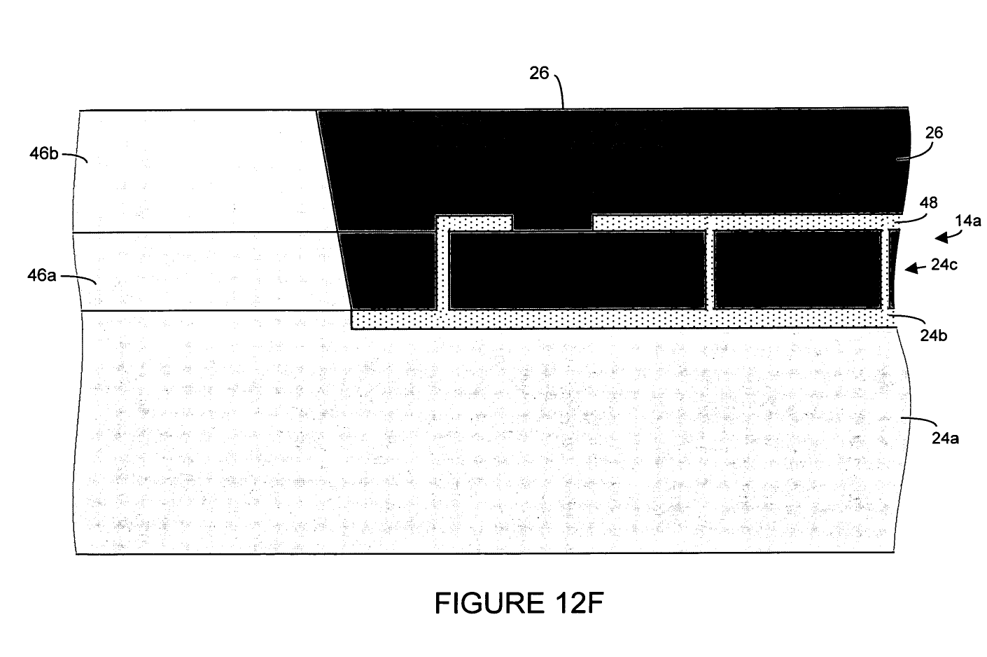

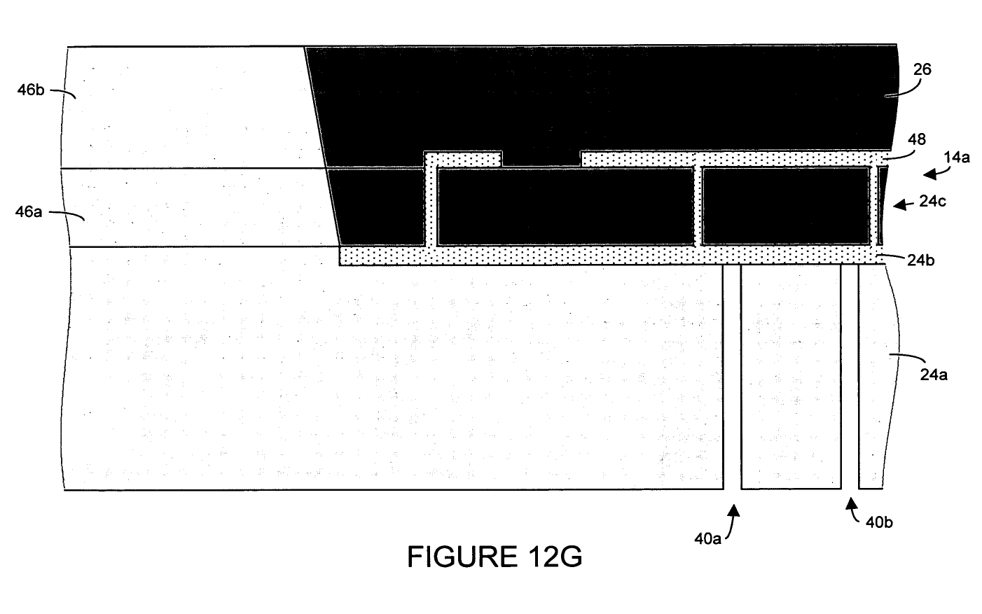

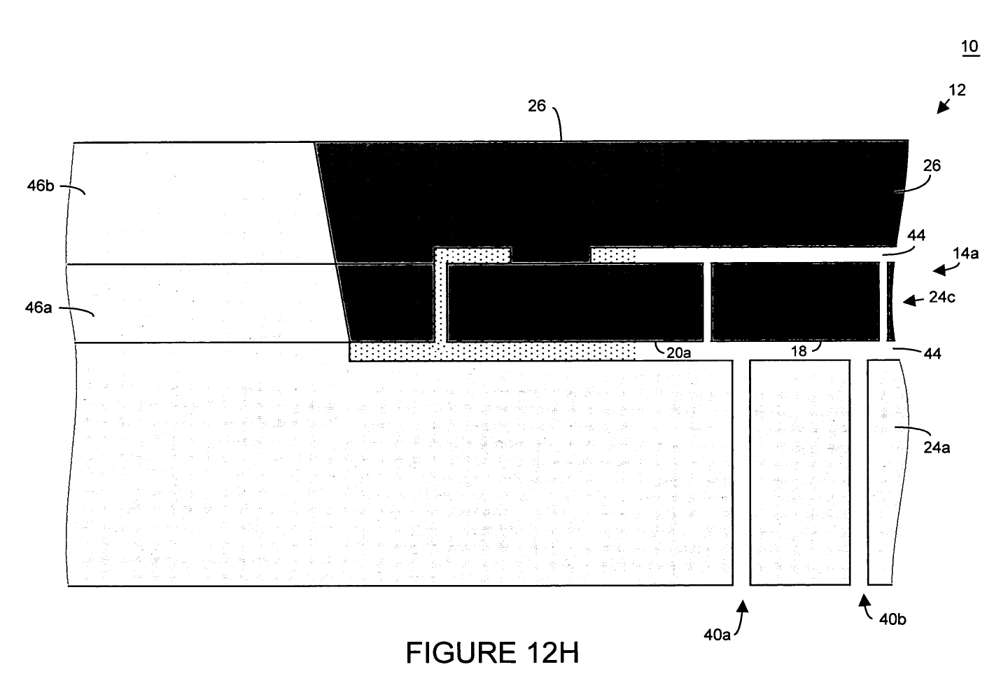

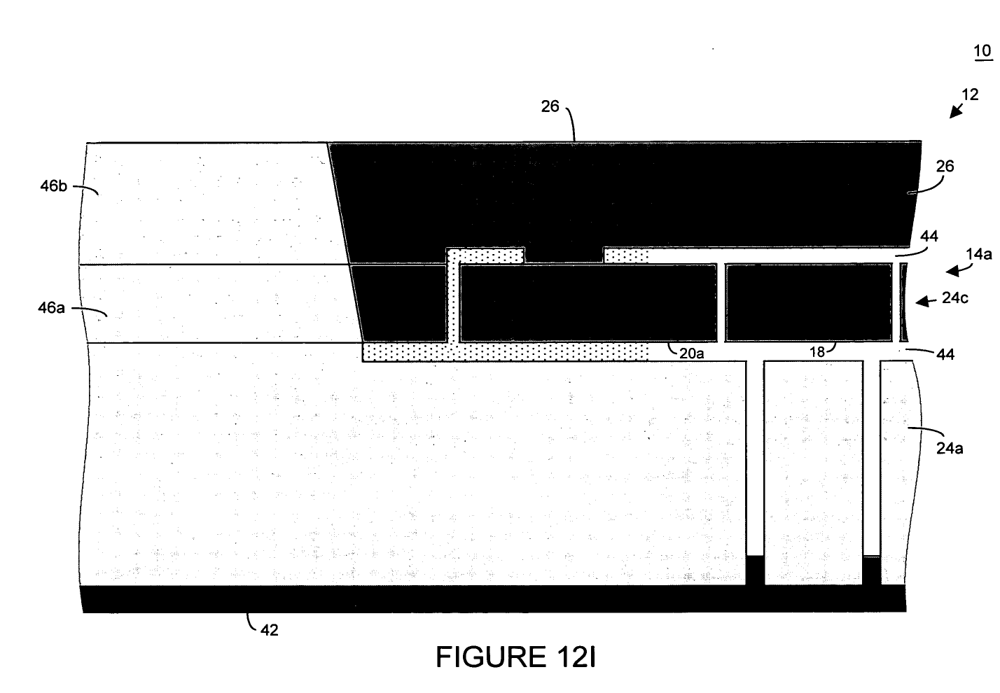

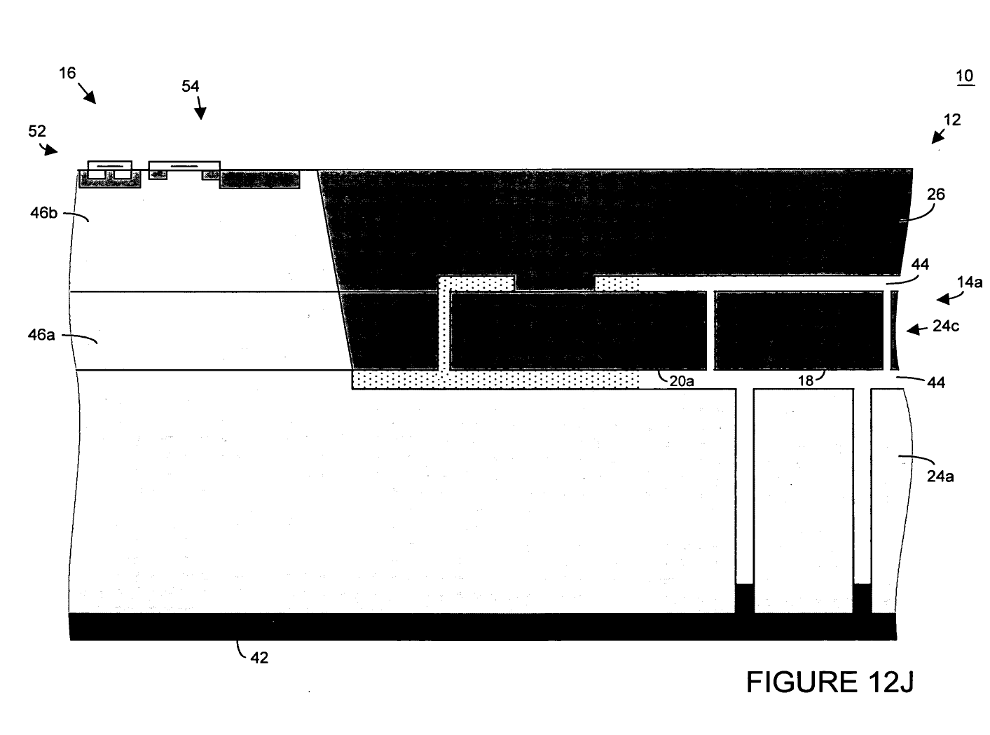

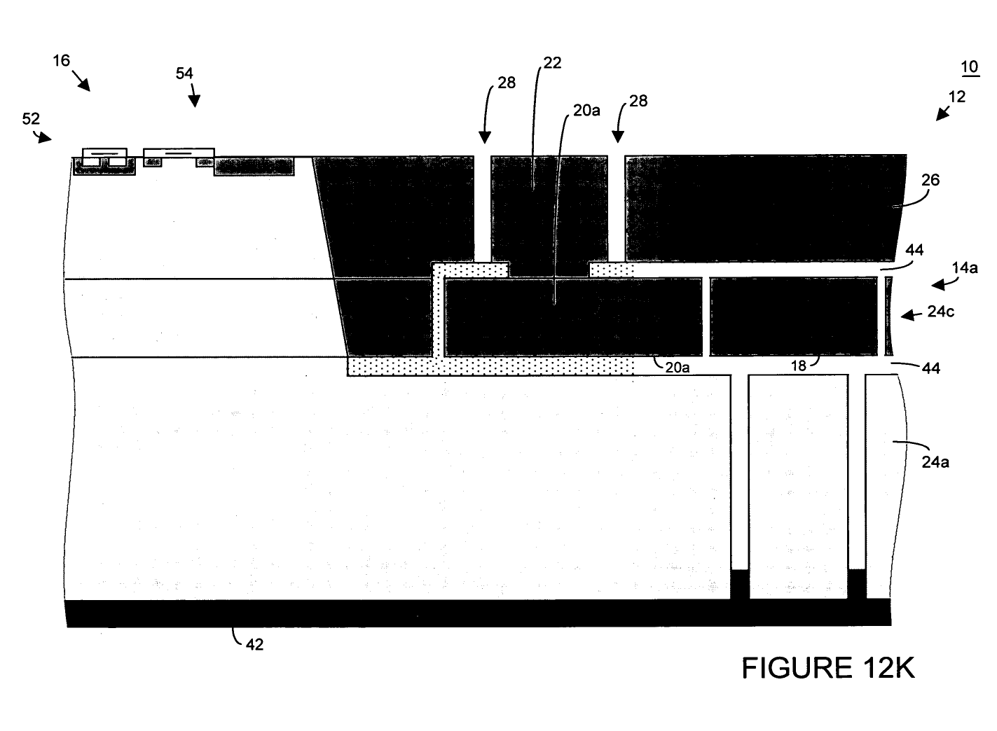

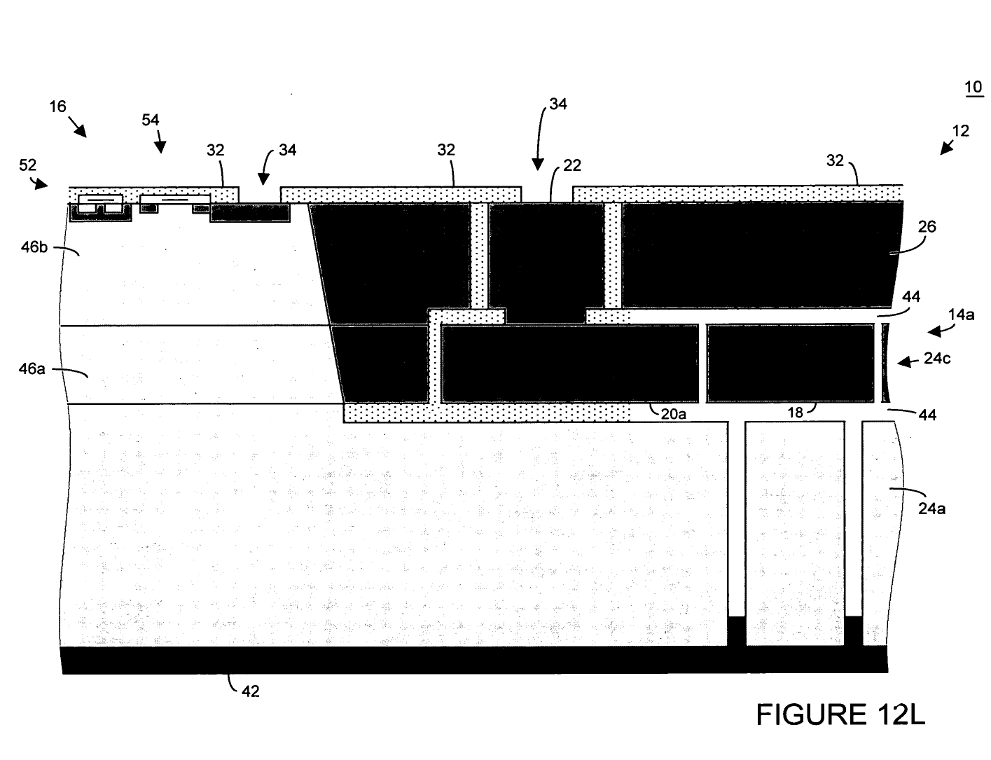

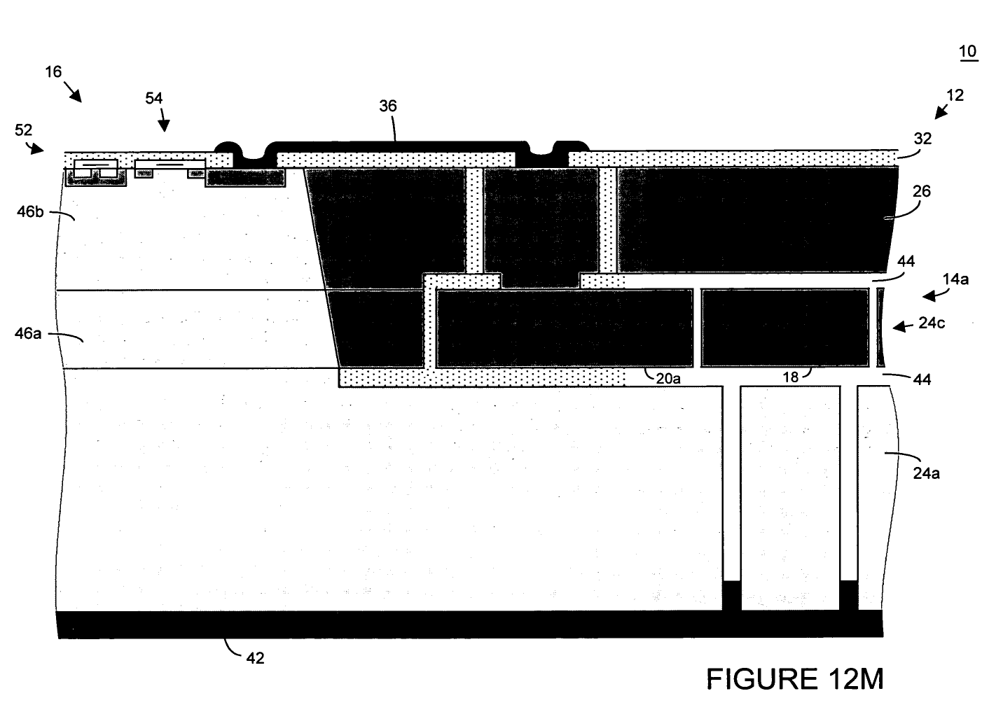

As noted above, the transistors and/or circuitry of transistor region 36 may also be formed after deposition, application, formation and/or growth of sealing materials 42 in backside vents or holes 40. (See, for example, FIGS. 11 and 12A-12H). Here, mechanical structure 12 may be manufactured and released as described above with respect to FIGS. 4, 5 and/or 6. For the sake of brevity, those discussions will not be repeated.

In this embodiment, after “release” of mechanical structure 12 (for example, moveable electrode 18) by (i) etching backside vents or holes 40a and 40b in first substrate layer 24a (using, for example, anisotropic etching) and (ii) etching and/or removal of at least selected portions of sacrificial layers 24b and 48 (using any of the techniques and materials described herein), sealing materials 42 may be deposited, applied, formed and/or grown on first substrate material 24a and/or over and/or in backside vents or holes 40. (See, FIG. 12I). The materials and techniques employed to deposit, apply, form and/or grow sealing materials 42 may be the same as or similar to any described in connection with FIGS. 4, 5 and 6. Again, for the sake of brevity, those discussions will not be repeated.

Thereafter, conventional transistor and integrated circuit processing (for example, formation of gate and gate insulator) may be employed to complete the transistors of circuitry 16. (See, FIG. 12J). For example, in one embodiment, transistor regions 52 include transistor implants 54 which may be formed using well-known lithographic and implant processes. Conventional transistor processing (for example, formation of gate and gate insulator) may be employed to complete the transistors of circuitry 16.

Following transistor fabrication (or prior thereto), trenches 28 may be formed in cover 26, using, for example, well-known lithographic and etching techniques. (See, FIG. 12K). An insulating material may be deposited and/or grown in trenches 28. In this way, contact 22 may be electrically isolated from surrounding or neighboring portions of cover 26.

With reference to FIG. 12L, insulation layer 32 may be deposited, formed and/or grown and thereafter patterned. The insulating layer 32 may be, for example, a silicon dioxide, a silicon nitride, a PSG, a BPSG, or an SOG, or combinations thereof. It may be advantageous to employ silicon nitride because silicon nitride may be deposited in a more conformal manner than silicon oxide. Moreover, silicon nitride is compatible with CMOS processing, in the event that microelectromechanical system 10 includes CMOS integrated circuits.

A conductive layer 36 (for example, a highly conductive semiconductor, a metal (such as aluminum, chromium, gold, silver, molybdenum, platinum, palladium, tungsten, titanium, and/or copper), metal stacks, complex metals and/or complex metal stacks) may be deposited and/or formed on insulating layer 32. (See, for example, FIG. 12M). Thus, conductive layer 36 may be a low resistance electrical path that is deposited and patterned to facilitate connection of micromachined mechanical structure 12 to, in this embodiment, transistors of circuitry 16.

After formation of conductive layer 36, passivation layer 38 may be deposited on the exposed surfaces of conductive layer 36 and insulating layer 32 to protect an/or insulate microelectromechanical system 10. (See, FIG. 11). As stated above, passivation layer 38 may include one or more layers including, for example, polymers, a silicon dioxide and/or a silicon nitride.

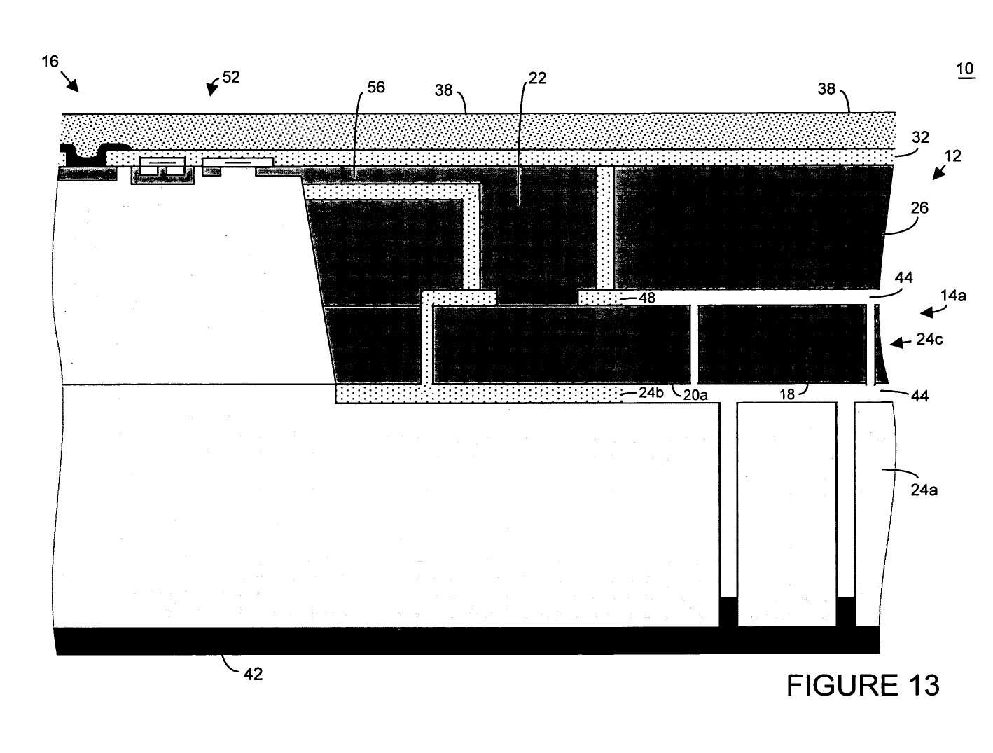

Notably, transistors of circuitry 16 may access contact 22 using any technique and/or configuration whether now known or later developed. For example, with reference to FIG. 13, transistors of circuitry 16 may access contact 22 via wiring region 56 which is deposited and/or formed in cover 26. The wiring region 56 may be a doped semiconductor (for example, heavily doped polysilicon). The wiring region 56 may provide a low resistance electrical path and/or an electrical path having predetermined electrical characteristics (for example, a predetermined resistance, inductance and/or capacitance which provides a predetermined frequency response to output signals generated by micromachined mechanical structures 12 during operation thereof).

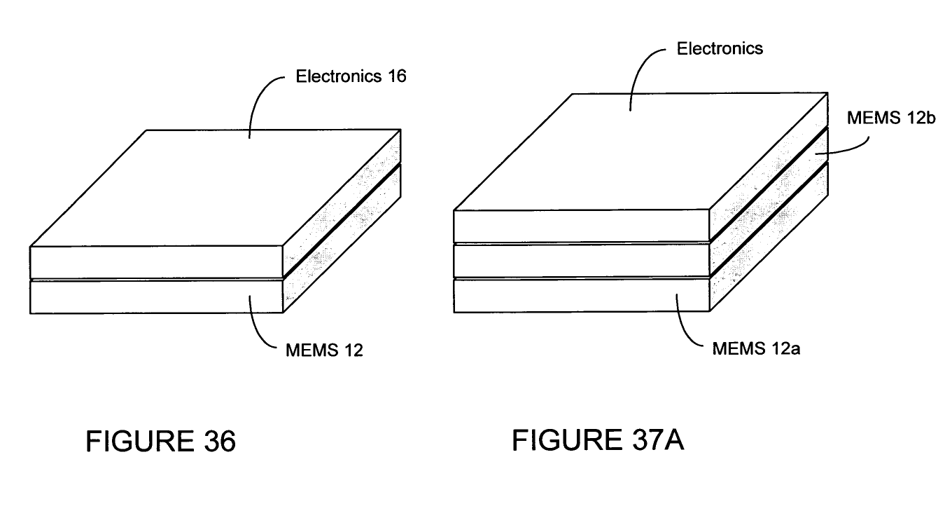

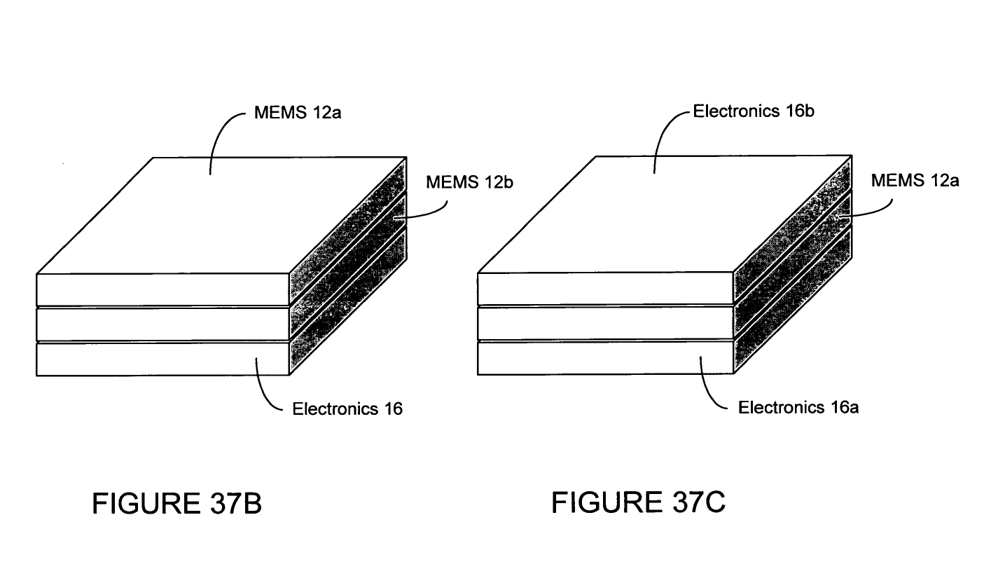

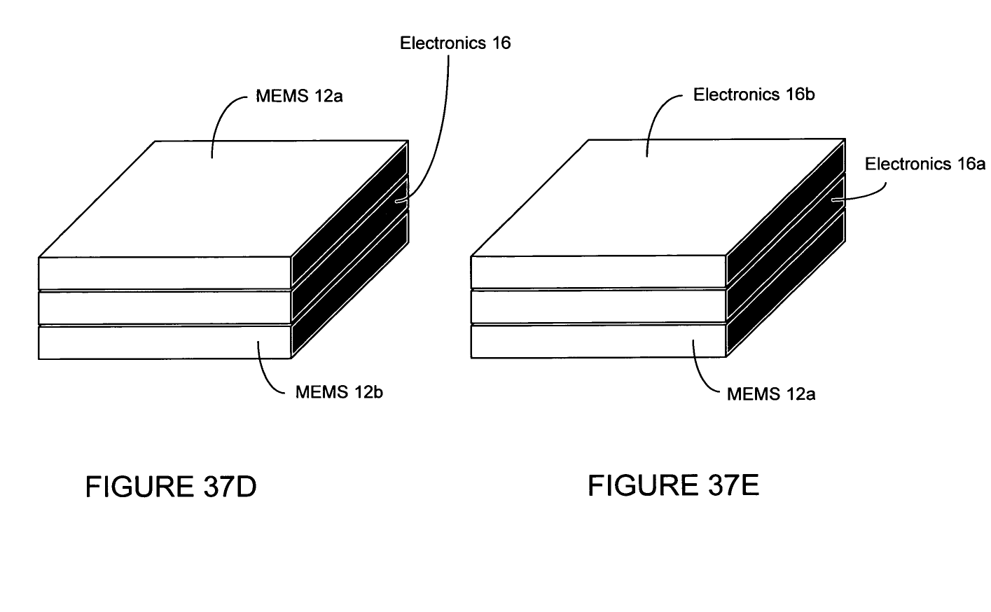

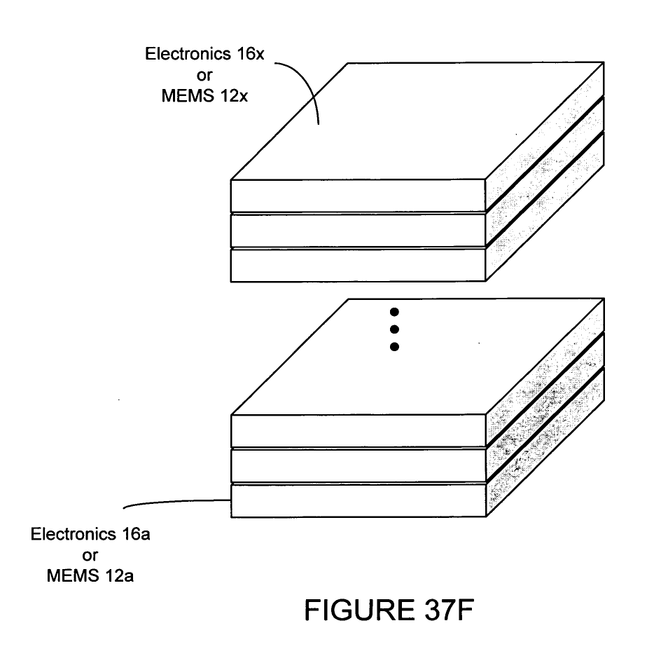

In certain embodiment, additional substrates, including additional micromachined mechanical structures 12 and/or transistors of circuitry 16, may be formed and/or provided in are disposed on and affixed to cover 26. The additional substrates may be deposited or formed on cover 26 and/or bonded to cover 26. (See, for example, FIGS. 36 and 37A-37F). In these embodiments, the plurality of substrates containing micromachined mechanical structures 12 and/or transistors of circuitry 16 are stacked. Each micromachined mechanical structure 12 of the plurality of stacked substrates may include the same, different or predetermined environments (for example, where micromachined mechanical structure includes an inertial device an environment providing a low quality factor (Q) may be advantageous and micromachined mechanical structure includes a resonator an environment providing a high Q may be advantageous).

In another set of embodiments, cover 26 may be a substrate which is fixed (for example, bonded) to the exposed surface of substrate 14a (or a layer disposed thereon or affixed thereto). In this regard, cover 26 may be a substrate comprised of a semiconductor material, a conductive material, a glass material, or an insulator material. For example, where cover 26 is a semiconductor material, cover 26 may be comprised of, for example, materials in column IV of the periodic table, such as silicon, germanium, carbon, and/or combinations of these, for example, silicon germanium, or silicon carbide, and/or compounds of material in column III-V, for example, gallium phosphide, aluminum gallium phosphide, or other III-V combinations; also combinations of III, IV, V, or VI.

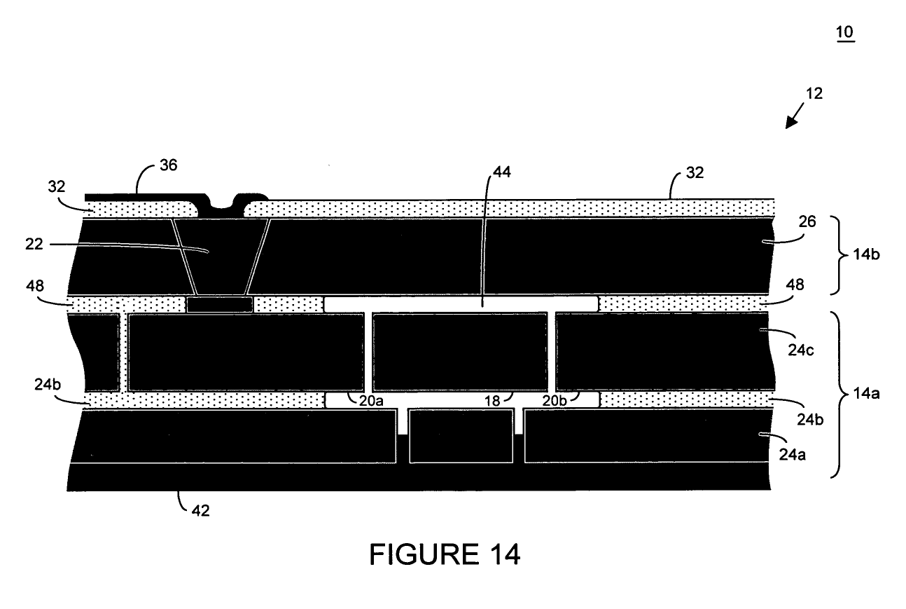

With reference to FIG. 14, in one embodiment, cover 26 may include second substrate 14b which is fixed to the exposed portions of first substrate 14a or layers disposed or affixed thereto (which includes second sacrificial layer 48 and contact interconnect 60). In these embodiments, cover 26 may be secured to substrate 14a using, for example, well-known bonding techniques such as fusion bonding, anodic-like bonding and/or silicon direct bonding. Other bonding technologies are suitable including soldering (for example, eutectic soldering), thermo compression bonding, thermo-sonic bonding, laser bonding and/or glass reflow, and/or combinations thereof. Indeed, all forms of bonding, whether now known or later developed, are intended to fall within the scope of the present inventions.

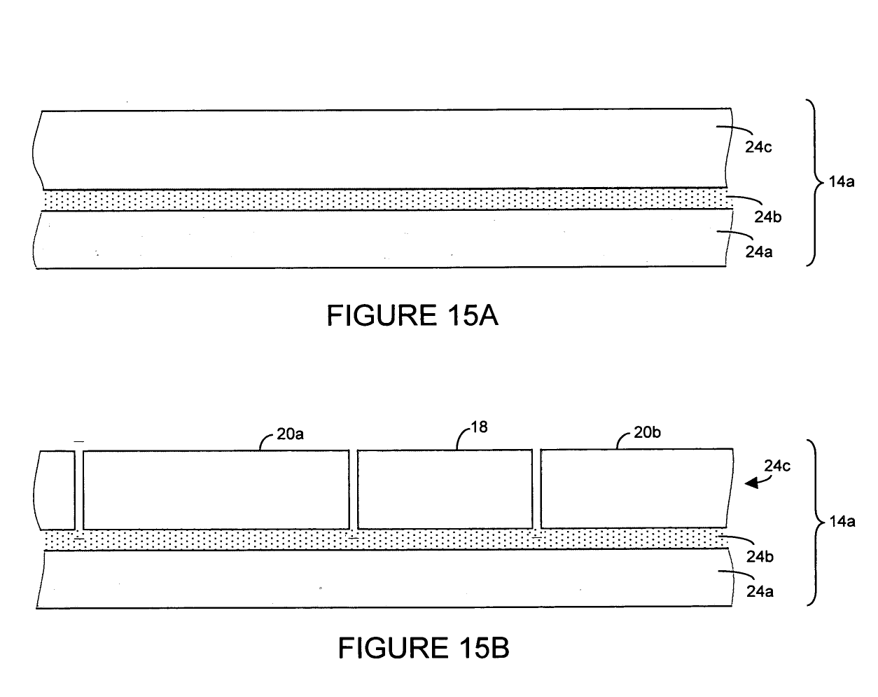

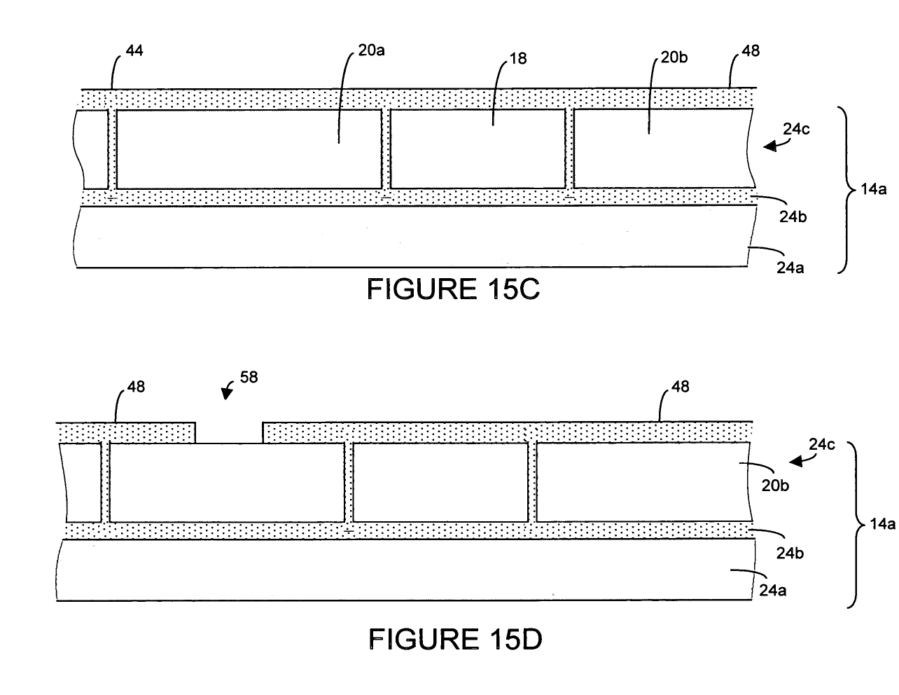

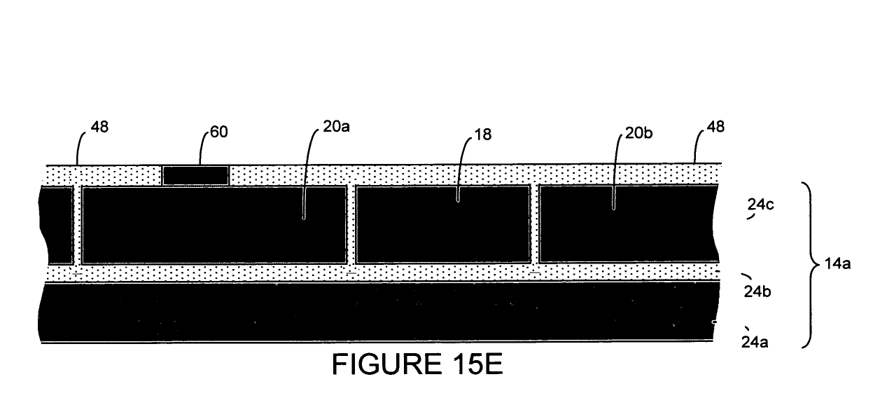

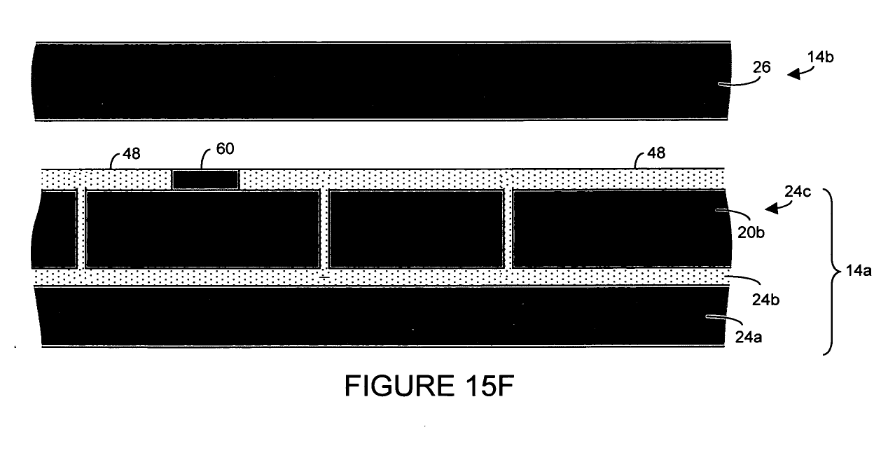

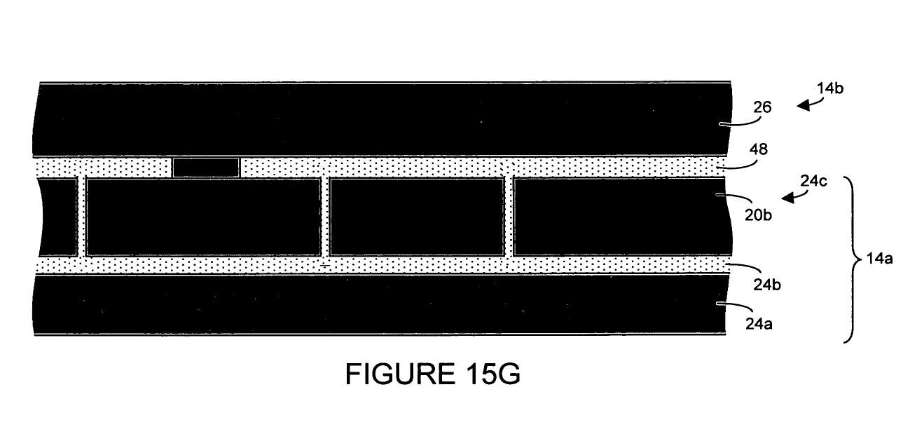

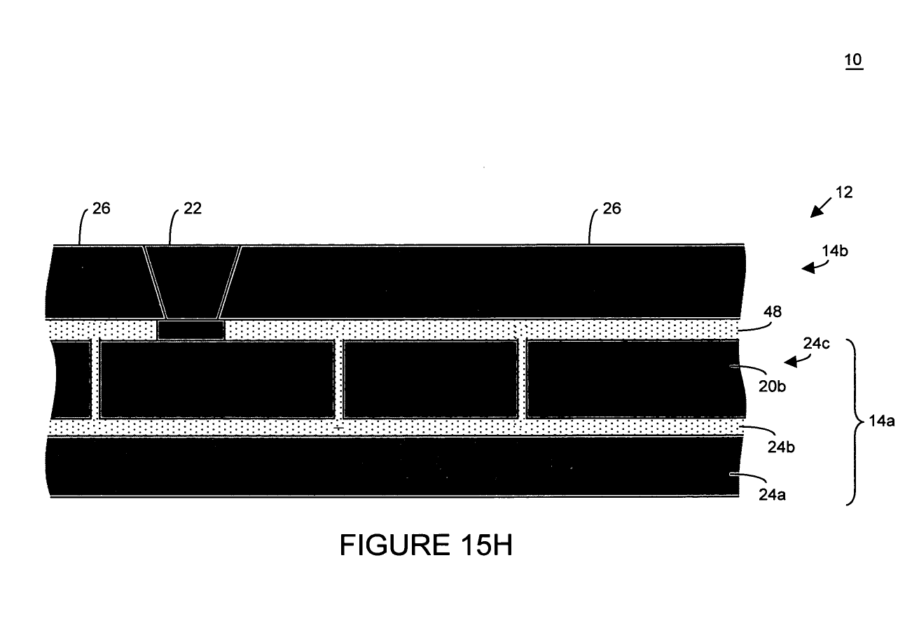

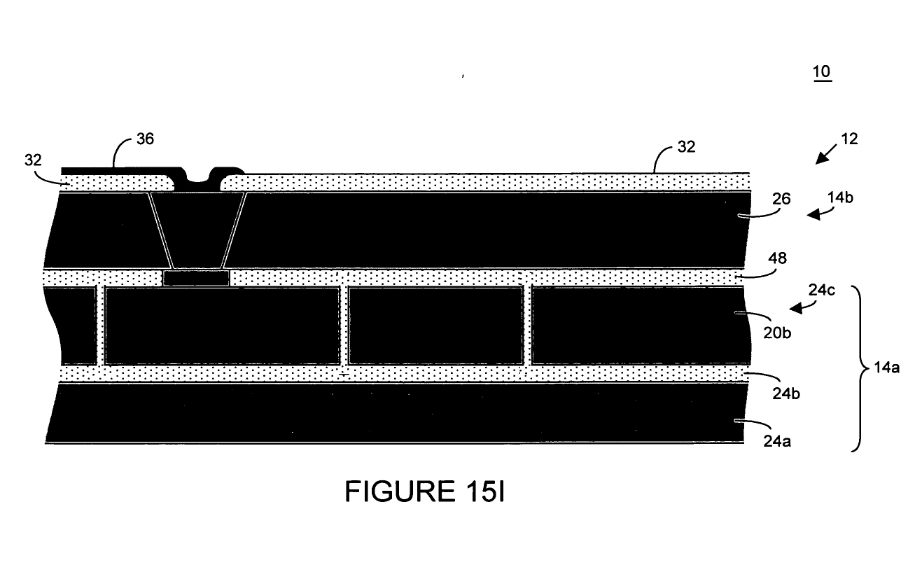

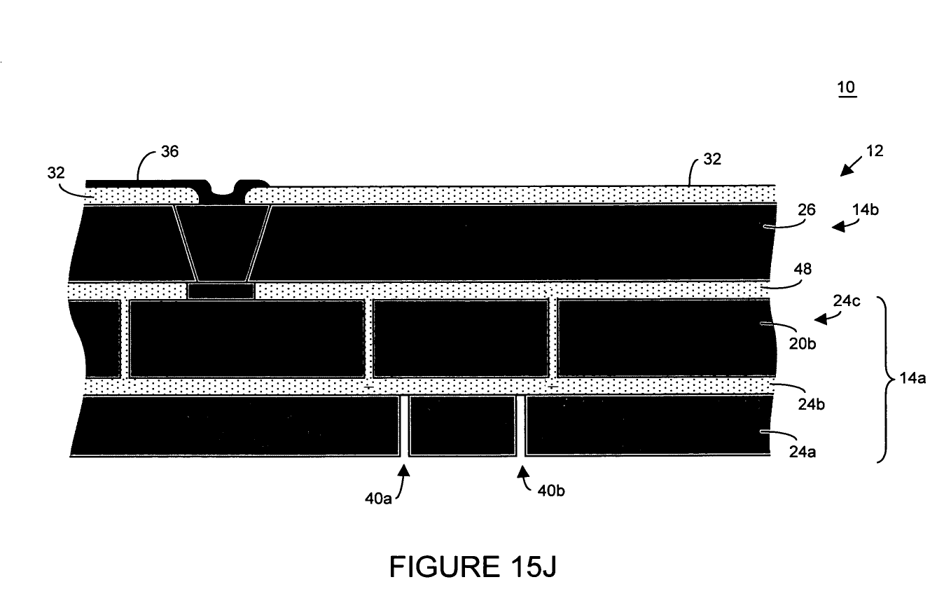

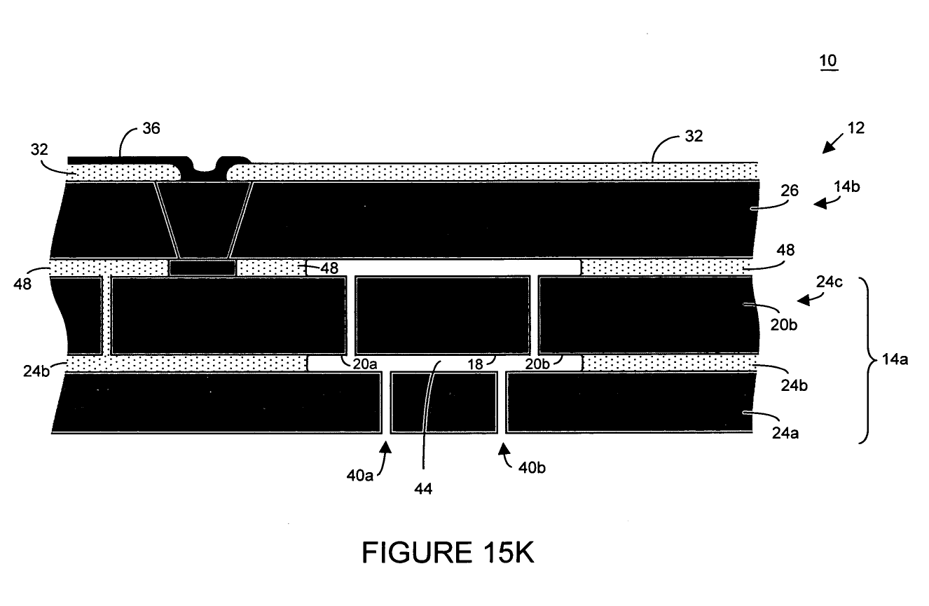

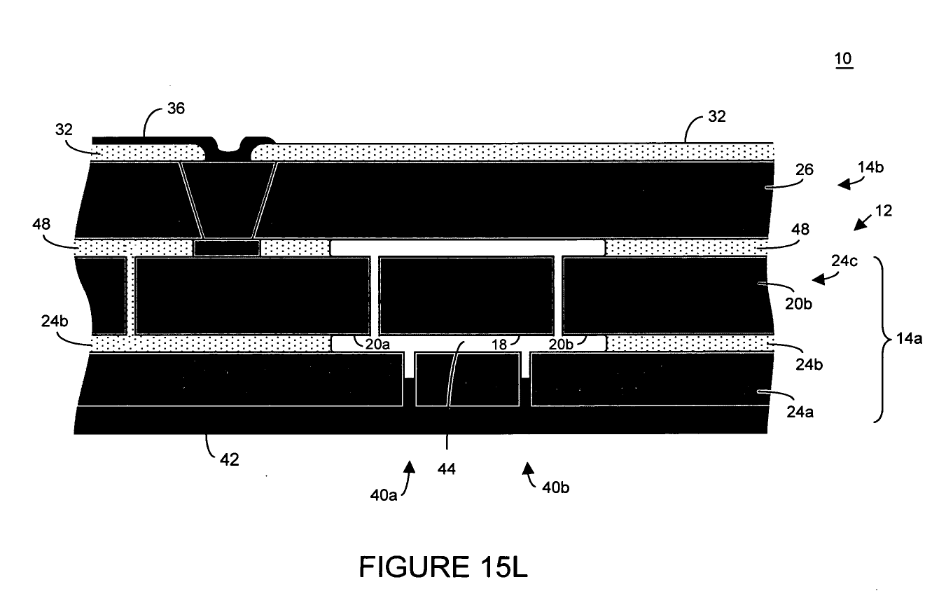

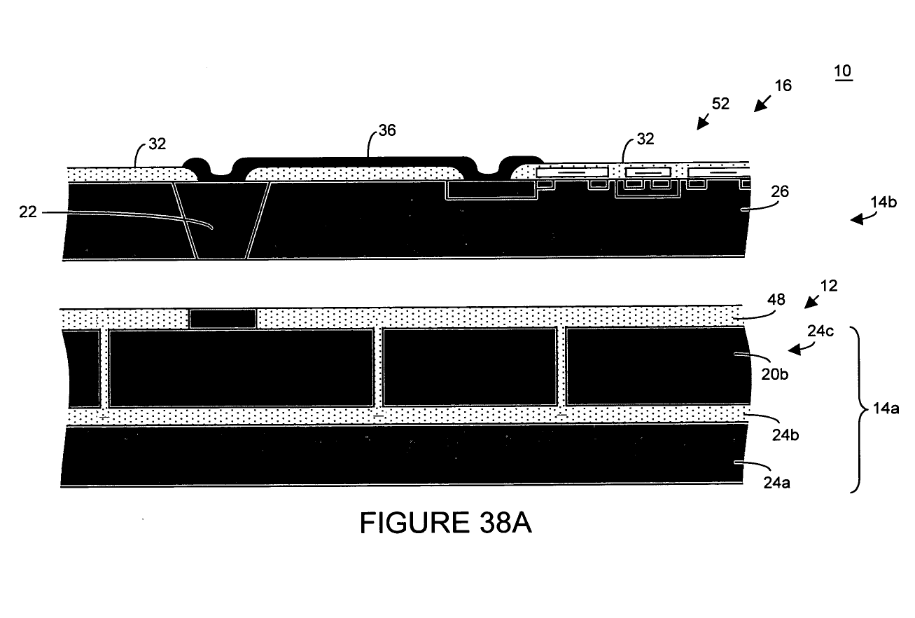

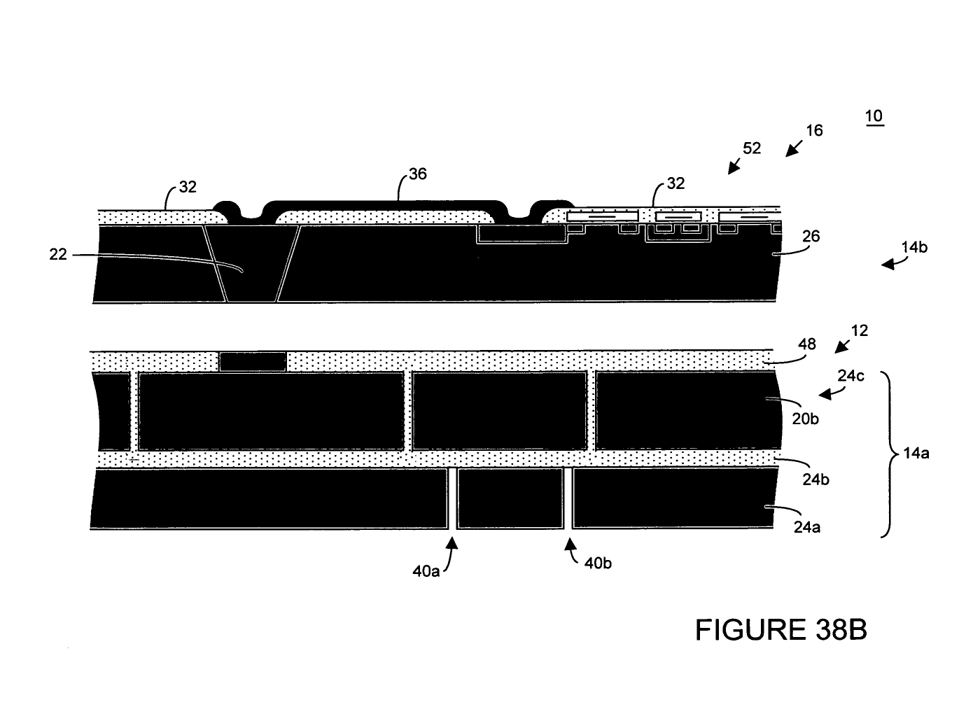

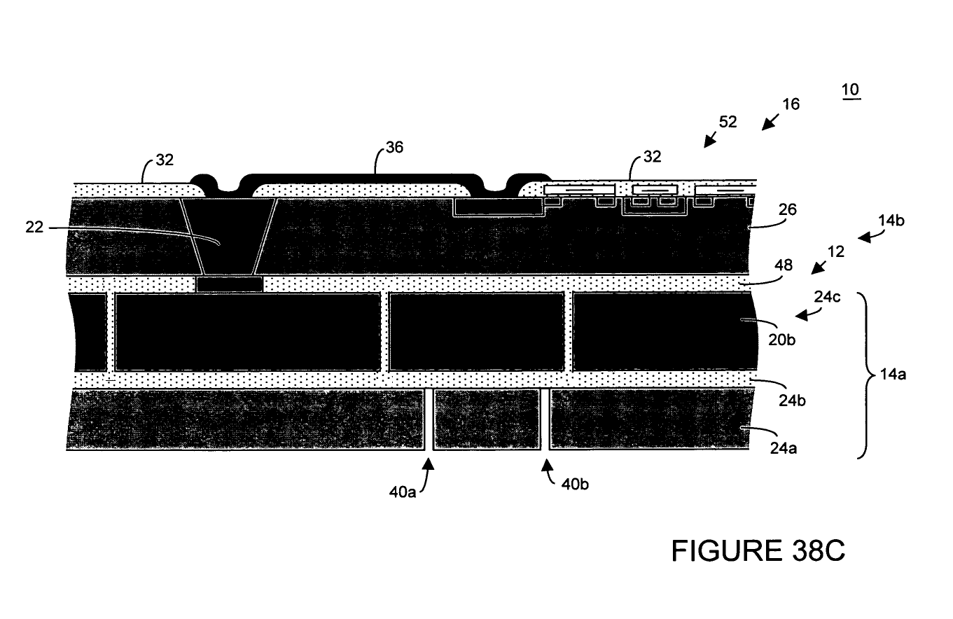

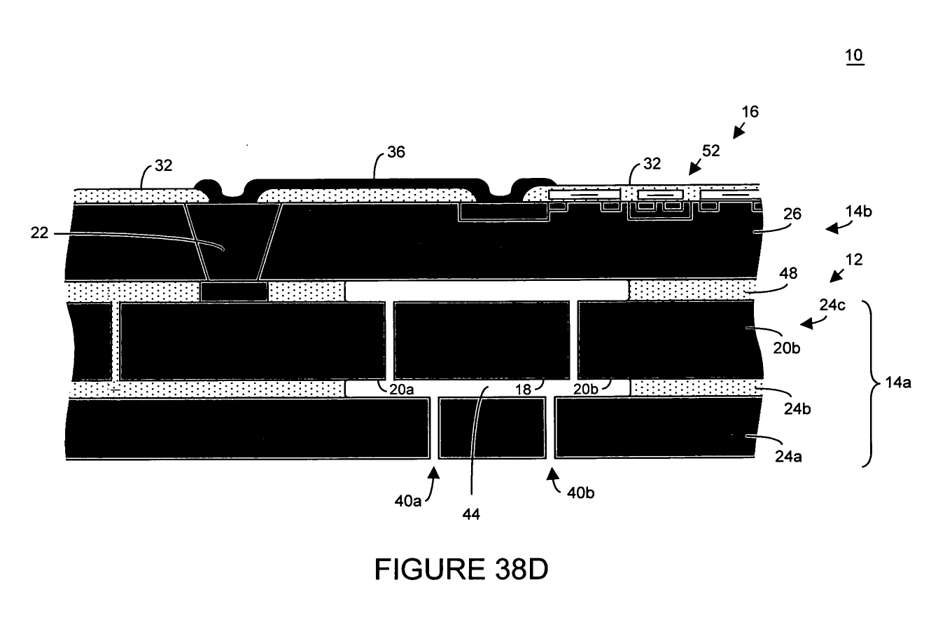

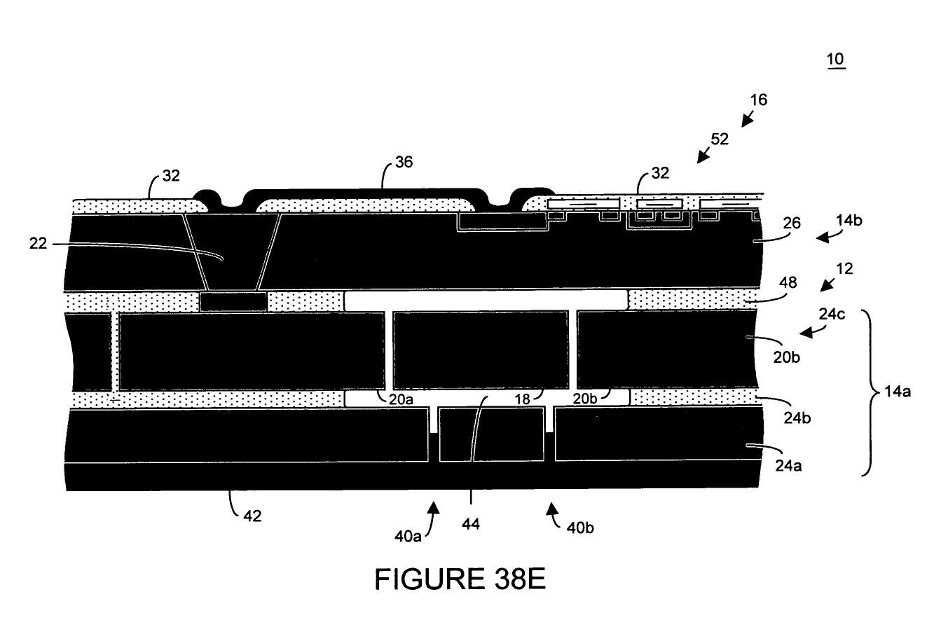

In one embodiment, prior to formation of backside vents or holes 40 and/or prior to deposition, application, formation and/or growth of sealing materials 42 in or on backside vents or holes 40, cover 26 may be fixed or secured to substrate 14. (See, for example, FIGS. 15A-15J). In another embodiment, after formation of backside vents or holes 40 and/or after deposition, application, formation and/or growth of sealing materials 42 in backside vents or holes 40, cover 26 may be fixed or secured to substrate 14. (See, for example, FIGS. 38A-38E).

For example, with reference to FIGS. 15A-15J, in one exemplary method, second substrate 14b is fixed to first substrate 14a (including, among other things, additional layers 48), before release of micromechanical structures 12 and sealing chamber 44 via sealing material 42. With reference to FIGS. 15A and 15B, the exemplary process may begin with forming mechanical structures 12 disposed on first sacrificial layer 24b, for example, a silicon dioxide or a silicon nitride material, using the same or similar techniques described in connection with FIGS. 4A-4D and 6A-6D (or any other embodiment described and illustrated herein). For the sake of brevity, those discussions will not be repeated in detail but will be summarized below in connection with this embodiment.

As noted above, mechanical structures 12, including moveable electrode 18 and fixed electrodes 20a and 20b may be formed using well-known deposition, lithographic, etching and/or doping techniques as well as from well-known materials (for example, semiconductors such as silicon, germanium, silicon-germanium or gallium-arsenide). (See, FIG. 15B).

With reference to FIG. 15C, following formation of moveable electrode 18 and fixed electrodes 20a and 20b, second sacrificial layer 48, for example, a silicon dioxide or a silicon nitride, may be deposited and/or formed to secure, space and/or protect mechanical structures 20a-d during subsequent processing. The window opening 58 may be etched or formed into second sacrificial layer 48 to facilitate electrical interconnection of mechanical structure 12 to electrical contact 22. (See, FIG. 15D). The window opening 58 may be provided using, for example, well-known masking techniques (such as a nitride mask) prior to and during deposition and/or formation of second sacrificial layer 48, and/or well-known lithographic and etching techniques after deposition and/or formation of second sacrificial layer 48.

Thereafter, contact interconnect 60 may be deposited, formed and/or grown in window opening 58 and on fixed electrode 20a. (See, FIG. 15E). The contact interconnect 60 may be comprised of one or more semiconductor materials (for example, materials in column IV of the periodic table, such as silicon, germanium, carbon, and/or combinations of these, for example, silicon germanium, or silicon carbide, and/or compounds of material in column III-V, for example, gallium phosphide, aluminum gallium phosphide, or other III-V combinations; also combinations of III, IV, V, or VI) or conductive material (for example, a metal such as aluminum). The deposition, formation and/or growth of the one or more may be by a conformal process or non-conformal process, and the material may be the same as or different from the material comprising fixed electrode 20a.

It may be advantageous to substantially planarize the exposed surface of first substrate 14a (including sacrificial layer 48 and contact interconnect 60) to provide a relatively “smooth” surface layer and/or (substantially) planar surface using, for example, polishing techniques (for example, chemical mechanical polishing (“CMP”)). In this way, the exposed planar surface of first substrate 14a may be a better prepared base upon which second substrate 14b may be fixed.

With reference to FIGS. 15F and 15G, second substrate 14b may be fixed to the exposed portion(s) of exposed surface of first substrate 14a and/or layers disposed thereon, including sacrificial layer 48 and contact interconnect 60. As noted above, second substrate 14b may be secured to the exposed portion(s) of first substrate 14a using, for example, well-known bonding techniques such as fusion bonding, anodic-like bonding and/or silicon direct bonding. Other bonding technologies are suitable including soldering (for example, eutectic soldering), thermo compression bonding, thermo-sonic bonding, laser bonding and/or glass reflow, and/or combinations thereof. Indeed, all forms of bonding, whether now known or later developed, are intended to fall within the scope of the present inventions.

A bonding material and/or a bonding facilitator material (not illustrated) may be disposed between the substrate cover and the first substrate (or layer disposed thereon or affixed thereto) to, for example, enhance the attachment of the substrates, address/compensate for planarity considerations between substrates to be bonded (for example, compensate for differences in planarity between bonded substrates), and/or to reduce and/or minimize differences in thermal expansion (that is materials having different coefficients of thermal expansion) of the substrates and materials therebetween (if any). Such materials may be, for example, solder, metals, frit, adhesives, BPSG, PSG, or SOG, or combinations thereof.

The second substrate 14b may be formed from any material now known or later developed. In a preferred embodiment, second substrate 14b includes or is formed from, for example, materials in column IV of the periodic table, for example, silicon, germanium, carbon; also combinations of these, for example, silicon germanium, or silicon carbide; also of III-V compounds for example, gallium phosphide, aluminum gallium phosphide, or other III-V combinations; also combinations of III, IV, V, or VI materials, for example, silicon nitride, silicon oxide, aluminum carbide, or aluminum oxide; also metallic silicides, germanides, and carbides, for example, nickel silicide, cobalt silicide, tungsten carbide, or platinum germanium silicide; also doped variations including phosphorus, arsenic, antimony, boron, or aluminum doped silicon or germanium, carbon, or combinations like silicon germanium; also these materials with various crystal structures, including single crystalline, polycrystalline, nanocrystalline, or amorphous; also with combinations of crystal structures, for instance with regions of single crystalline and polycrystalline structure (whether doped or undoped).

Before or after second substrate 14b is secured to the exposed portion(s) of first substrate 14a, contact 22 may be formed in a portion of second substrate 14b to be aligned with, connect to or overlie contact interconnect 60 in order to provide suitable, desired and/or predetermined electrical conductivity (for example, N-type or P-type) with fixed electrode 20a when second substrate 14b is secured to first substrate 14a. (See, FIG. 15H). The contact 22 may be formed in second substrate 14b using well-known lithographic and doping techniques. In this way, contact 22 may be a highly doped region of second substrate 14b which provides enhanced electrical conductivity with fixed electrode 20a.

Thereafter, insulating material 32 may be deposited, grown or formed, a window formed therein, and conductive material 36 (for example, a low electrical resistance material, such as a metal) may then be deposited and/or formed to provide electrical connection to contact 22 (FIG. 15I). These processing techniques (and the equipment and materials used therein) may be the same as or similar to those techniques and materials described in connection with FIGS. 4G-4J (or any other embodiment described and illustrated herein). For the sake of brevity, those discussions will not be repeated. Notably, insulation layer 32 and/or conductive layer 36 may be formed, grown and/or deposited before or after second substrate 14b is secured to the exposed portion(s) of substrate 14a (or layers/features disposed thereon or affixed thereto, for example, second sacrificial layer 48 and contact interconnect 60).

With reference to FIG. 15J, in this embodiment, mechanical structure 12 (for example, moveable electrode 18) is “released” by etching backside vents or holes 40a and 40b in first substrate layer 24a. As noted above, in one exemplary embodiment, anisotropic etching backside vents or holes 40a and 40b have a diameter or aperture size of between 0.1 μm to 10 μm, and preferably between 1 μm and 5 μm. Notably, however, all techniques for forming or fabricating vents or holes 40a and 40b, whether now known or later developed, are intended to be within the scope of the present inventions.

The backside vents or holes 40a and 40b facilitate etching and/or removal of at least selected portions of sacrificial layers 24b and 48, respectively (see, FIG. 15K) and formation of chamber 44. For example, in one embodiment, where sacrificial layers 24b and 48 are comprised of silicon dioxide, selected portions of layers 24b and 48 may be removed/etched using well-known wet etching techniques and buffered HF mixtures (i.e., a buffered oxide etch) or well-known vapor etching techniques using vapor HF. Proper design of aspects of mechanical structure 12 (for example, moveable electrode 18) and sacrificial layers 24b and 48, and control of the HF etching process parameters facilitates etching of all or substantially all of layers 24b and 48 around aspects of mechanical structure 12 and thereby releases moveable electrode 18 to permit proper operation of microelectromechanical system 10.

In another embodiment, where sacrificial layers 24b and 48, respectively, are comprised of silicon nitride, selected portions of layers 24b and 48 may be removed/etched using phosphoric acid. Again, proper design of mechanical structure 12 and sacrificial layers 24b and 48, and control of the wet etching process parameters may permit portions of sacrificial layers 24b and 48 to be etched to remove all or substantially all of sacrificial layers 24b and 48 around moveable electrode 18 and portions of fixed electrodes 20a and 20b.

It should be noted that there are: (1) many suitable materials for layers 24b and/or 48 (for example, silicon dioxide, silicon nitride, and doped and undoped glass-like materials, such as a PSG, a BPSG, and an SOG), (2) many suitable/associated etchants (for example, a buffered oxide etch, phosphoric acid, and alkali hydroxides such as, for example, NaOH and KOH), and (3) many suitable etching or removal techniques (for example, wet, plasma, vapor or dry etching), to eliminate, remove and/or etch sacrificial layers 24b and/or 48. Indeed, layers 24b and/or 48 may be a doped or undoped semiconductor (for example, polycrystalline silicon, silicon/germanium or germanium) in those instances where mechanical structure 12 is the same or similar semiconductors (i.e., processed, etched or removed similarly) provided that mechanical structure 12 is not adversely affected by the etching or removal processes (for example, where structure 12 is “protected” during the etch or removal process (e.g., an oxide layer protecting a silicon based structures 18, 20a and 20b) or where structure 12 is comprised of a material that is adversely affected by the etching or removal process of layers 24b and/or 48). Accordingly, all materials, etchants and etch techniques, and permutations thereof, for eliminating, removing and/or etching, whether now known or later developed, are intended to be within the scope of the present inventions.

Notably, fixed electrode 20a and/or 20b may remain partially, substantially or entirely surrounded by sacrificial layers 24b and/or 48. For example, with reference to FIG. 15J, while moveable electrode 18 is released from its respective underlying sacrificial layers 24b and/or 48 beneath or underlying structures 20a and 20b may provide additional physical support.

With reference to FIG. 15L, after releasing mechanical structure 12 (for example, moveable electrode 18), sealing materials 42 may be deposited, applied, formed and/or grown to seal chamber 44. The one or more sealing materials 42 may be deposited, applied, formed and/or grown (i) on first substrate material 24a and/or (ii) over and/or in backside vents or holes 40.

As noted above, sealing material 42 may be any material that may be deposited, applied, formed and/or grown (i) on first substrate material 24a and/or (ii) over and/or in backside vents or holes 40 to seal chamber 44 including, for example, spin on materials such as polymers, plasma deposited materials such as a silicon oxide, a silicon nitride and/or TEOS. The one or more sealing materials 42 may be and/or include an adhesive, a paste, a solder, a metal, for example, a material that facilitates mechanical or electrical connection of system 10 to a frame (for example, lead frame) or substrate (for example, a circuit board or rigid platform).

Further, the one or more sealing materials 42 may be a silicon material, for example, a monocrystalline silicon, polycrystalline silicon, amorphous silicon or porous polycrystalline silicon (whether doped or undoped), germanium, silicon/germanium, silicon carbide, and gallium arsenide (and combinations thereof. The silicon may be deposited using, for example, an epitaxial, a sputtering or a CVD-based reactor (for example, LPCVD) process (in a tube or EPI reactor) or plasma enhanced PECVD process and sealing material 42 may be a doped polycrystalline silicon deposited using an atmospheric pressure APCVD process). The deposition, formation and/or growth may be by a conformal process or non-conformal process. The material may be the same as or different from first substrate layer 24a. However, it may be advantageous to employ the same material to, for example, closely “match” the thermal expansion rates of first substrate layer 24a and sealing material 42. Notably, all materials and deposition, growth, application and/or formation techniques for encapsulating or sealing chamber 44, whether now known or later developed, are intended to be within the scope of the present inventions.

The sealing material 42 may include one or more materials and/or layers thereof. For example, the encapsulation or sealing process of chamber 44 may include two or more sealing materials of the same or different materials. In this regard, a first sealing material may be deposited to partially or fully seal or close backside vents or holes 40. Thereafter, a second sealing material may be deposited on the first sealing material to more fully seal or close backside vents or holes 40. (See, for example, FIGS. 5A-5C). In one exemplary embodiment, the second sealing material may be a semiconductor material (for example, silicon, silicon carbide, silicon-germanium or germanium) or metal bearing material (for example, silicides or TiW), which is deposited using, for example, an epitaxial, a sputtering or a CVD-based reactor (for example, APCVD, LPCVD or PECVD). The deposition, formation and/or growth may be by a conformal process or non-conformal process. Notably, more than two materials may be employed to seal or close backside vents or holes 40. (See, for example, FIGS. 5D and 5E). Again, all materials and deposition techniques of sealing material 42 to encapsulate or seal chamber 44, whether now known or later developed, are intended to be within the scope of the present inventions.

As noted above, in conjunction with encapsulating or sealing chamber 44, the atmosphere (including its characteristics) in which moveable electrode 18 operates may also be defined while encapsulating or sealing chamber 44 or thereafter. In this regard, the atmosphere in chamber 44 may be defined when one or more sealing materials 42 are deposited, applied, formed and/or grown (i) on first substrate material 24a and/or (ii) over and/or in backside vents or holes 40, or after further processing (for example, an annealing step may be employed to adjust the pressure). Notably, all techniques of defining the atmosphere, including the pressure thereof, during the process of encapsulating or sealing chamber 44, whether now known or later developed, are intended to be within the scope of the present inventions.

For example, sealing materials 42 are deposited, applied, formed and/or grown in a nitrogen, oxygen and/or inert gas environment (for example, helium). The pressure of the fluid (gas or vapor) may be selected, defined and/or controlled to provide a suitable and/or predetermined pressure of the fluid in chamber 44 immediately after encapsulating or sealing chamber 44, after one or more subsequent processing steps (for example, an annealing step) and/or after completion of micromachined mechanical structure 12 and/or microelectromechanical system 10.

Notably, the gas(es) employed during these processes may provide predetermined reactions (for example, oxygen molecules may react with silicon to provide a silicon oxide); all such techniques, gasses and/or materials are intended to fall within the scope of the present inventions.

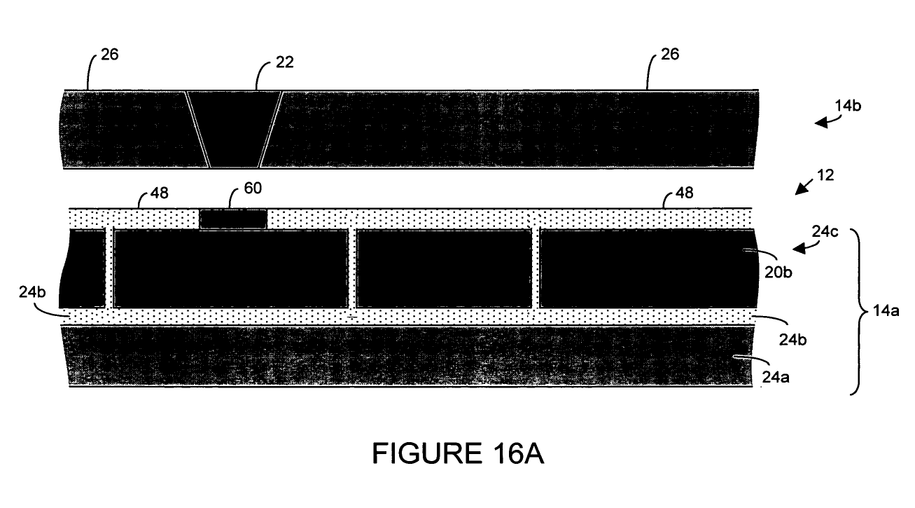

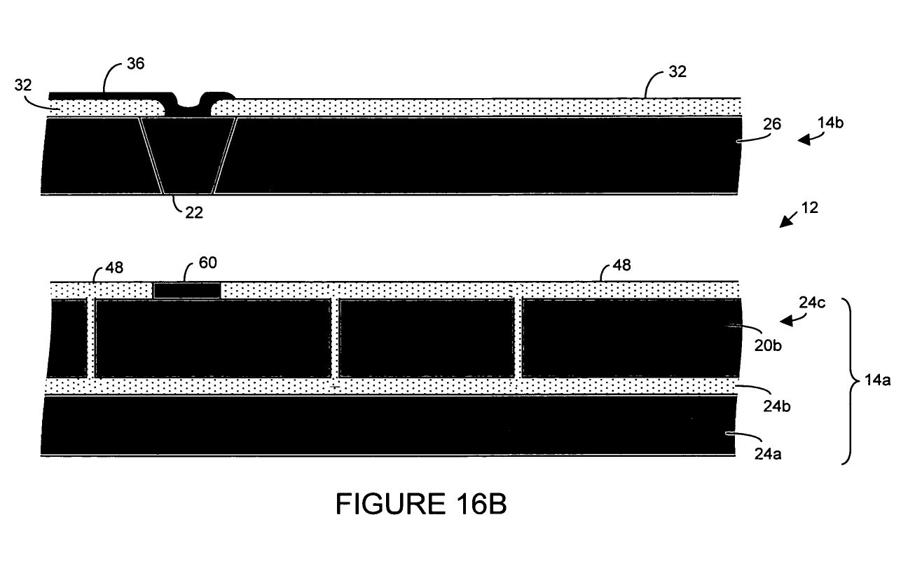

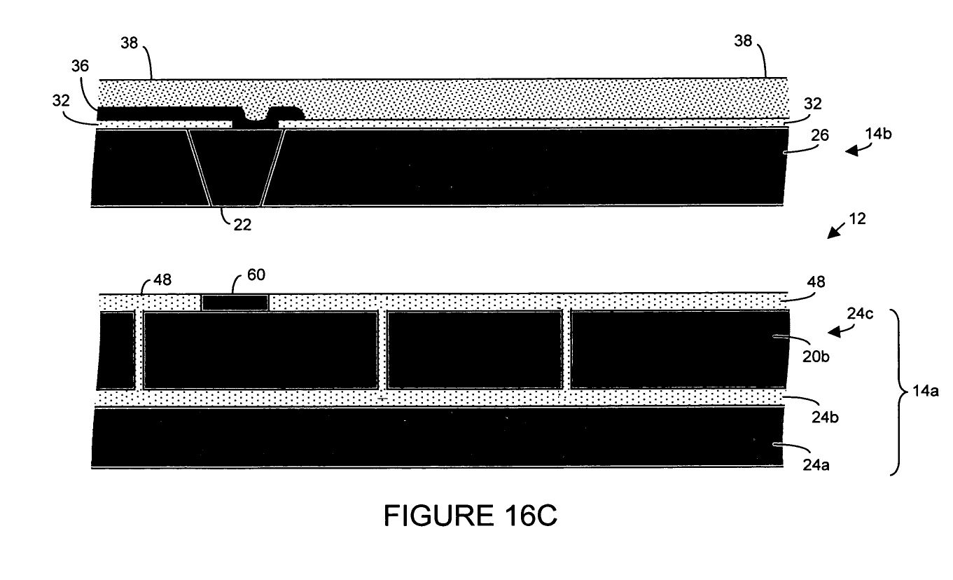

As mentioned above, when cover substrate 14b is fixed to the exposed portion(s) of exposed surface of first substrate 14a and/or layer disposed thereon, including sacrificial layer 48 and contact interconnect 60, cover substrate 14b may already include (i) contact 22, and (ii) insulation layer 32, conductive layer 36, and/or passivation layer 38 formed therein. (See, for example, FIGS. 16A-16C).

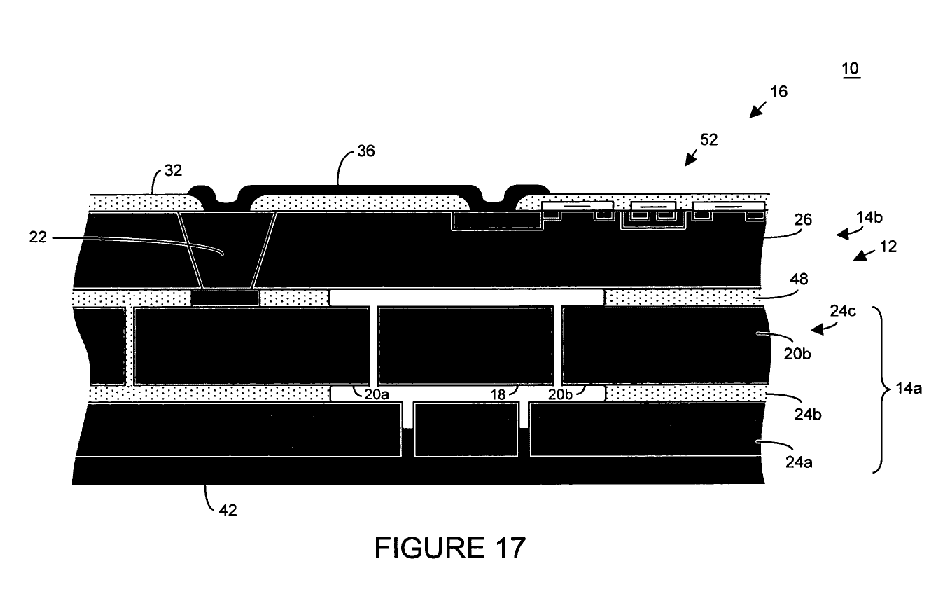

With reference to FIG. 17, it may be advantageous to include circuitry 16 in or on second substrate 14b. For example, the illustrative embodiments of FIGS. 14 and 16A-16C may further include circuitry 16 which is disposed in second substrate 14b. The circuitry 16 may be fabricated using the same or similar techniques as described above with reference to FIGS. 9, 11 and 13. The circuitry 16 may be fabricated (in whole or in part), prior to or after securing second substrate 14b to first substrate 14a. Moreover, circuitry 16 may be fabricated (in whole or in part) prior to or after formation, deposition and/or growth of (i) insulation layer 32 and/or conductive layer 34, or (ii) additional micromachined mechanical structures 12 (disposed on second substrate 14b).

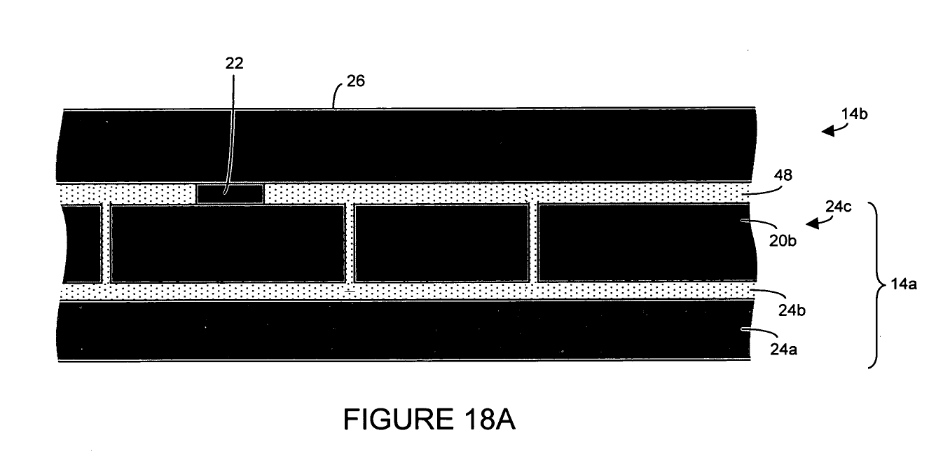

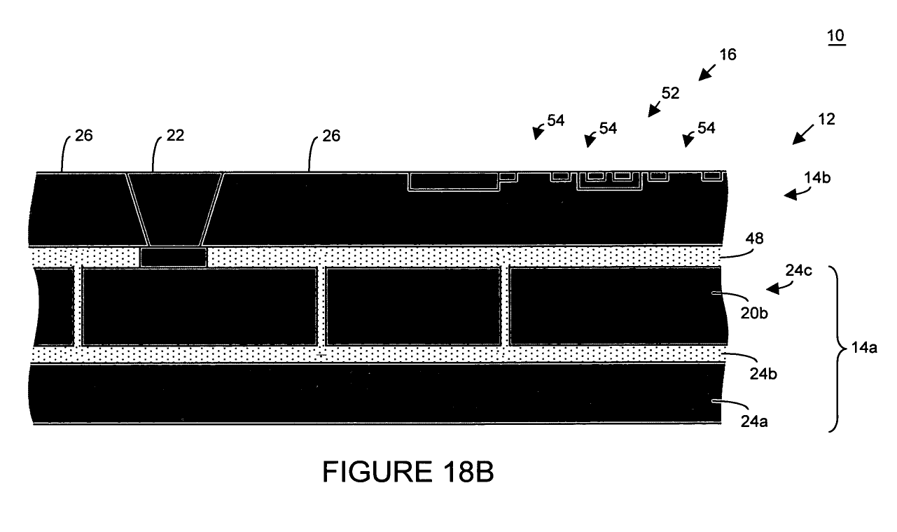

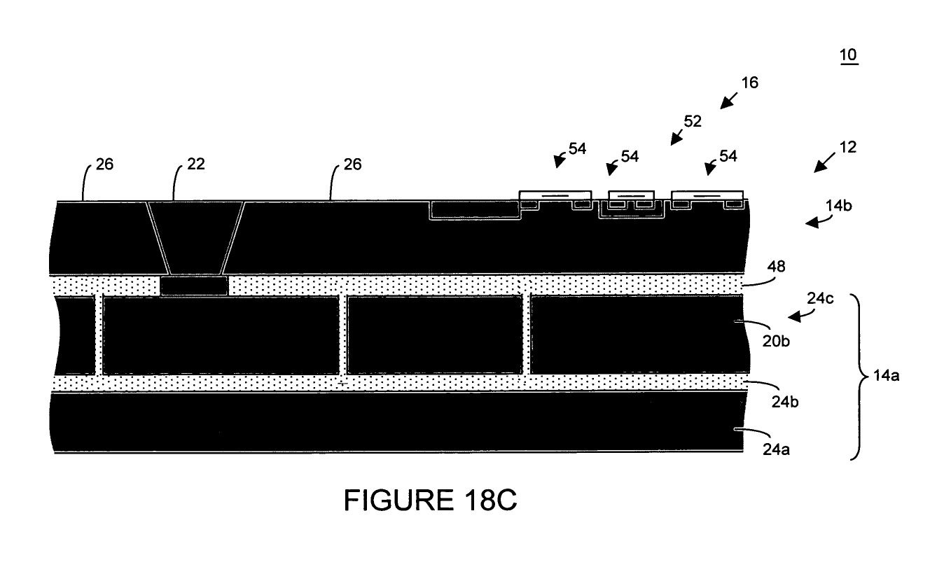

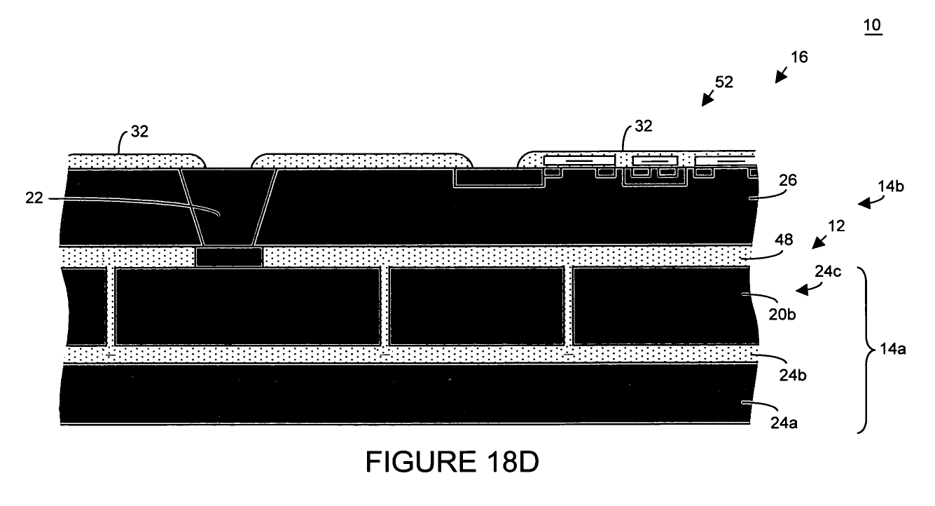

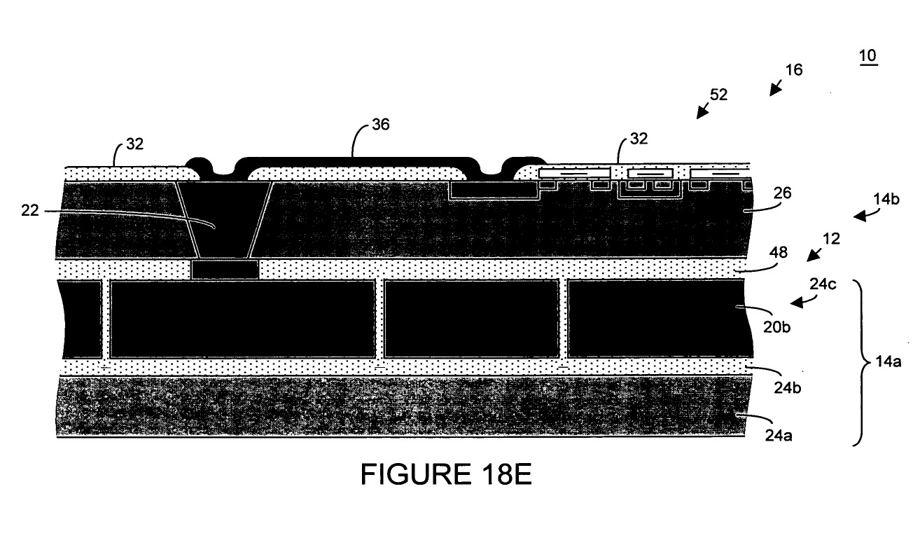

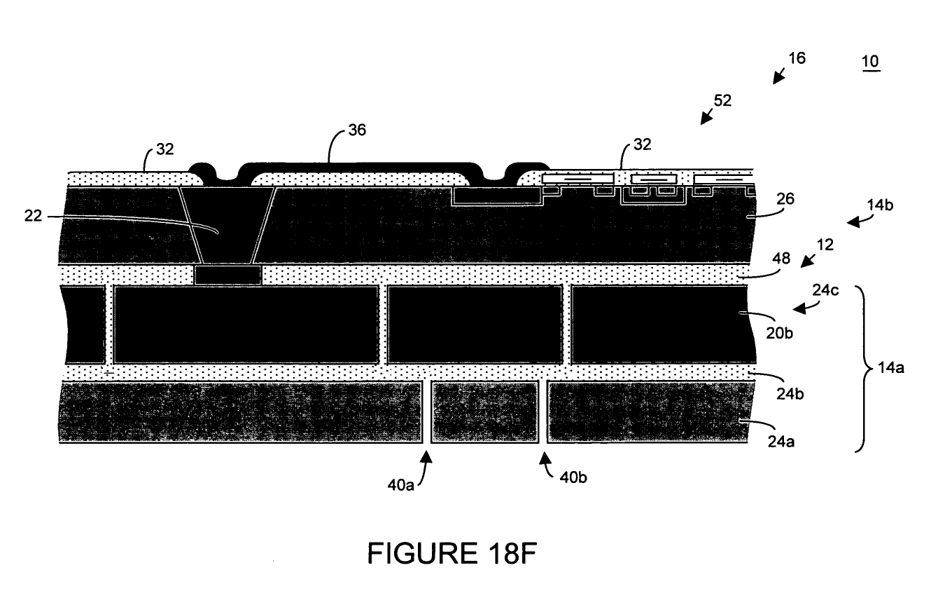

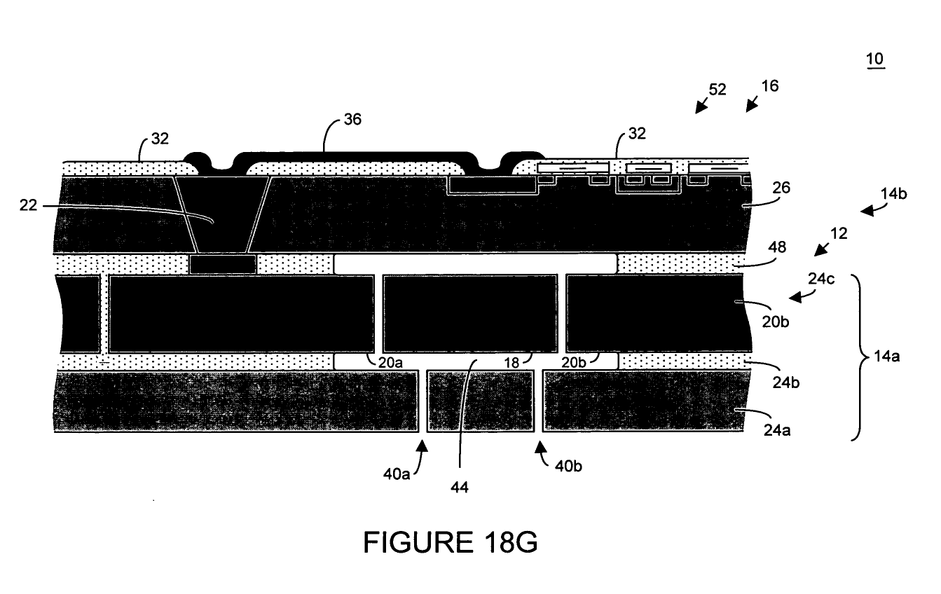

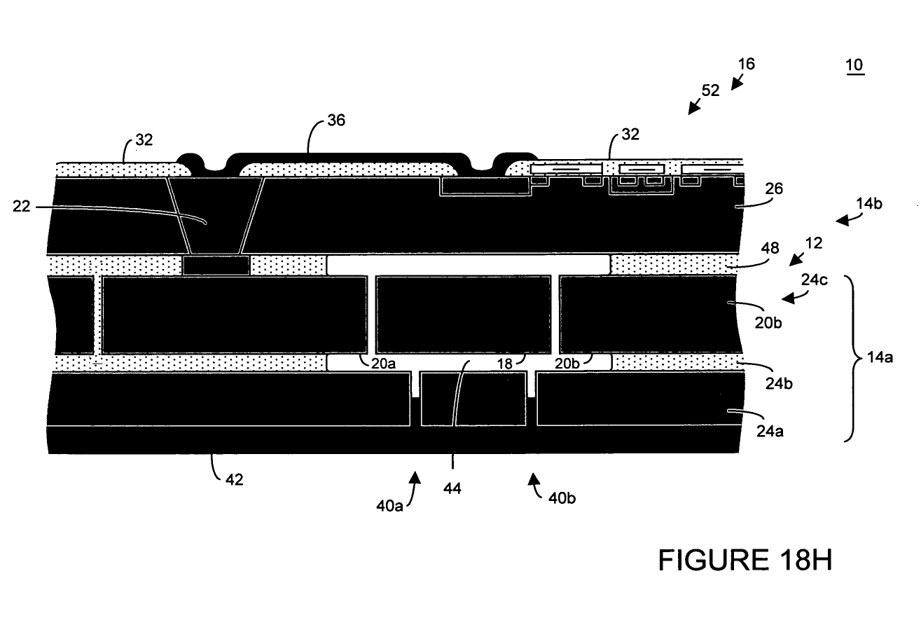

For example, in one embodiment, circuitry 16 may be fabricated in/on second substrate 14b after securing second substrate 14b to the exposed surfaces of first substrate 14a (for example, layers disposed thereon such as second sacrificial layer 48 and contact interconnect 60) and prior to release of micromechanical structures 12 or sealing chamber 44 via sealing material 42. (See, for example, FIGS. 18A-18F).

In particular, with reference to FIGS. 18B and 18C, after securing second substrate 14b to first substrate 14a, conventional transistor and integrated circuit processing (for example, formation of transistor implants 54, of gates, and gate insulators) may be employed to complete the transistors of circuitry 16. For example, conventional transistor processing (for example, formation of gate and gate insulator) may be employed to complete the transistor implants 54 of transistor regions 52 of circuitry 16.

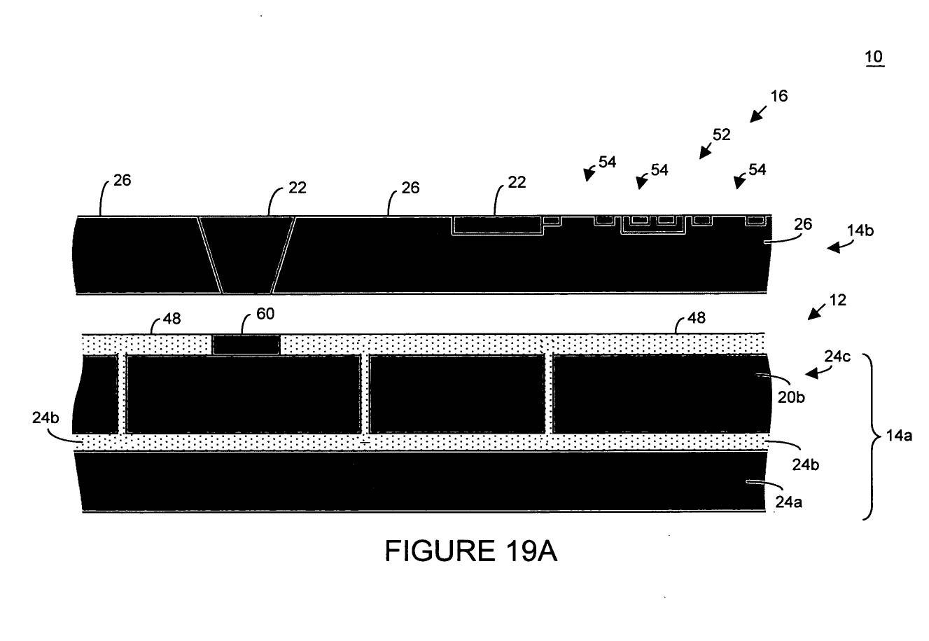

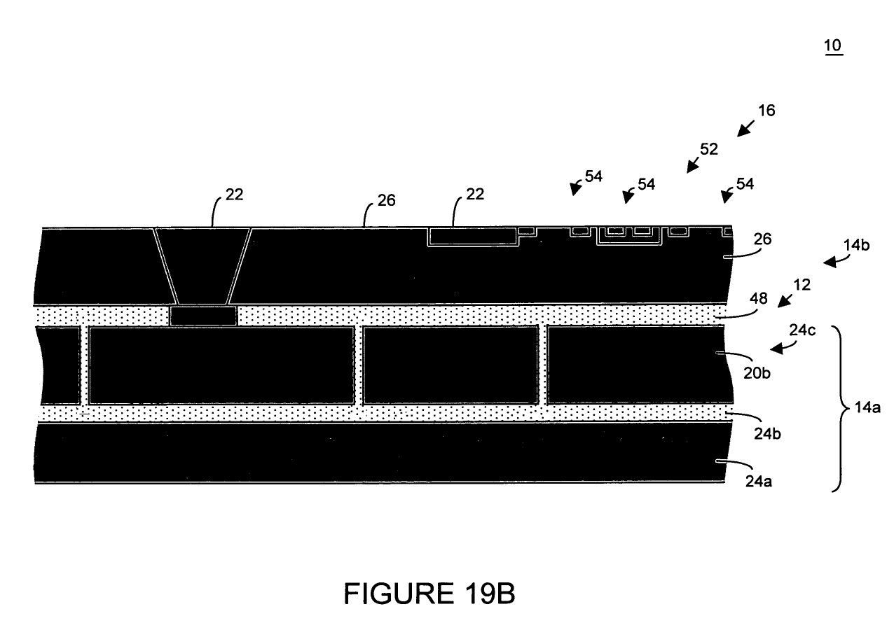

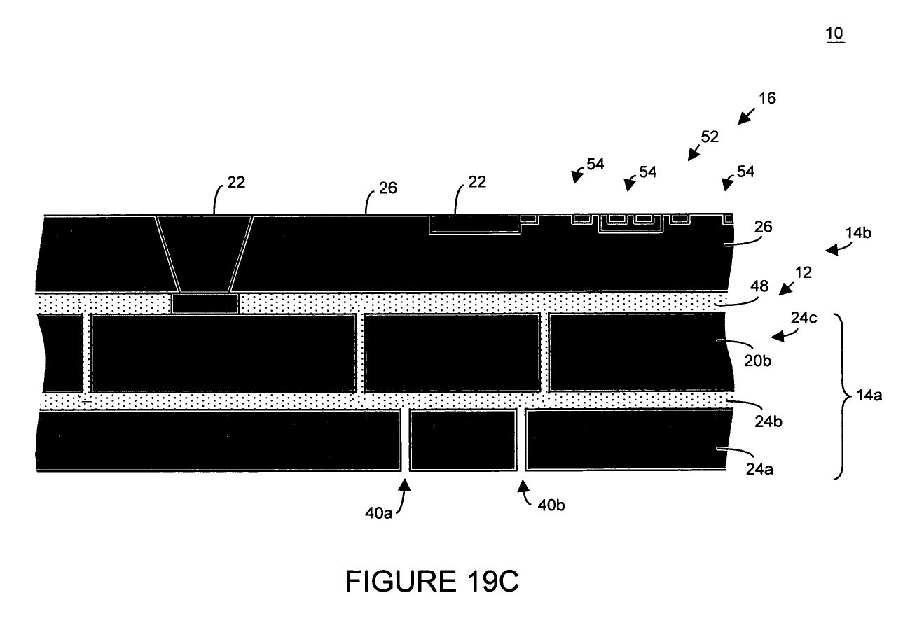

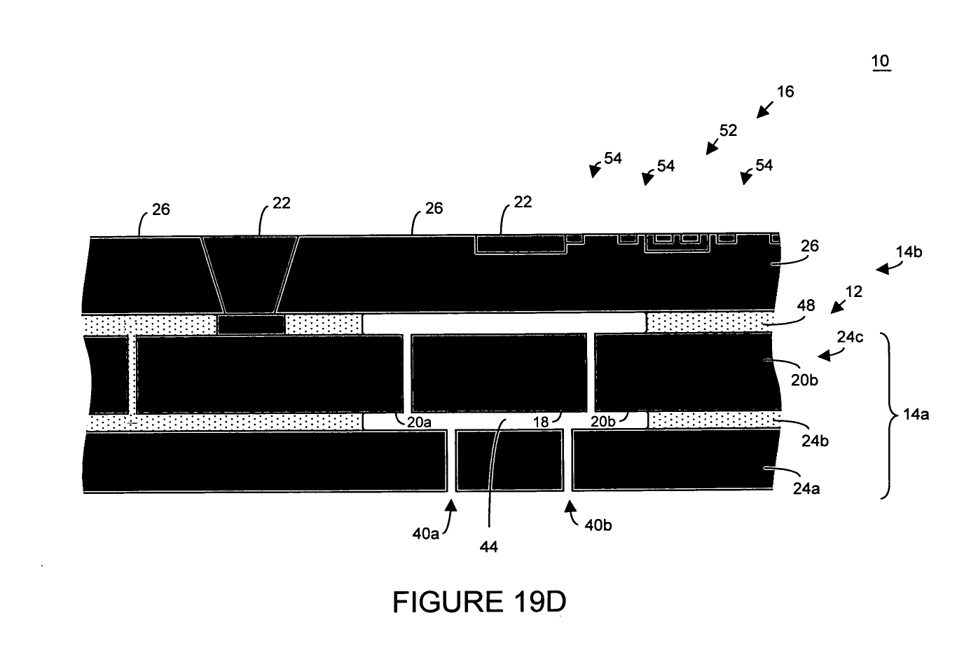

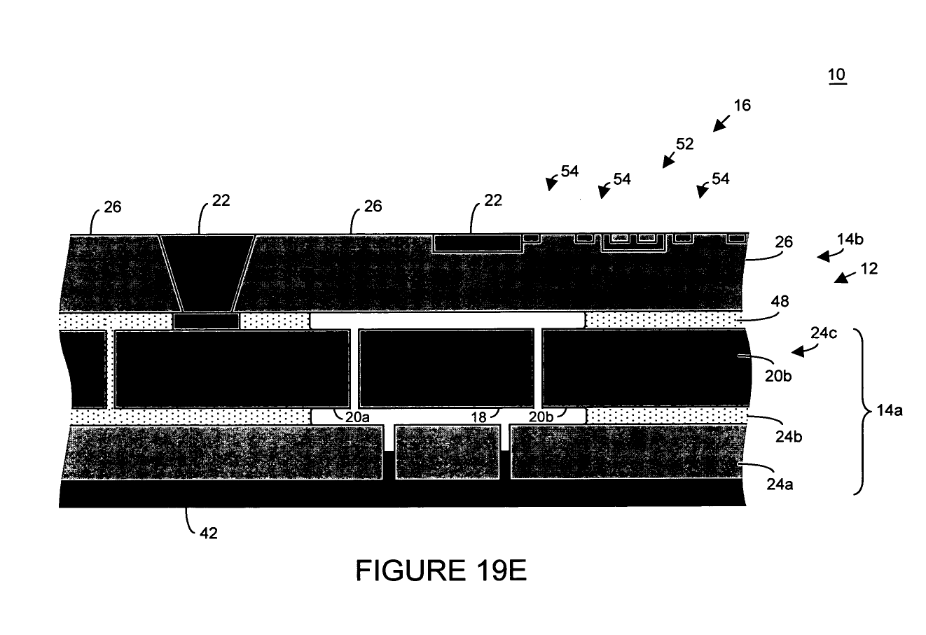

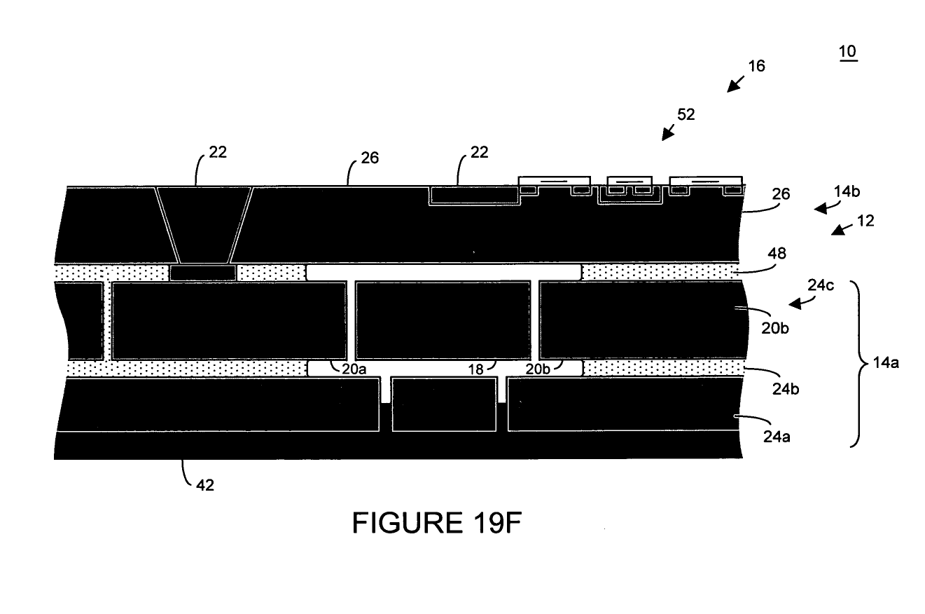

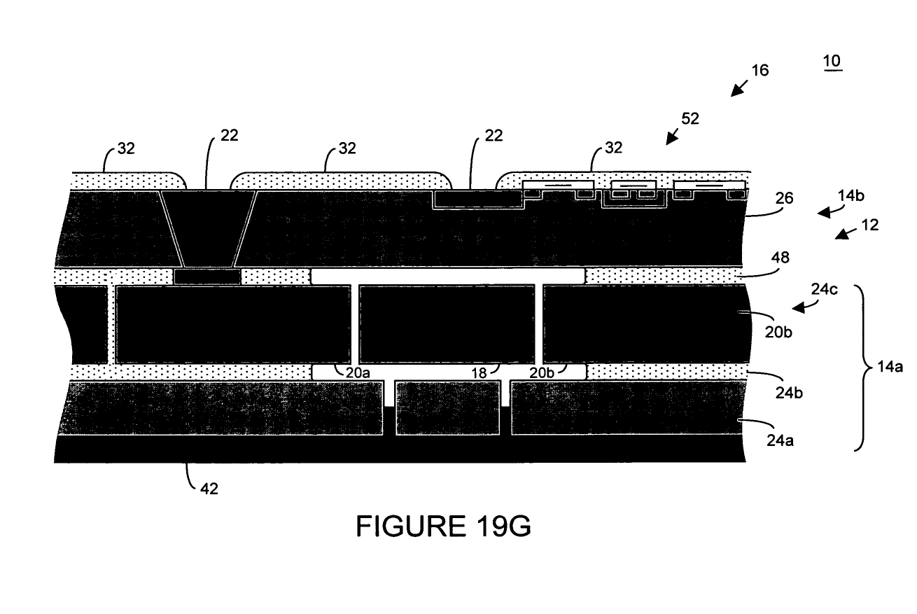

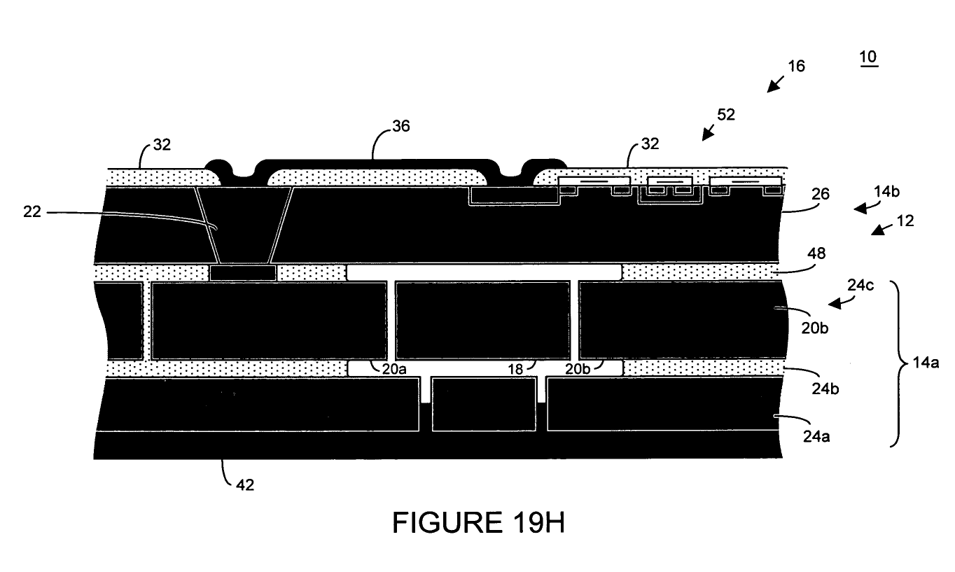

Following transistor fabrication insulation layer 32 may be deposited, formed and/or grown and thereafter patterned. (See, FIG. 19D). As noted above, insulating layer 32 may be, for example, silicon dioxide, silicon nitride, BPSG, PSG, or SOG, or combinations thereof. It may be advantageous to employ a silicon nitride because a silicon nitride may be deposited in a more conformal manner than a silicon oxide. Moreover, a silicon nitride is compatible with CMOS processing, in the event that microelectromechanical system 10 includes CMOS integrated circuits.

A conductive layer 36 (for example, a metal (such as aluminum, chromium, gold, silver, molybdenum, platinum, palladium, tungsten, titanium, and/or copper), metal stacks, complex metals and/or complex metal stacks) may be deposited and/or formed on insulating layer 32. (See, for example, FIG. 18E). In the illustrative embodiments, transistors of circuitry 16 access contact 22 via conductive layer 36. The conductive layer 36 may be a low resistance electrical path that is deposited and patterned to facilitate connection of micromachined mechanical structure 12 and circuitry 16.

Thereafter, mechanical structure 12 (for example, moveable electrode 18) may be released by first etching backside vents or holes 40a and 40b in first substrate layer 24a, using, for example, anisotropic etching (see, FIG. 18F) and then etching and/or removal of at least selected portions of sacrificial layers 24b and 48, using any of the techniques and materials described herein (see, FIG. 18G). The sealing materials 42 may be deposited, applied, formed and/or grown on first substrate material 24a and/or over and/or in backside vents or holes 40. (See, FIG. 18H). The materials and techniques employed to deposit, apply, form and/or grow sealing materials 42 may be the same as or similar to any described in connection with FIGS. 4, 5 and 6. Again, for the sake of brevity, those discussions will not be repeated.

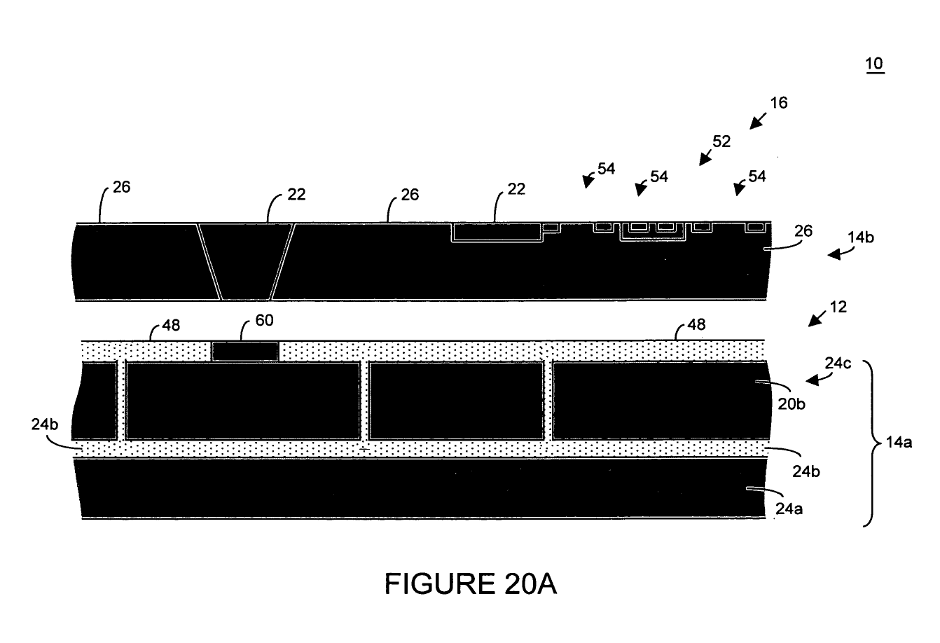

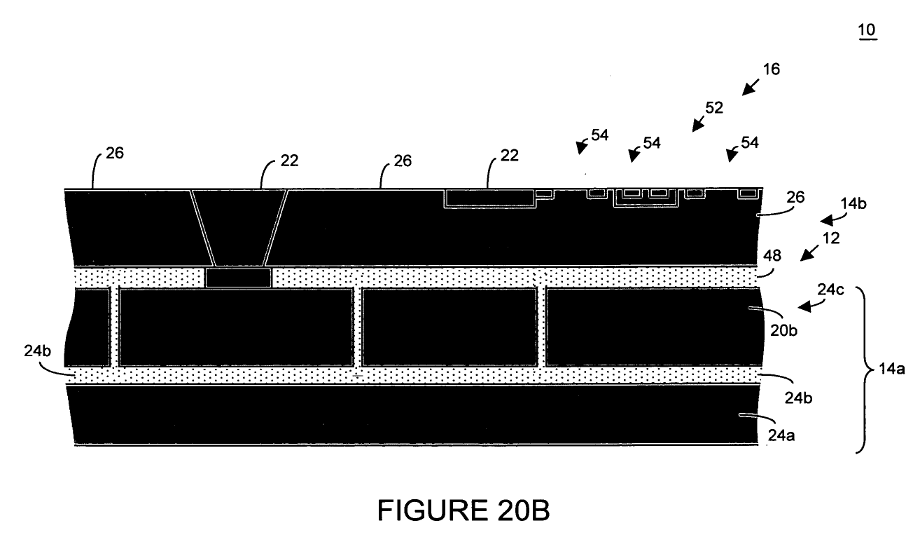

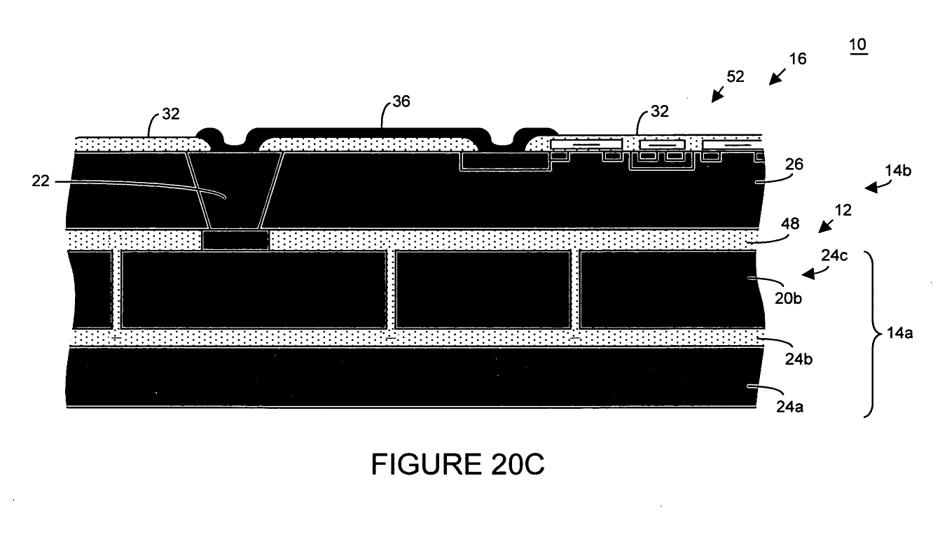

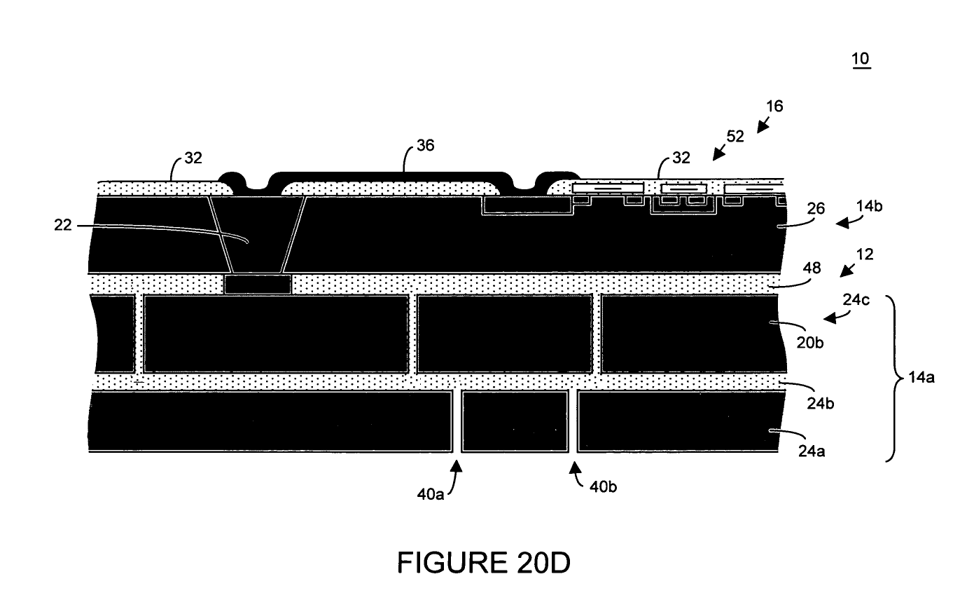

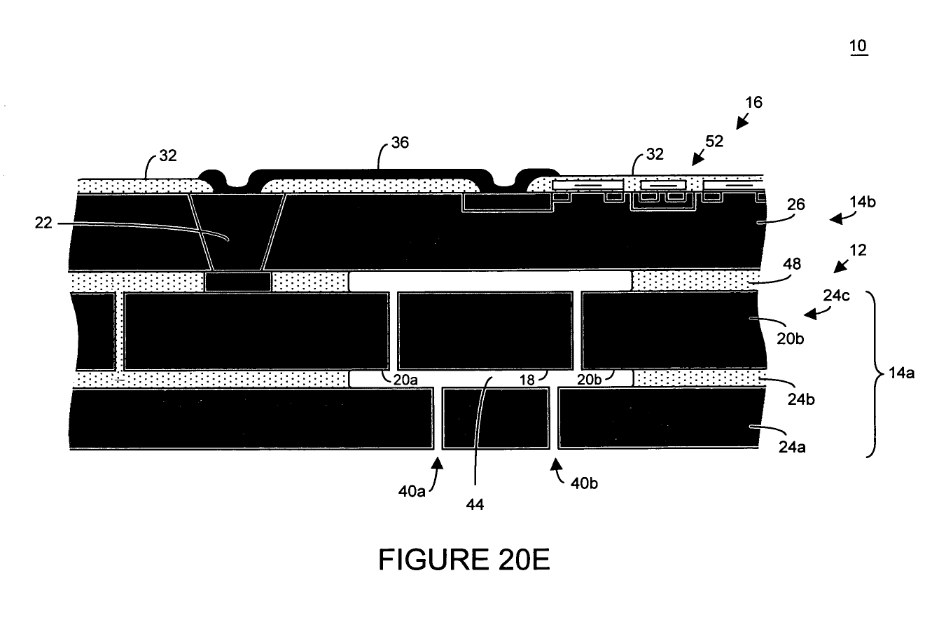

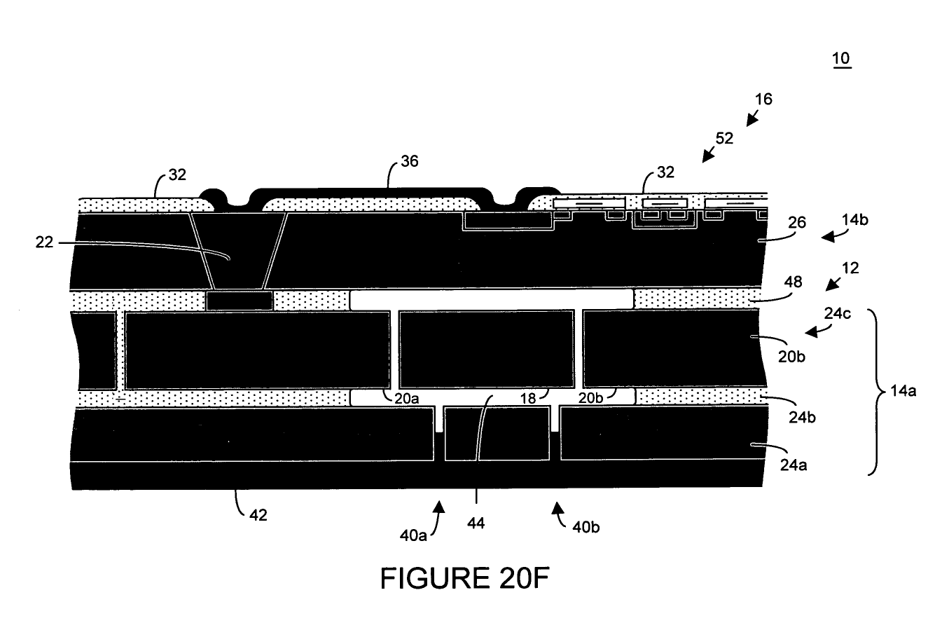

In another exemplary embodiment, with reference to FIG. 19A, circuitry 16 may be fabricated (in part) prior to securing second substrate 14b to first substrate 14a. After securing second substrate 14b to first substrate 14a (for example, bonded), as described above, the fabrication of circuitry 16 may be completed after release of micromechanical structures 12 and/or sealing chamber 44 via sealing material 42 (see, for example, FIGS. 19B-19H). In yet another exemplary embodiment, circuitry 16 again may be fabricated (in part) prior to securing second substrate 14b to first substrate 14a and after securing second substrate 14b to first substrate 14a (for example, bonded), as described above, the fabrication of circuitry 16 may be completed before release of micromechanical structures 12 and/or sealing chamber 44 via sealing material 42 (see, for example, FIGS. 20A-20F). Again, these embodiments may employ any of the techniques, materials or alternatives discussed herein (for example, employing a plurality of sealing materials and/or a passivation layer as illustrated in FIGS. 4, 5 and 6, and described herein). For the sake of brevity, those discussions will not be repeated.

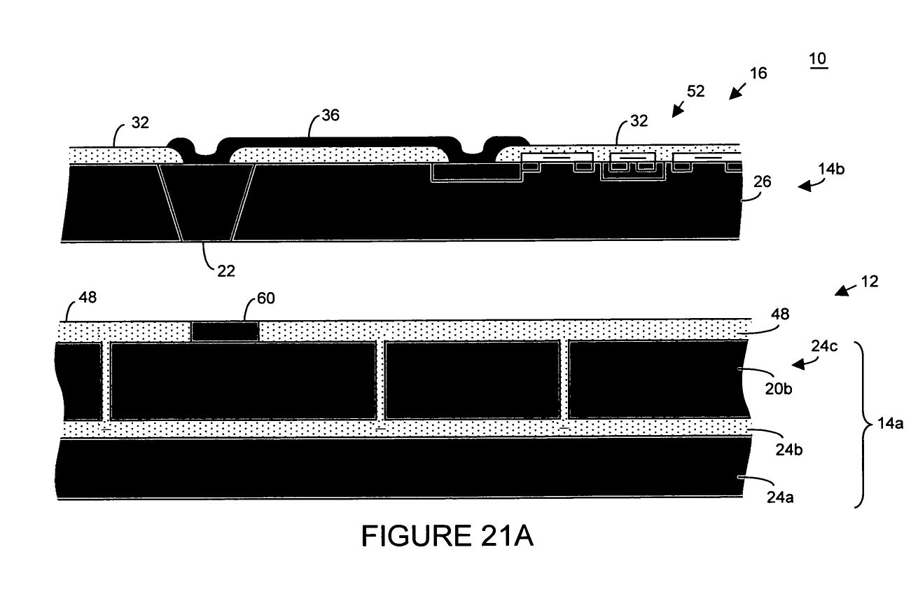

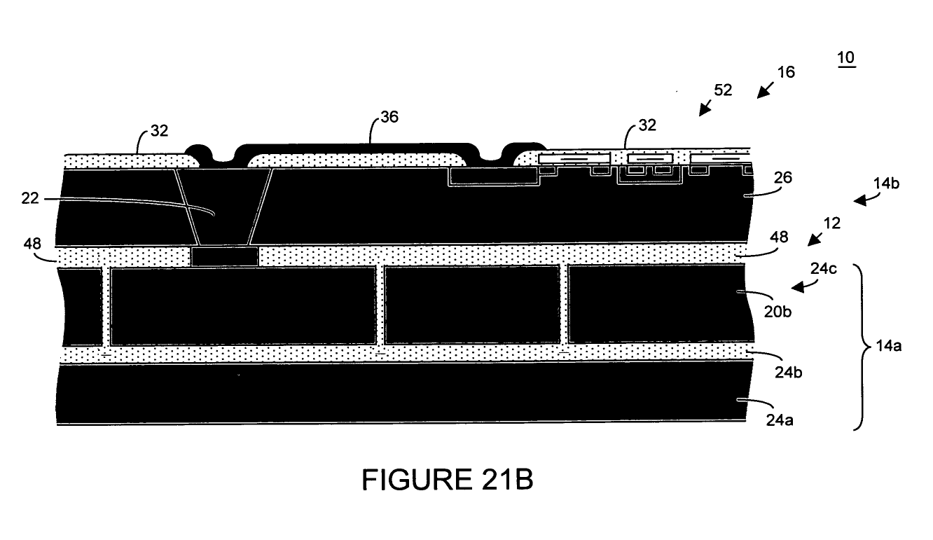

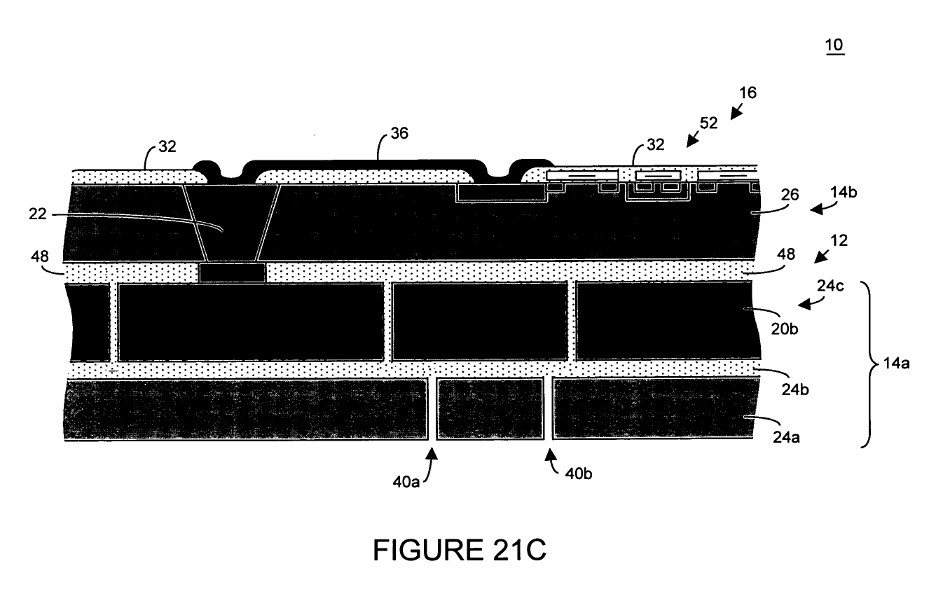

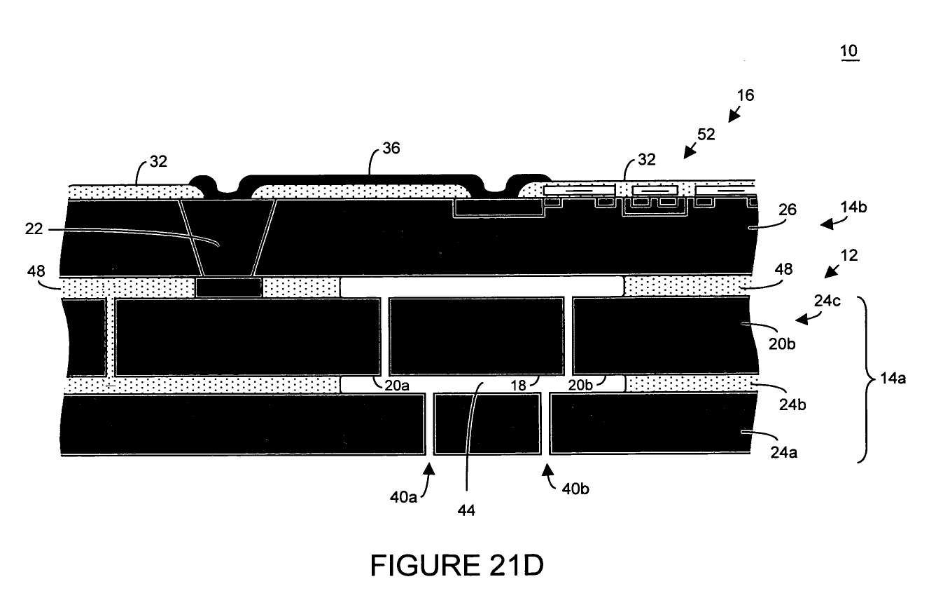

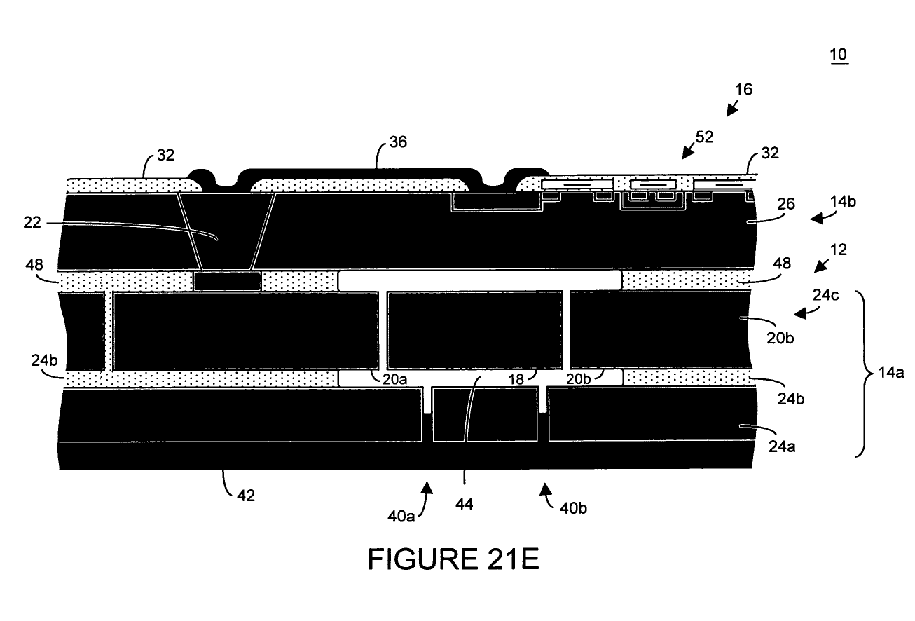

Indeed, in another exemplary embodiment, circuitry 16 may be fabricated in total in/on second substrate 14b before securing second substrate 14b to first substrate 14a (or layer(s) disposed thereon or affixed thereto). The second substrate 14b may be secured to first substrate 14a (for example, bonded) as described above. With reference to FIGS. 21A and 21B, in this embodiment, circuitry 16 is complete or substantially complete before securing second substrate 14b to first substrate 14a. Thereafter, micromechanical structures 12 may be released (see, FIGS. 21C and 21D) and sealing material 42 may be deposited (see, for example, FIG. 21E). These embodiments may employ any of the techniques, materials or alternatives discussed herein (for example, employ a plurality of sealing materials as illustrated in FIGS. 4, 5 and 6). For the sake of brevity, those discussions will not be repeated. Thus, in this embodiment, mechanical structure 12 is released and encapsulated in chamber 44 using any of the techniques described herein, for example, those techniques of FIGS. 4, 5 and/or 6, after securing second substrate 14b, which includes complete or substantially complete circuitry, to first substrate 14a. For the sake of brevity, those discussions will not be repeated.

Notably, the present inventions may be implemented in conjunction with any of the embodiments described and illustrated in U.S. Non-Provisional patent application Ser. No. 11/336,521, which was filed by Partridge et al. on Jan. 20, 2006 and entitled “Wafer Encapsulated Microelectromechanical Structure and Method of Manufacturing Same” (hereinafter “the Wafer Encapsulated Microelectromechanical Structure patent Application”). In this regard, the release and encapsulation techniques of the present inventions may be implemented in conjunction with any of the substrate bonding architectures, structures, processes and/or configurations described and illustrated in the Wafer Encapsulated Microelectromechanical Structure patent Application. The entire contents of the Wafer Encapsulated Microelectromechanical Structure patent Application, including, for example, the inventions, features, attributes, architectures, configurations, materials, techniques and advantages described and illustrated therein, are incorporated by reference herein. For the sake of brevity, those discussions will not be repeated; rather those discussions (text and illustrations), including the discussions relating to the process and/or structure, are incorporated by reference herein in its entirety.

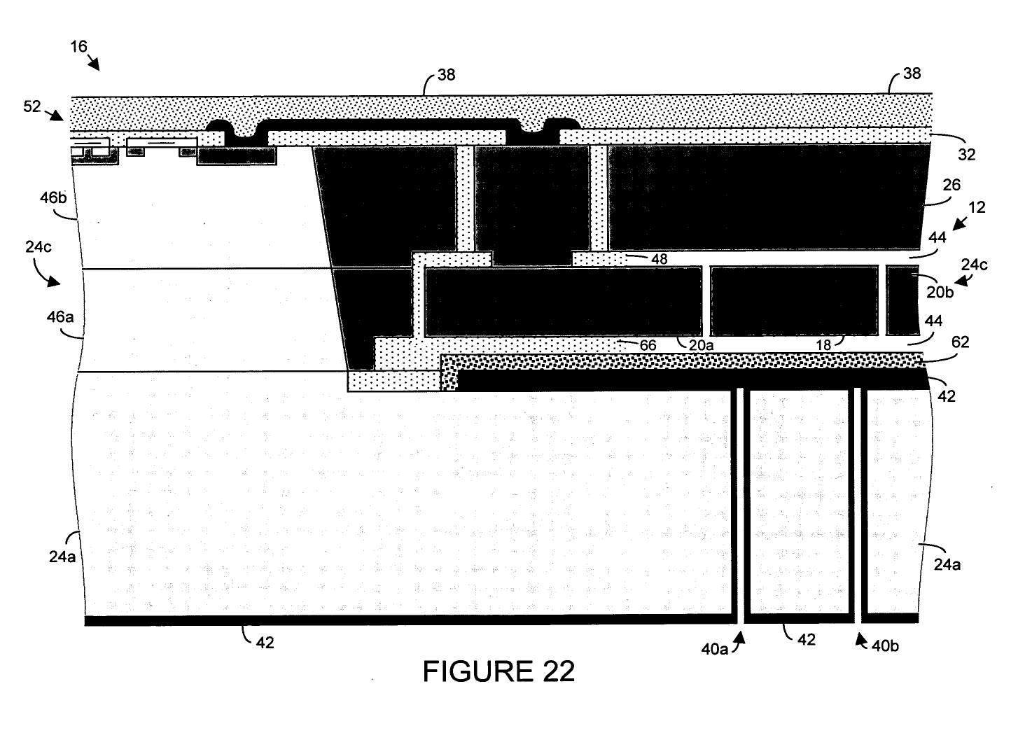

In another set of embodiments, with reference to FIG. 22, microelectromechanical system 10 may include sealing layer screen 62 which provides a barrier or obstacle sealing material 42 from collecting on any of the structures of micromachined mechanical structure 12 during deposition, application, formation and/or growth of sealing materials 42 (i) on first substrate material 24a and/or (ii) over and/or in backside vents or holes 40, material of sealing layer 42. In this regard, during deposition, application, formation and/or growth of sealing materials 42, sealing layer screen 62 minimizes, reduces or eliminates sealing material 42 from entering chamber 44. As such, the time required to seal or close chamber 44 may be reduced. In addition, sealing layer screen 62 may prevent or minimize such material (for example, one or more monolayers) from forming or collecting on electrodes 18 and/or 20; thereby reducing the probability that deposition, formation and/or application of sealing material 42 may adversely impact the performance or operation of micromachined mechanical structure 12 by forming or collecting on electrodes 18 and/or 20.

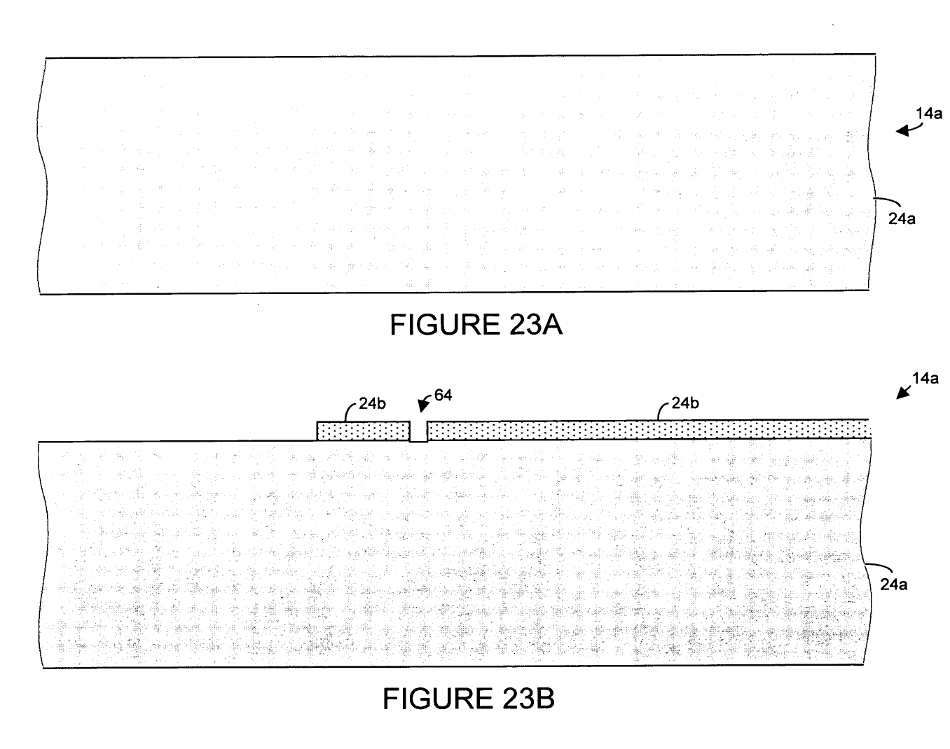

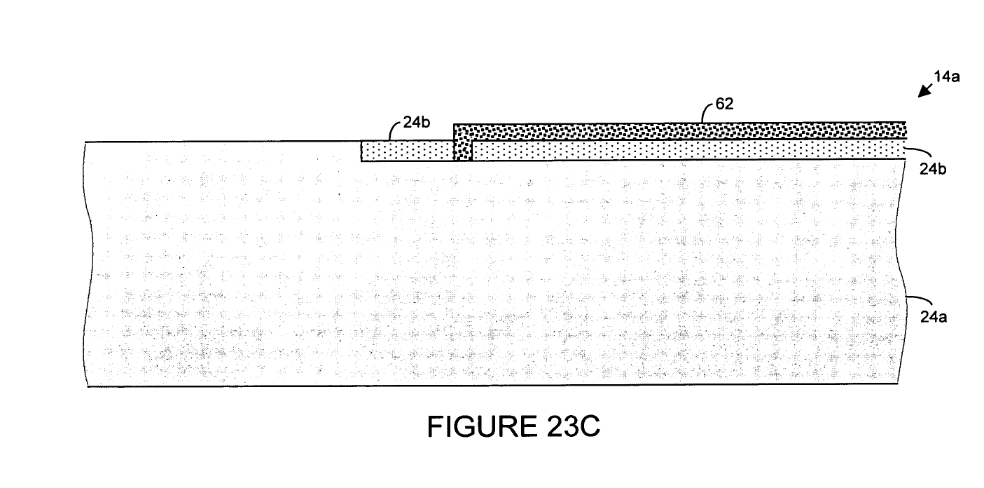

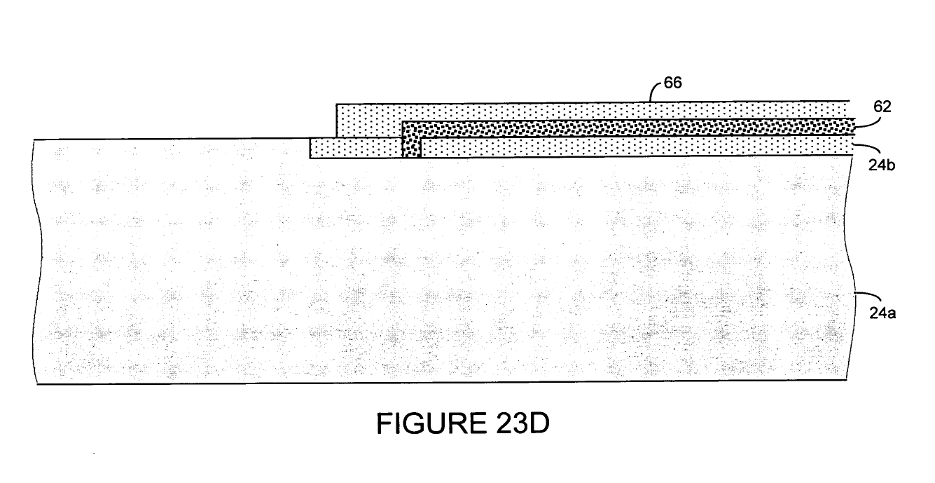

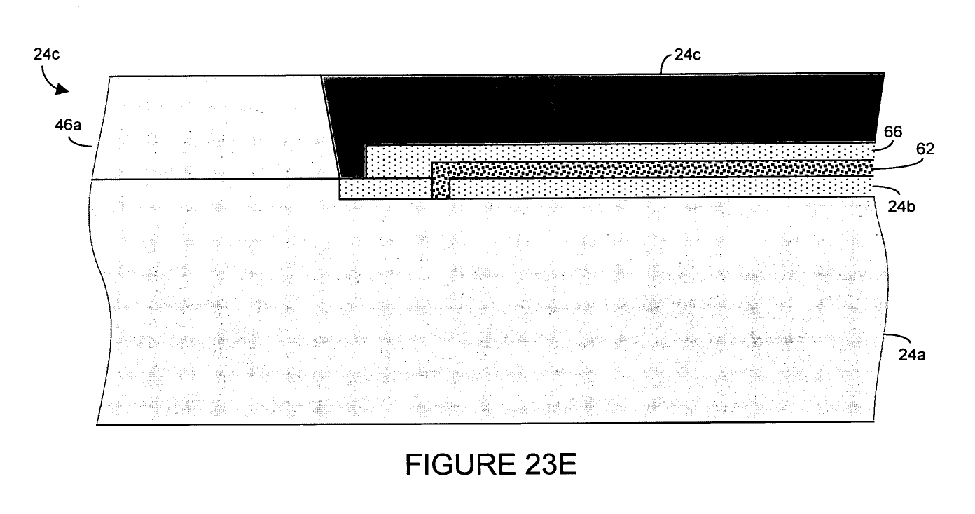

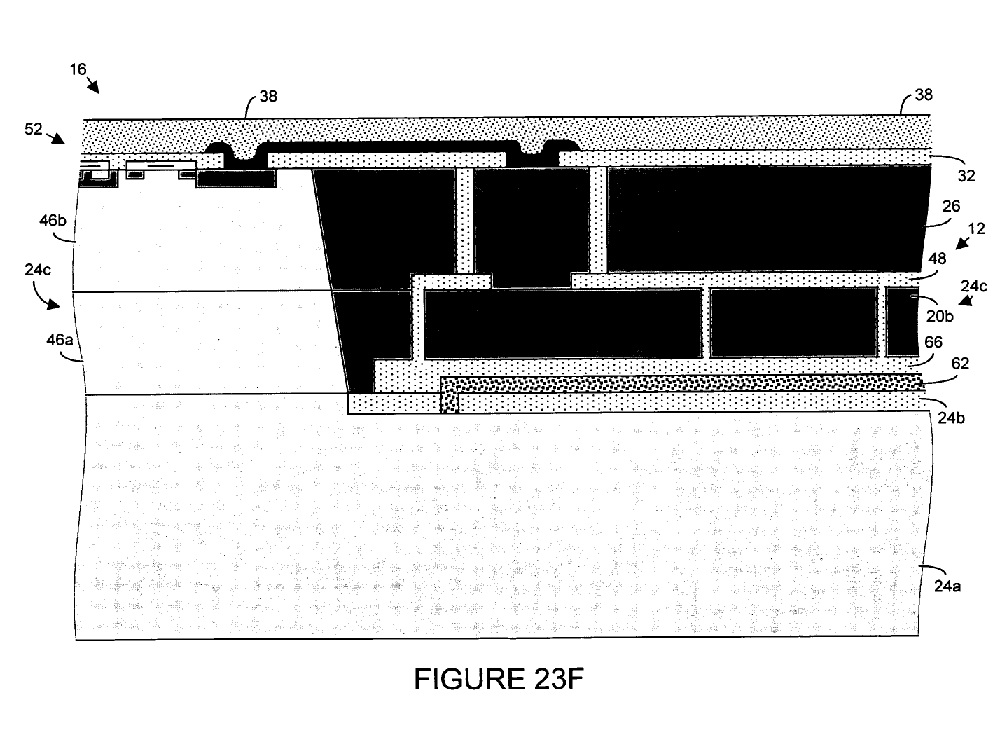

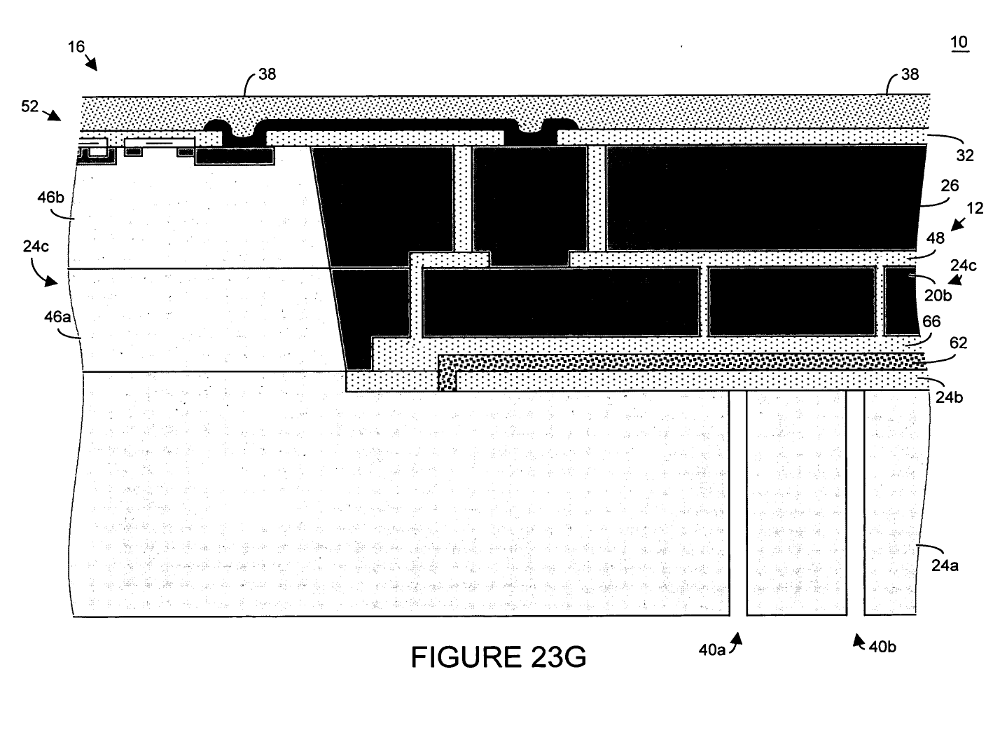

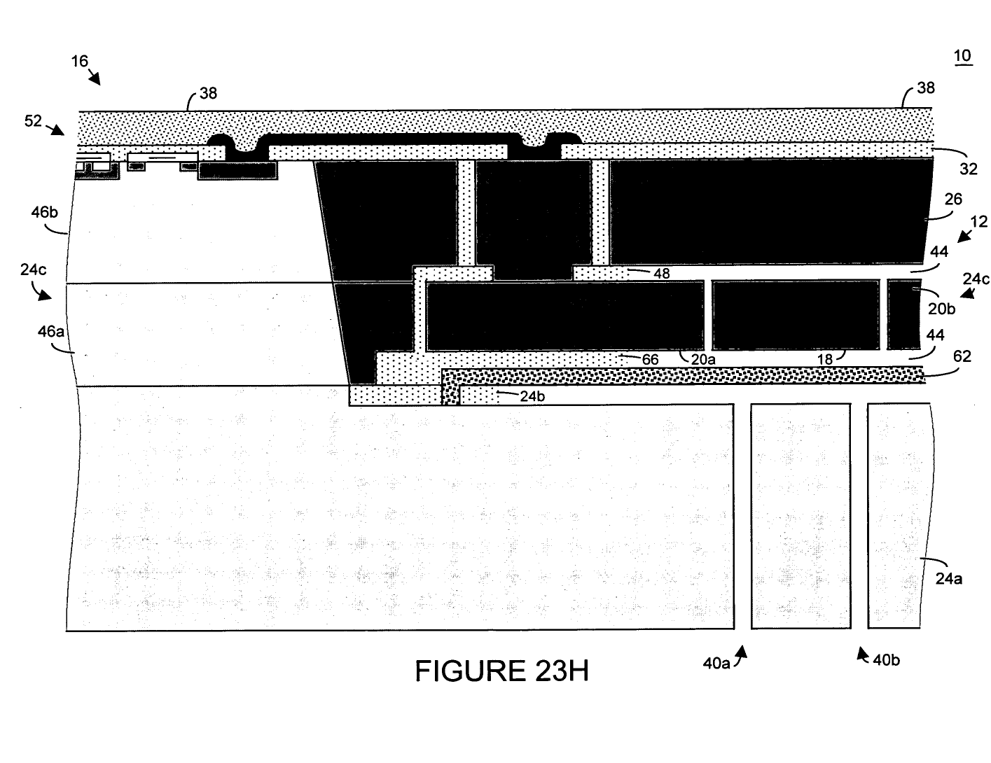

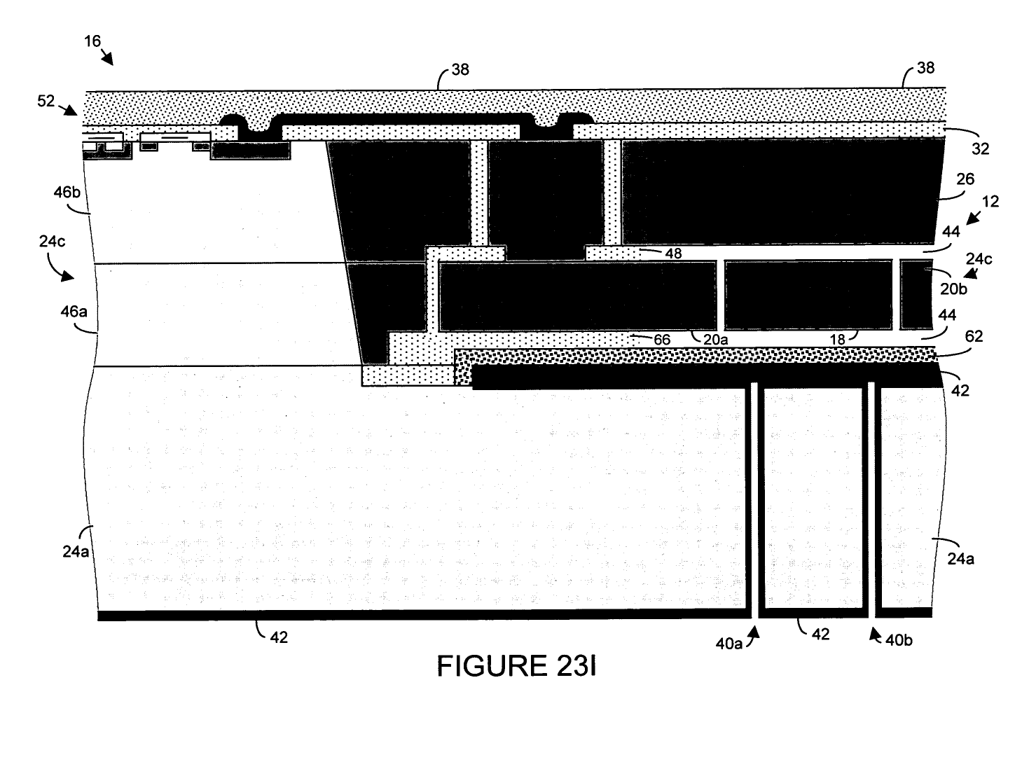

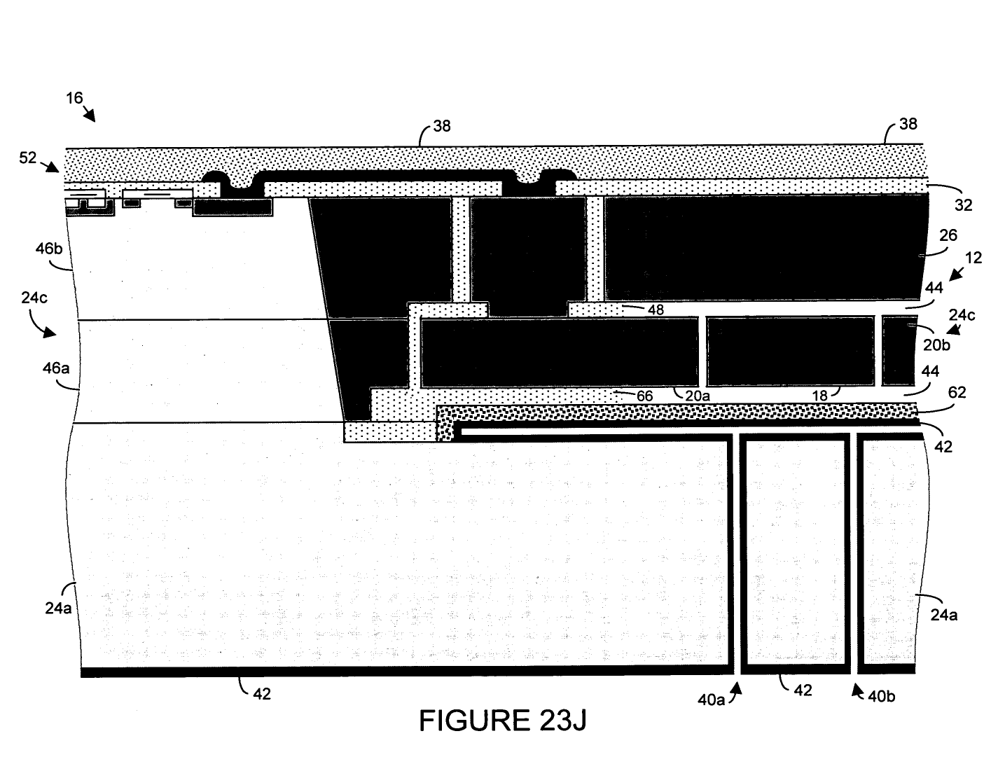

With reference to FIGS. 23A and 23B, an exemplary method of fabricating or manufacturing a micromachined mechanical structure 12 may begin with deposition, forming and/or growing first sacrificial layer 24b on first substrate layer 24a. In one embodiment, first sacrificial layer 24b is a silicon dioxide, a silicon nitride, a BPSG, a PSG, or an SOG, or combinations thereof. An opening or window 64 may be formed or provided in first sacrificial layer 24b. Thereafter, with reference to FIG. 23C, one or more materials may be deposited, applied, formed and/or grown to provide sealing layer screen 62. In this embodiment, material of sealing layer screen 62 may be a porous or amorphous material, for example, one or a combination of porous silicon dioxide, porous silicon nitride and/or porous semiconductor. In this way, micromachined mechanical structure may be released from the sacrificial layers through sealing layer screen 62. Notably, the material of sealing layer screen 62 may be porous when deposited or made porous thereafter.

With reference to FIG. 23D, sacrificial layer 66 may be deposited, applied, formed and/or grown on sealing layer screen 62. The sacrificial layer 66 may be a silicon dioxide, a silicon nitride, a BPSG, a PSG, or an SOG, or combinations thereof. It may be advantageous that sacrificial layers 24b and 66 be the same or substantially the same material(s), or react/respond the same, effectively the same and/or similarly to etchants or etching processes. In this way, as discussed below, both sacrificial layers 24b and 66 may be removed during the same or one processing step.

Thereafter, semiconductor layer 24c (for example, semiconductors such as silicon, germanium, silicon-germanium or gallium-arsenide) may be deposited, formed and/or grown (see, FIG. 23E). The mechanical structures 12, including moveable electrode 18 and fixed electrodes 20a and 20b, and other structures and/or features of microelectromechanical system 10 may be fabricated as discussed in detail with respect to other embodiments. (See, FIG. 23F). Such discussion will not be repeated here.

The backside vents or holes 40a and 40b may then be etched in first substrate layer 24a. (See, FIG. 23G). In one exemplary embodiment, anisotropic etching backside vents or holes 40a and 40b have a diameter or aperture size of between 0.1 μm to 10 μm, and preferably between 1 μm and 5 μm. Notably, however, all techniques for forming or fabricating vents or holes 40a and 40b, whether now known or later developed, are intended to be within the scope of the present inventions.

With reference to FIG. 23H, in this embodiment, mechanical structure 12 (for example, moveable electrode 18) is “released” by etching and/or removal of at least selected portions of sacrificial layers 24b, 48 and 66 through sealing layer screen 62. The removal of such layers provides or forms chamber 44. For example, in one embodiment, where sacrificial layers 24b, 48 and 66 are comprised of silicon dioxide, selected portions of layers 24b and 48 may be removed/etched using well-known wet etching techniques and buffered HF mixtures (i.e., a buffered oxide etch) or well-known vapor etching techniques using vapor HF. In this embodiment, sealing layer screen 62 may be a porous polysilicon material and/or a porous silicon nitride material.

In another embodiment, where sacrificial layers 24b, 48 and 66, respectively, are comprised of silicon nitride, selected portions of layers 24b, 48 and 66 may be removed/etched using phosphoric acid. In this embodiment, sealing layer screen 62 may be a porous polysilicon material and/or a porous silicon dioxide material. Proper design of mechanical structure 12, sacrificial layers 24b, 48 and 66, and sealing layer screen 62, and proper control of the wet etching process parameters may permit portions of sacrificial layers 24b, 48 and 66 to be etched, through sealing layer screen 62, to remove all or substantially all of sacrificial layers 24b, 48 and 66 around moveable electrode 18 and portions of fixed electrodes 20a and 20b.

Notably, fixed electrode 20a and/or 20b may remain partially, substantially or entirely surrounded by sacrificial layers 24b and 48. For example, with reference to FIG. 23H, while moveable electrode 18 is released from its respective underlying sacrificial layers 24b and/or 48 beneath or underlying structures 20a may provide additional physical support.

With reference to FIGS. 231 and 23J, after releasing mechanical structure 12 (for example, moveable electrode 18), one or more sealing materials 42 may be deposited, applied, formed and/or grown to seal chamber 44. The one or more sealing materials 42 may be deposited, applied, formed and/or grown on first substrate material 24a and/or over and/or in backside vents or holes 40. In this embodiment, one or more sealing materials 42 may be deposited, formed and/or grown on sealing layer screen 62 wherein chamber 44 is closed or sealed. The sealing materials 42 may be deposited, applied, formed and/or grown in a conformal or non-conformal manner.

As noted above, sealing material 42 may be any material that deposits, forms and/or grows (i) on first substrate material 24a, (ii) over and/or in backside vents or holes 40, and/or (iii) on or in sealing layer screen 62 to seal chamber 44. The sealing material(s) 42 may be, for example, spin on materials such as polymers, plasma deposited materials such as a silicon oxide, a silicon nitride and/or TEOS. The sealing material(s) 42 may be and/or include an adhesive, a paste, a solder, a metal, for example, a material that facilitates mechanical or electrical connection of system 10 to a frame (for example, lead frame) or substrate (for example, a circuit board or rigid platform). Further, the sealing material(s) 42 may be a silicon-based material, for example, a monocrystalline silicon, polycrystalline silicon, amorphous silicon or porous polycrystalline silicon (whether doped or undoped), germanium, silicon/germanium, silicon carbide, and gallium arsenide (and combinations thereof. The silicon may be deposited using, for example, an epitaxial, a sputtering or a CVD-based reactor. The deposition, formation and/or growth may be by a conformal process or non-conformal process.

As mentioned above, sealing material 42 may include one or more materials and/or layers thereof. For example, the encapsulation or sealing process of chamber 44 may include two or more sealing materials of the same or different materials. In this regard, a first sealing material may be deposited to partially or fully seal or close backside vents or holes 40. Thereafter, a second sealing material may be deposited on the first sealing material to more fully seal or close backside vents or holes 40. (See, for example, FIGS. 5A-5C). Indeed, more than two materials may be employed to seal or close backside vents or holes 40. (See, for example, FIGS. 5D and 5E). Again, all materials and deposition techniques of sealing material 42 to encapsulate or seal chamber 44, whether now known or later developed, are intended to be within the scope of the present inventions.

Also noted above, in conjunction with sealing or closing chamber 44, the atmosphere (including its characteristics) in which moveable electrode 18 operates may also be defined while encapsulating or sealing chamber 44 or thereafter. In this regard, the atmosphere in chamber 44 may be defined when one or more sealing materials 42 are deposited, applied, formed and/or grown (i) on first substrate material 24a and/or (ii) over and/or in backside vents or holes 40, or after further processing (for example, an annealing step may be employed to adjust the pressure). Notably, all techniques of defining the atmosphere, including the pressure thereof, during the process of encapsulating or sealing chamber 44, whether now known or later developed, are intended to be within the scope of the present inventions.

For example, one or more sealing materials 42 are deposited, applied, formed and/or grown in a nitrogen, oxygen and/or inert gas environment (for example, helium). The pressure of the fluid (gas or vapor) may be selected, defined and/or controlled to provide a suitable and/or predetermined pressure of the fluid in chamber 44 immediately after encapsulating or sealing chamber 44, after one or more subsequent processing steps (for example, an annealing step) and/or after completion of micromachined mechanical structure 12 and/or microelectromechanical system 10. Notably, the gas(es) employed during these processes may provide predetermined reactions (for example, oxygen molecules may react with silicon to provide a silicon oxide); all such techniques, gasses and/or materials are intended to fall within the scope of the present inventions.

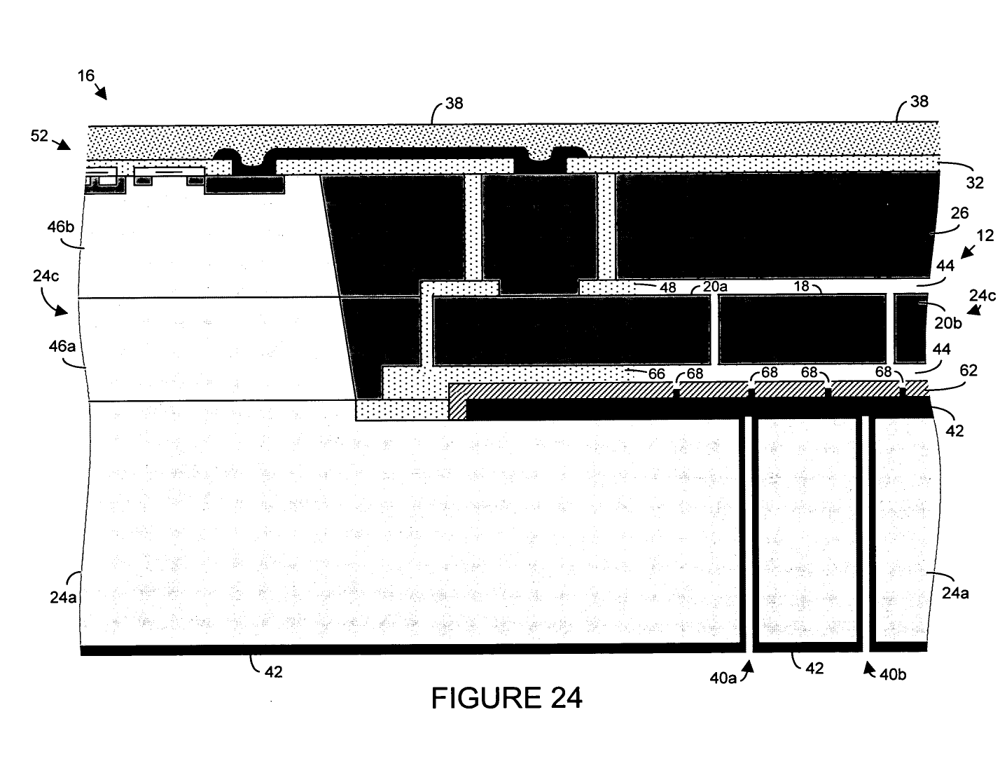

With reference to FIG. 24, in another embodiment, sealing layer screen 62 may include a plurality of vent holes which facilitate etching or removal of sacrificial layers 24b, 48 and 66. In this embodiment, mechanical structure 12 (for example, moveable electrode 18) is “released” by etching and/or removal of at least selected portions of sacrificial layers 24b, 48 and 66 primarily through vents 68 in sealing layer screen 66 and/or through the porosity of sealing layer screen 62. The vents 68 may include an aperture or diameter which is significantly smaller than backside vents or holes 40. Notably, in this embodiment, sealing layer screen 62 may or may not be comprised of a porous or amorphous material (whether or not porous when deposited or made porous thereafter).

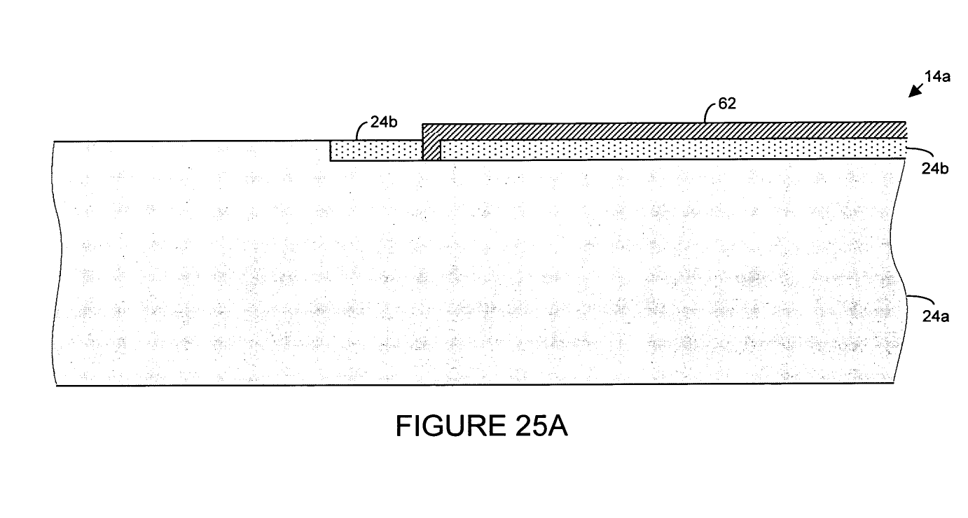

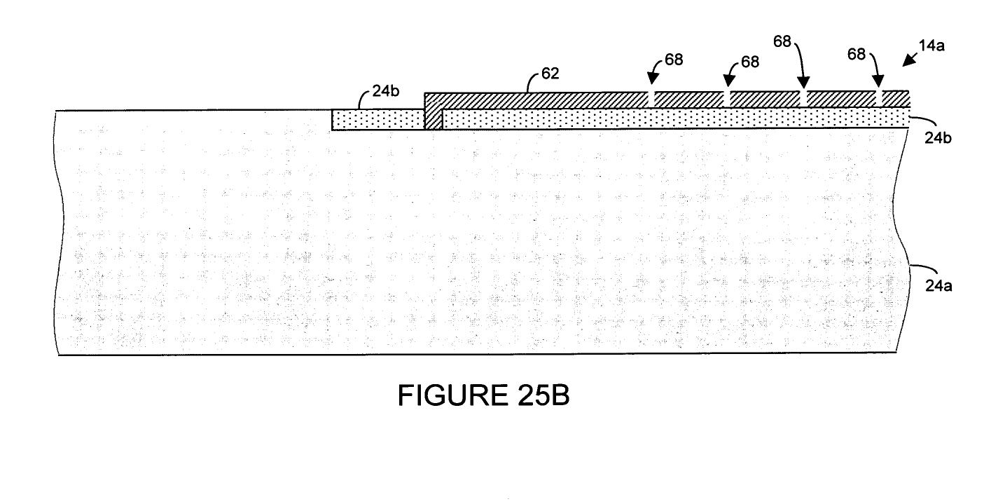

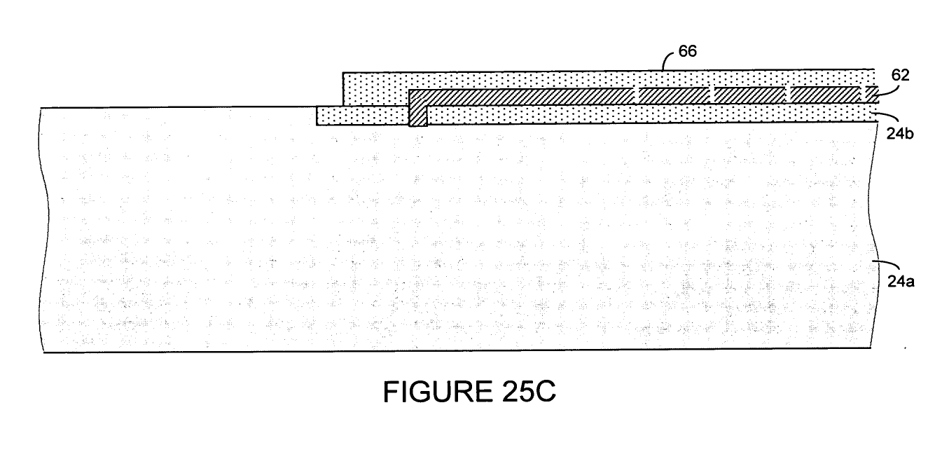

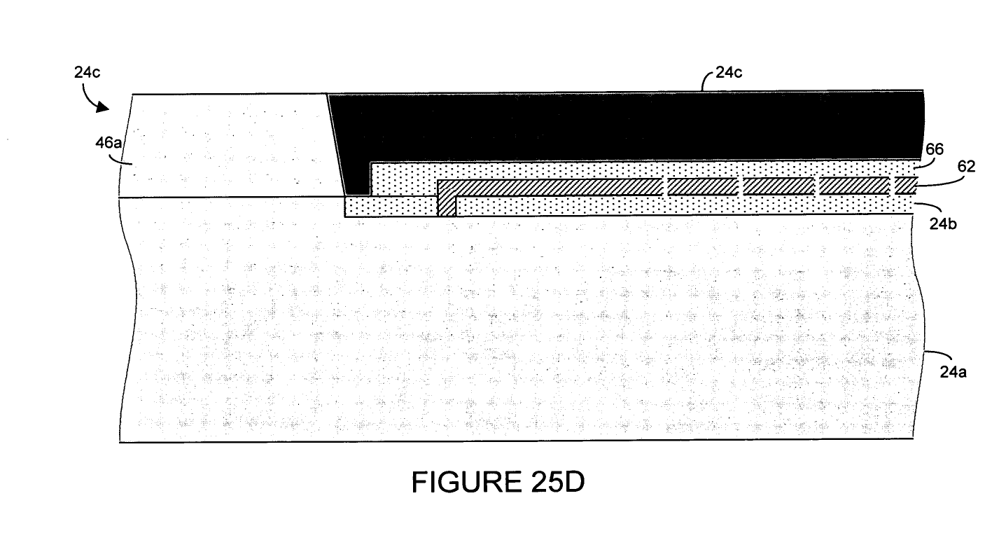

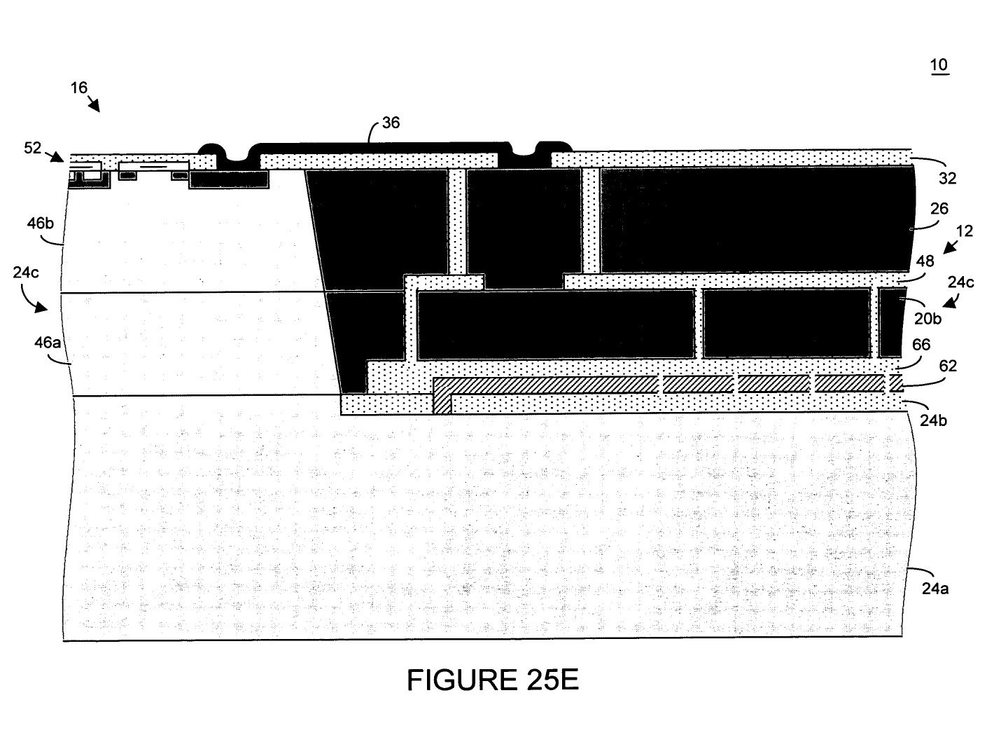

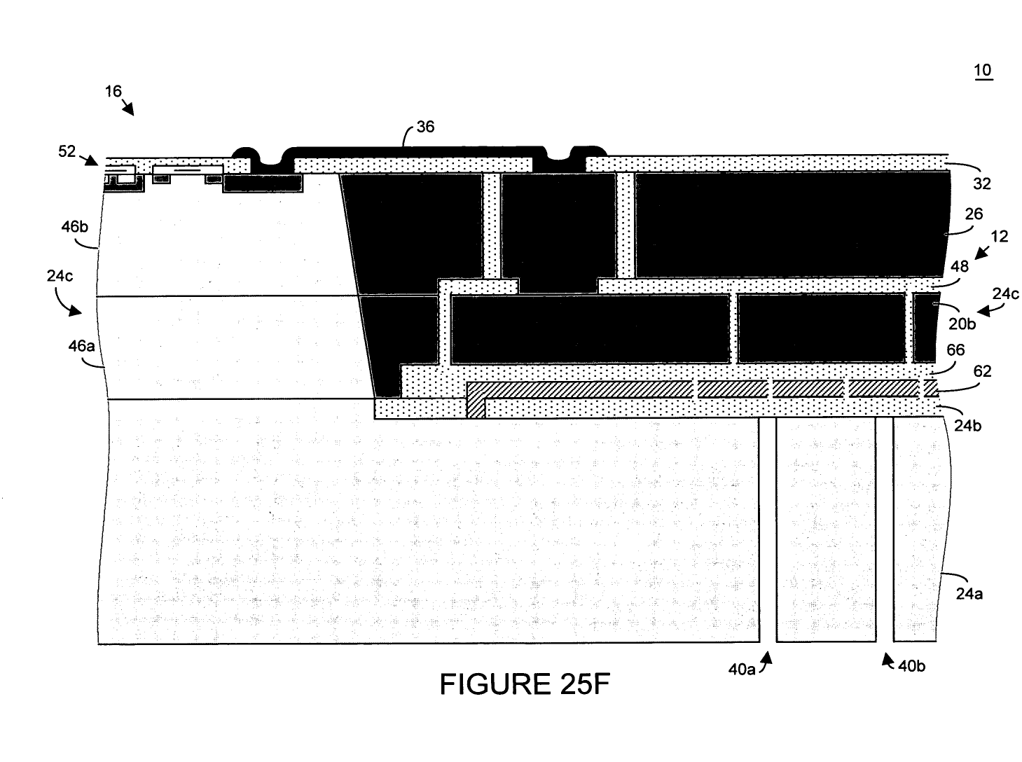

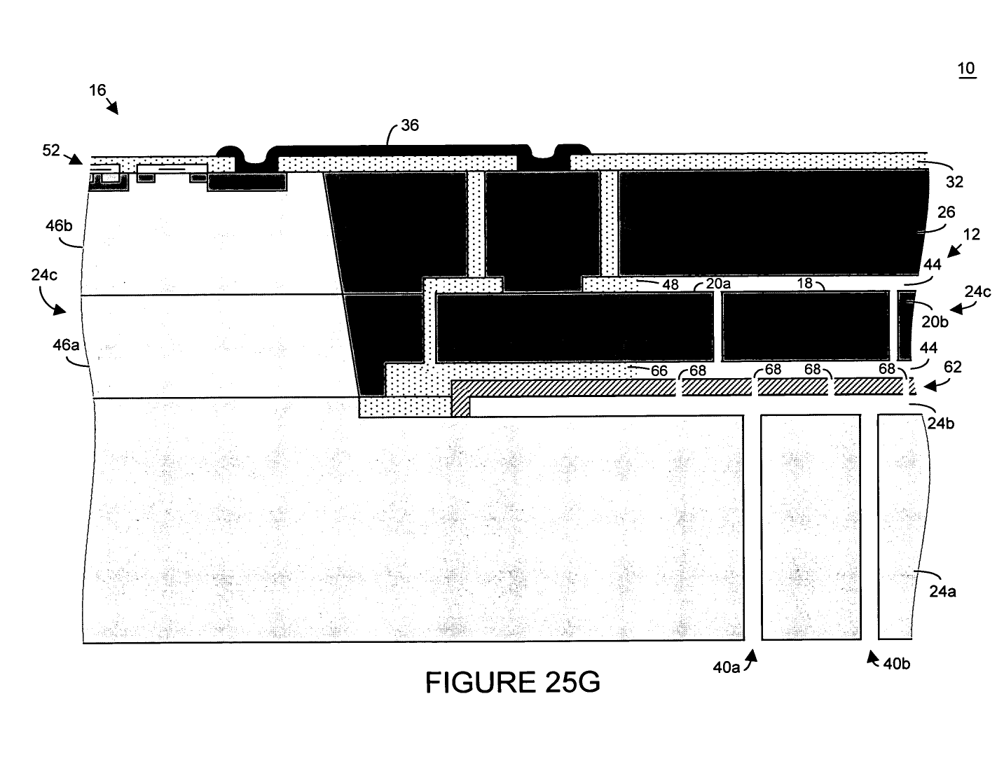

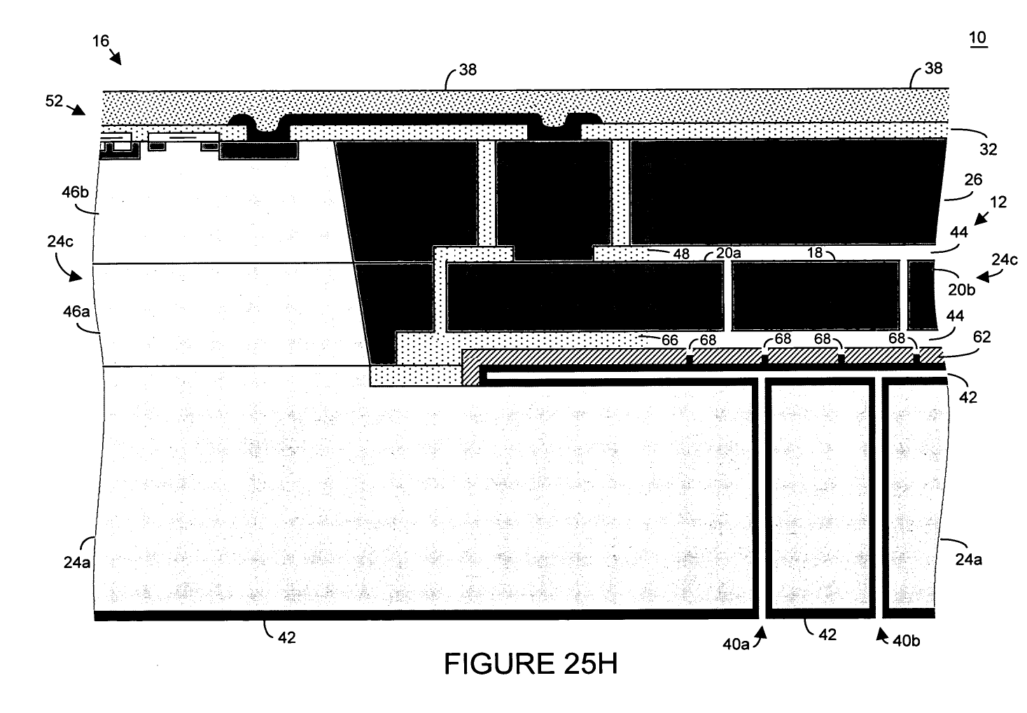

The embodiment of FIG. 24 may be fabricated in the same or similar manner as described above with respect to FIG. 22. In this embodiment, however, vents 68 may be formed in sealing layer screen 62 prior to deposition of sacrificial layer 66. (See, for example, FIG. 25B). An exemplary fabrication process is illustrated in FIGS. 25A-25H. For the sake of brevity, however, such discussion will not be repeated.

Notably, the sealing layer screen embodiments may be implemented in any of the embodiments described and illustrated herein. For example, sealing layer screen embodiments may be employed in conjunction with any of the cover formation, deposition, growth techniques of, for example, embodiments of FIGS. 3, 6 and 11, the formation, deposition, growth techniques of one or more sealing layers of FIGS. 5A-5D, different first substrates (for example, SOI and/or bulk type), and the substrate cover implementation of, for example, FIGS. 14 and 17. For the sake of brevity, such discussions will not be repeated.

As noted above, sealing layer screen 62 may reduce the time required to seal or close chamber 44 via deposition, application, formation and/or growth of sealing materials 42 (i) on first substrate material 24a, (ii) over and/or in backside vents or holes 40, and/or (iii) on or in sealing layer screen 62. In addition, such a configuration may reduce, eliminate, and/or minimize portions of sealing layer 42 from collecting in chamber 44 and/or on portions of micromachined mechanical structure 12 disposed therein. In this regard, any material that is disposed on electrodes 18 and/or 20 may impact (for example, adversely) the performance or operation of micromachined mechanical structure 12.

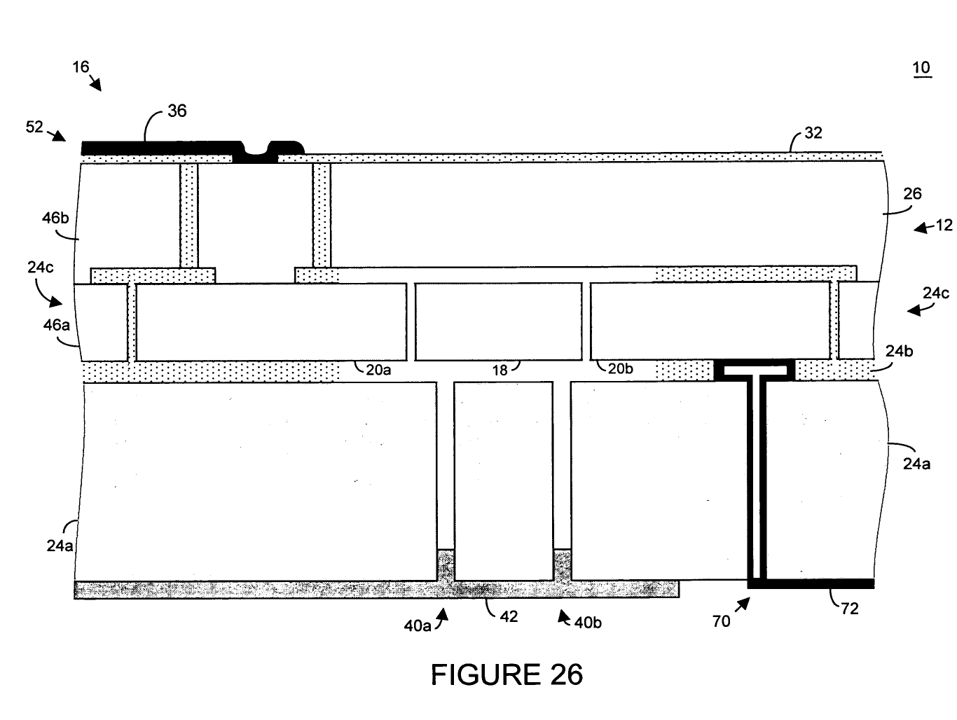

The electrical contact to the micromachined mechanical structure (for example, one or more fixed electrodes) may be disposed in the cover, in the first substrate layer, or both the cover and first substrate layer. For example, with reference to FIG. 26, in one embodiment, microelectromechanical system 10, in addition to a contact disposed in cover 26, includes electrical contact 70 which is disposed in first substrate layer 24a and contacts fixed electrode 20b. In this embodiment, electrical contact 70 includes conductive layer 72 to provide electrical contact/connection to micromachined mechanical structure 12 (for example, one or more fixed electrodes, here fixed electrode 20b). The conductive layer 72 may be, for example, a heavily doped polysilicon, metal (such as aluminum, chromium, gold, silver, molybdenum, platinum, palladium, tungsten, titanium, and/or copper), metal stacks, complex metals and/or complex metal stacks).

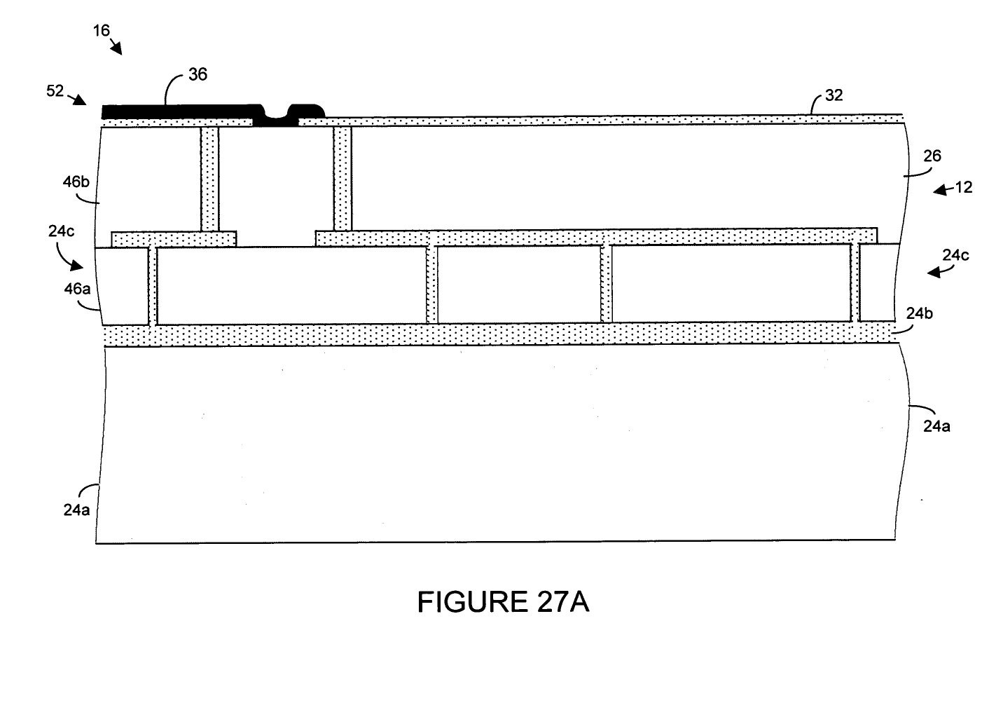

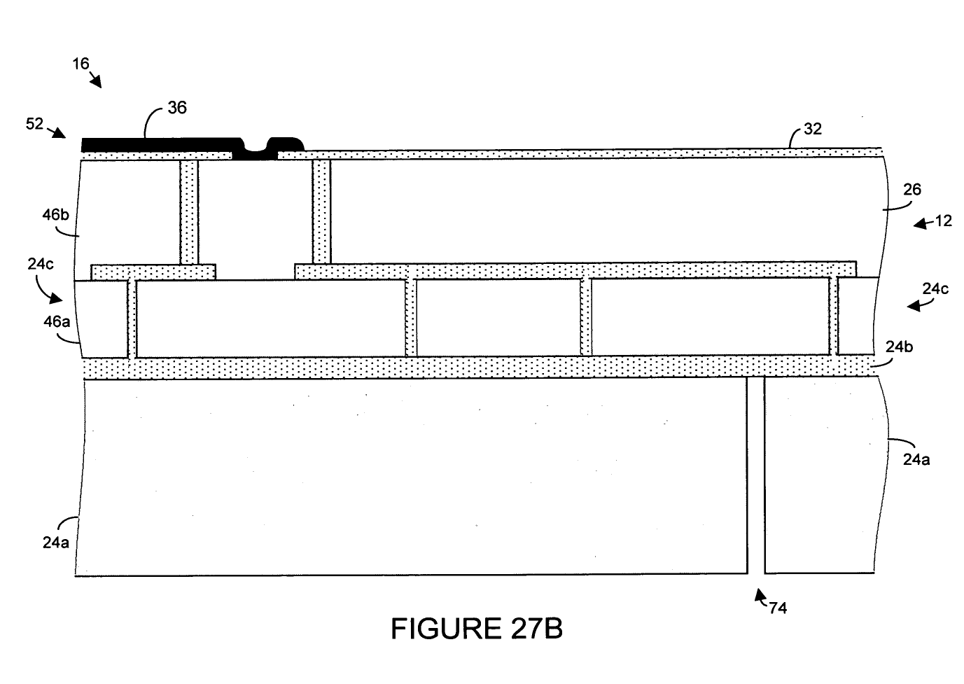

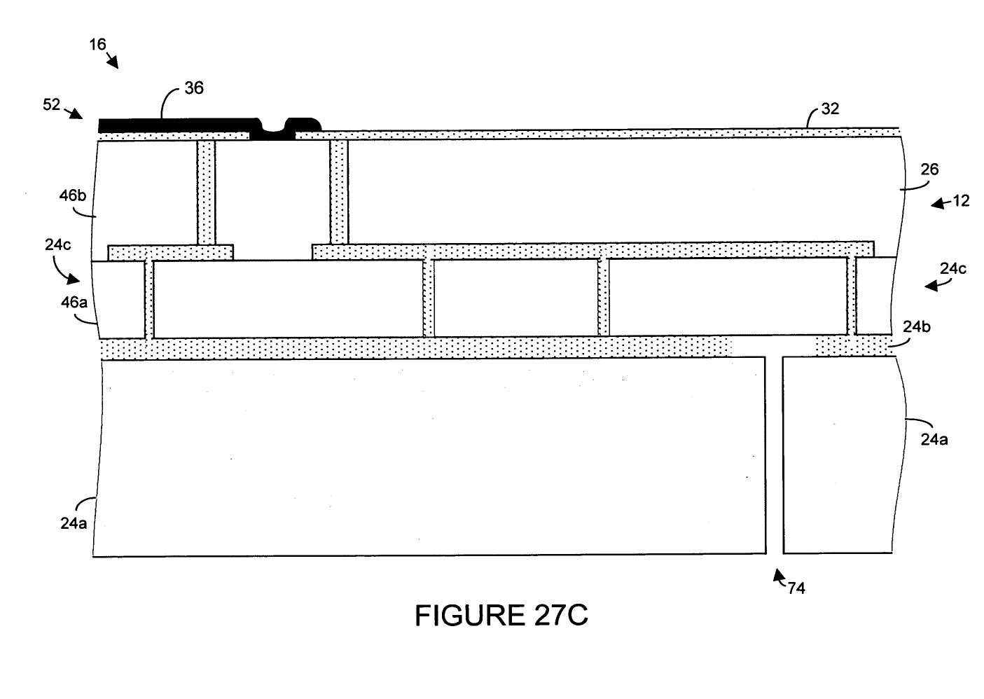

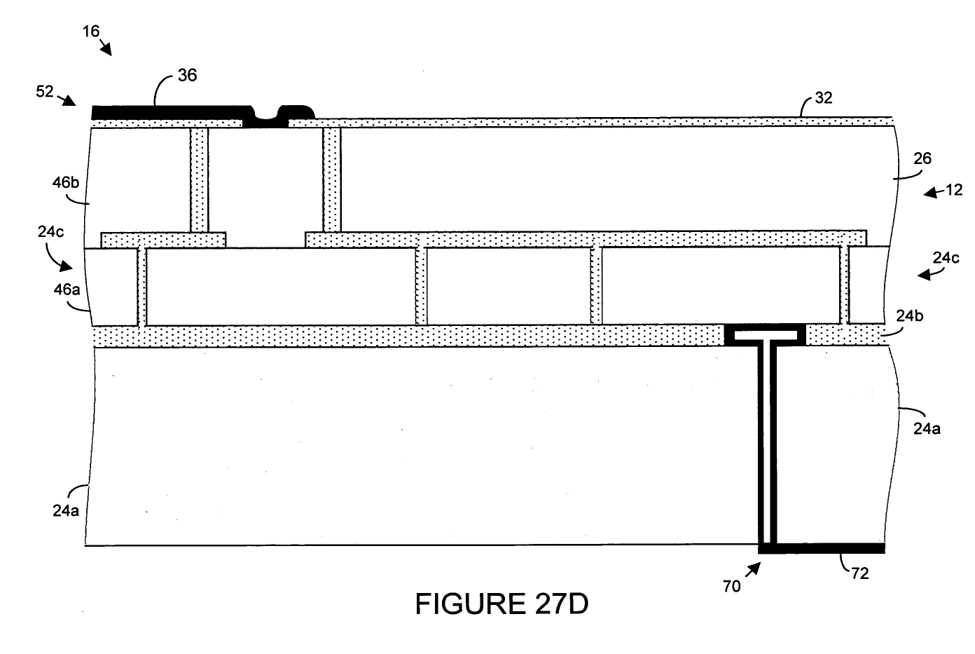

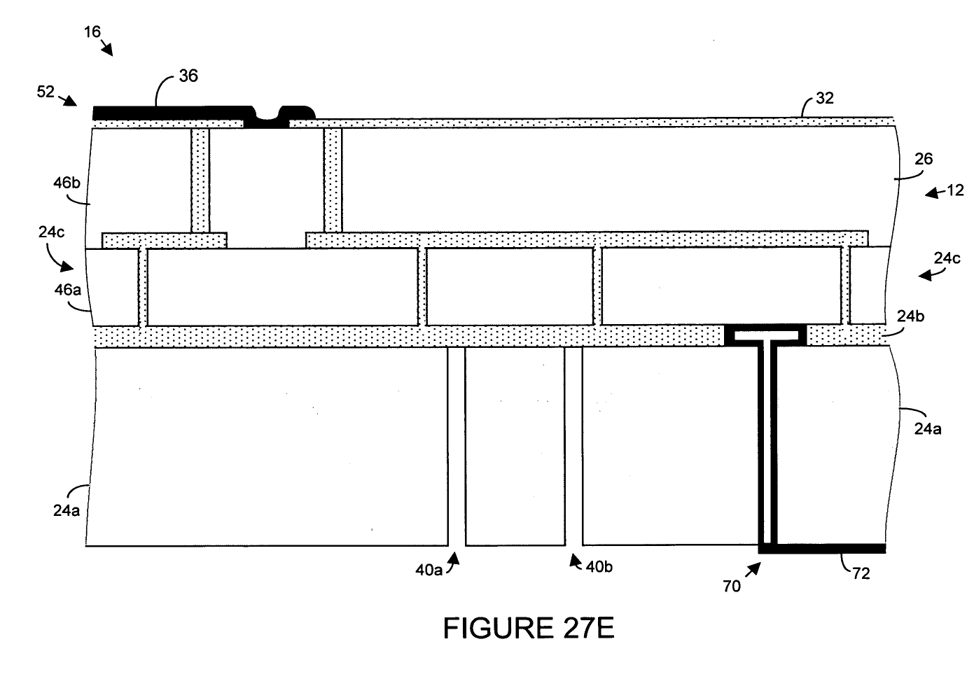

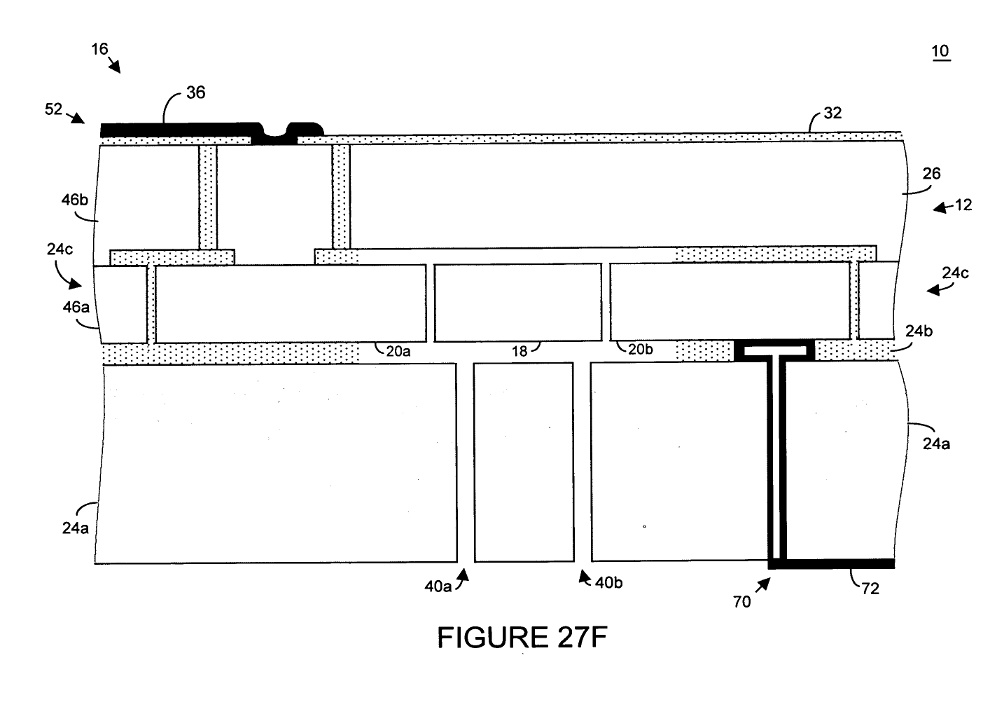

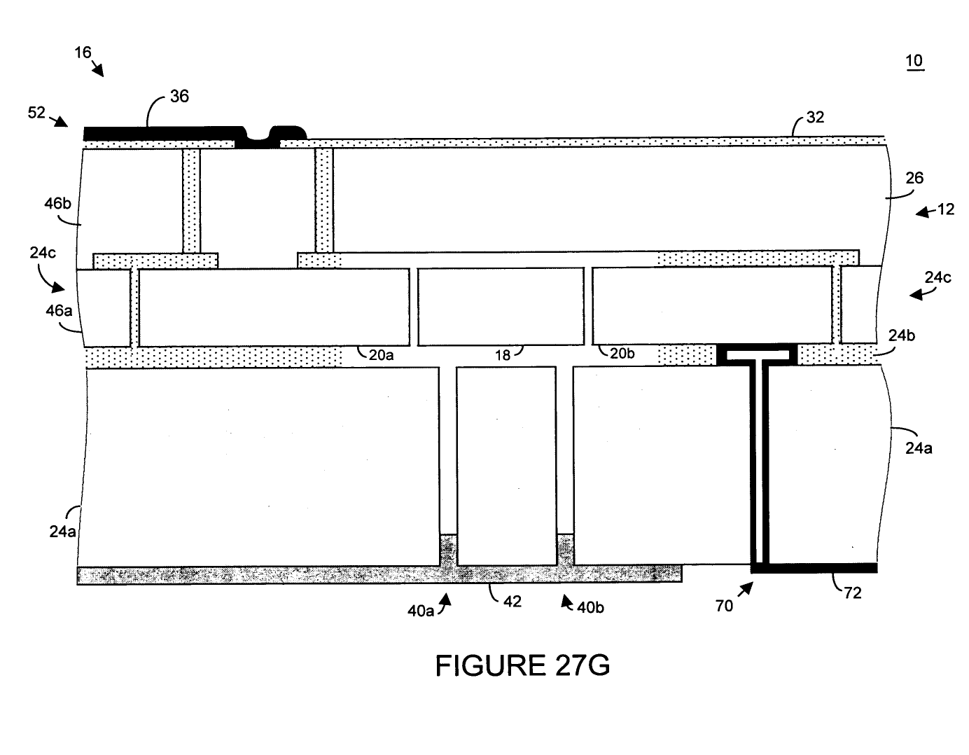

With reference to FIGS. 27A and 27B, in one exemplary fabrication technique, contact hole 74 may be formed (for example, via anisotropic etching). Thereafter, a portion of insulation or sacrificial layer 24b may be removed to allow contact to fixed electrode 20b. (See, FIG. 27C). The conductive layer 72 may then be deposited, formed and/or grown. (See, FIG. 27D).

After forming electrical contact 70, mechanical structure 12 may be released before or after backside vents or holes 40 are sealed or closed (or chamber 44 is sealed) using any of the techniques described and illustrated herein. (See, for example, FIGS. 27E-27G).

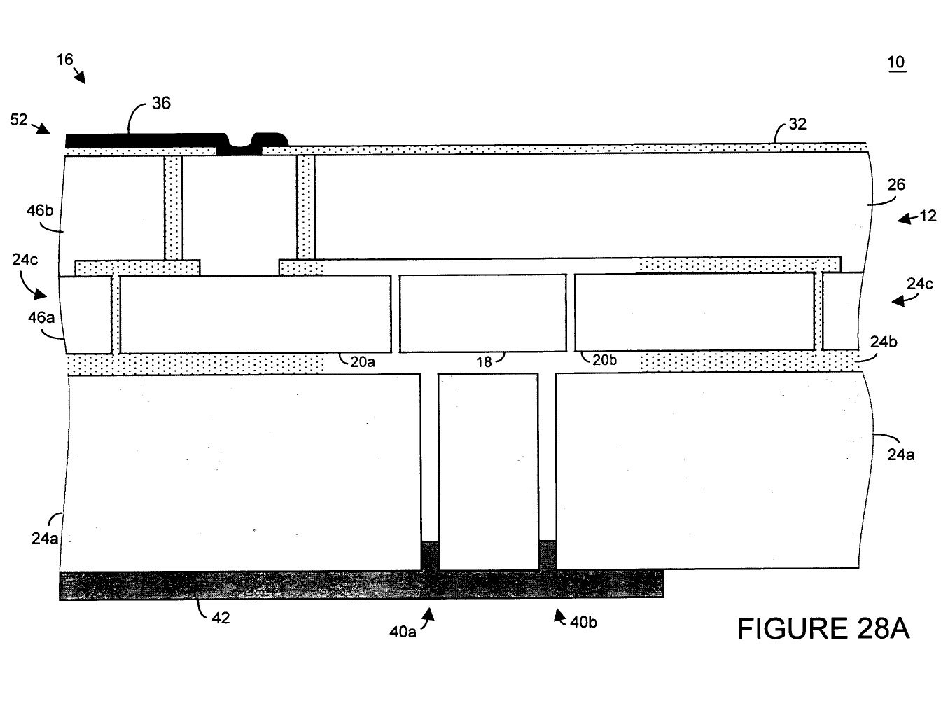

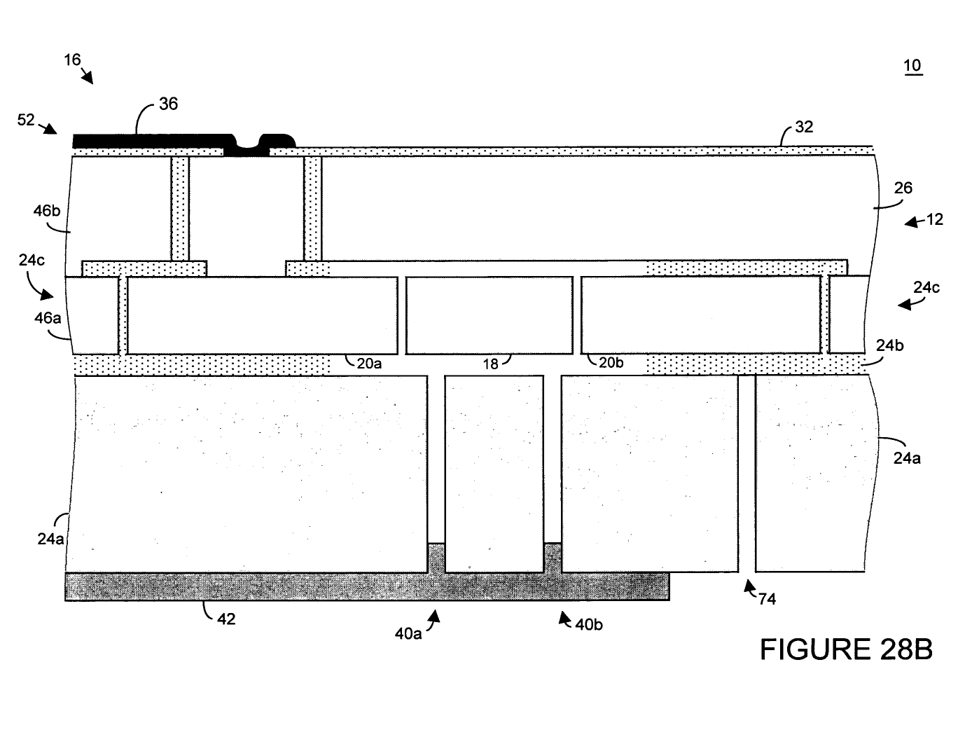

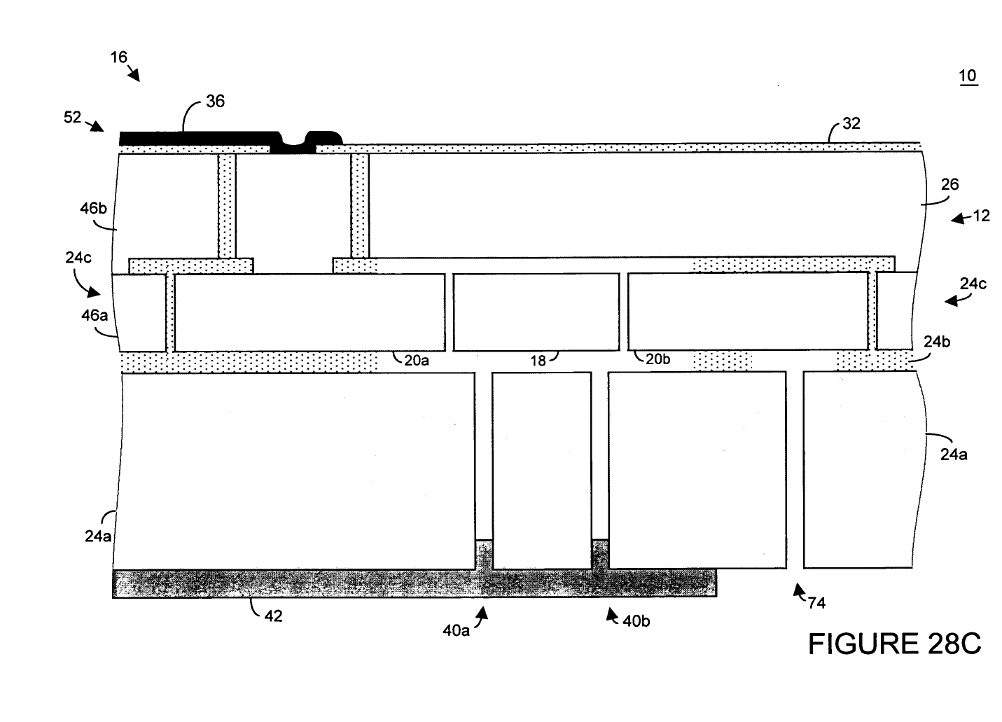

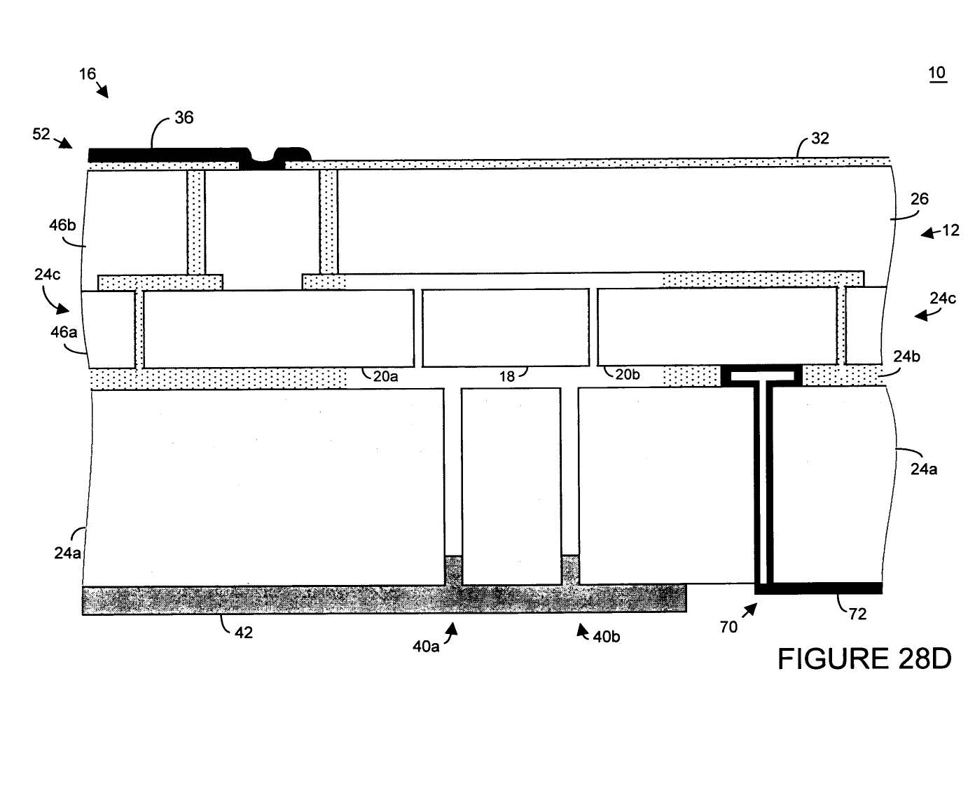

Notably, electrical contact 70 may also be formed after mechanical structure 12 is released and/or after backside vents or holes 40 are sealed or closed (or chamber 44 is sealed or closed). (See, for example, FIGS. 28A-28D).

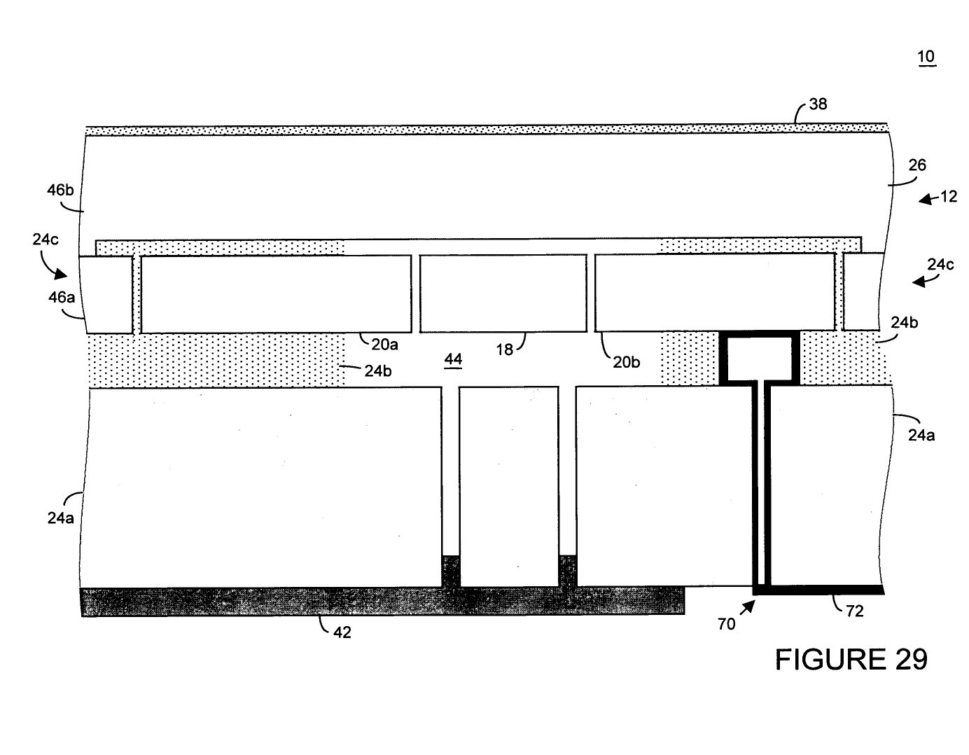

In one embodiment, microelectromechanical system 10 may, in lieu of a contact disposed in cover 26, include electrical contact 70 which is disposed in first substrate layer 24a and contacts fixed electrode 20b. (See, for example, FIG. 29). This embodiment may be implemented in conjunction with any or all of the embodiments described and/or illustrated herein.

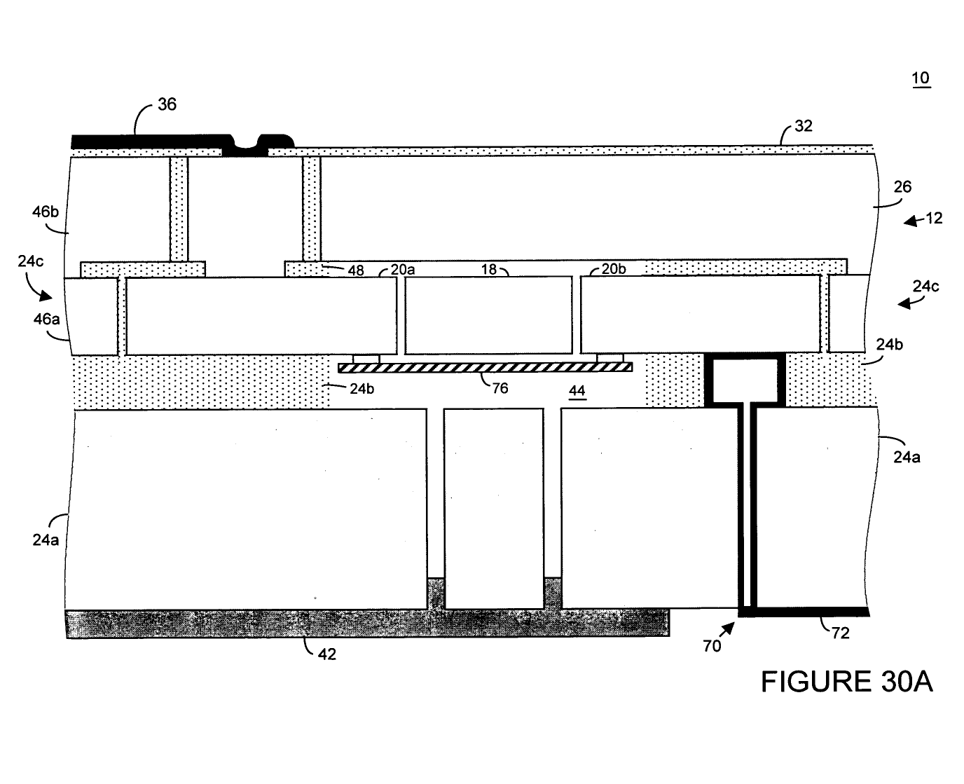

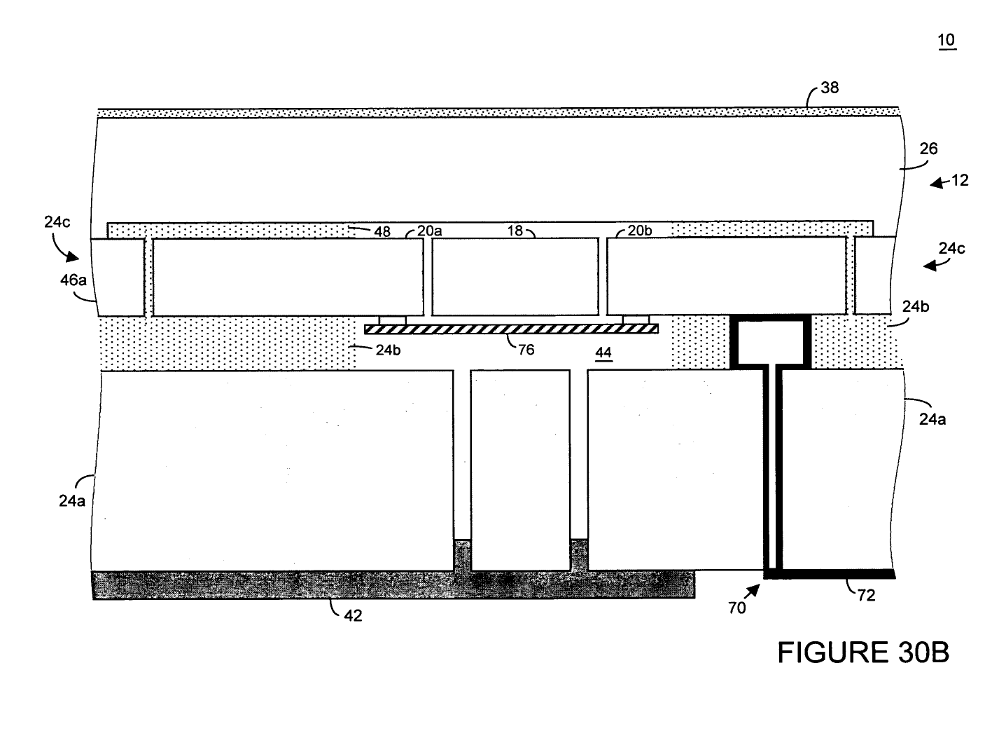

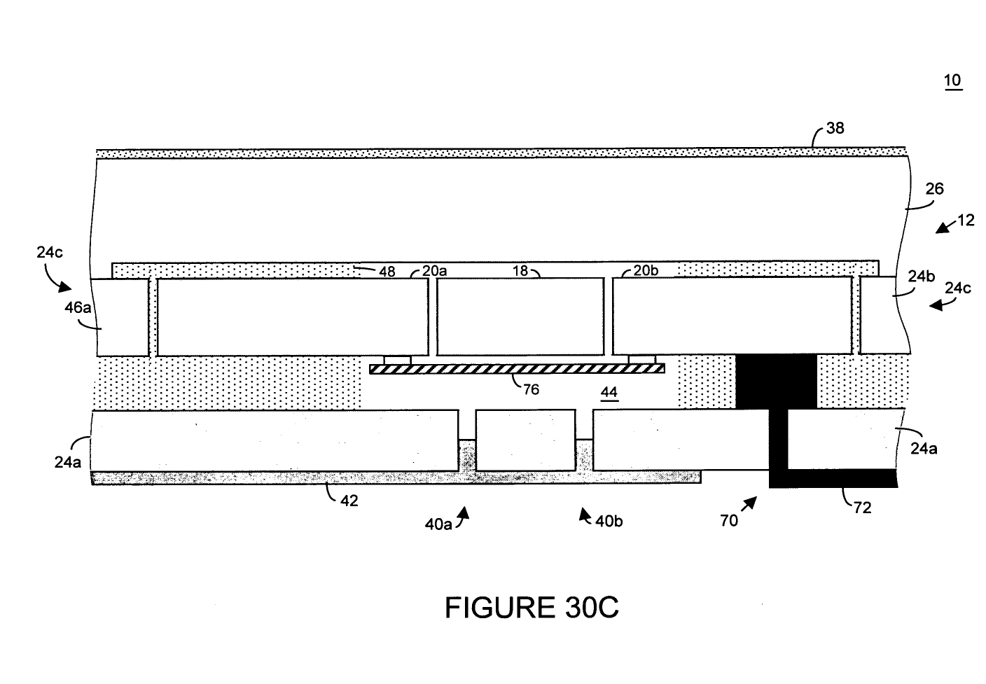

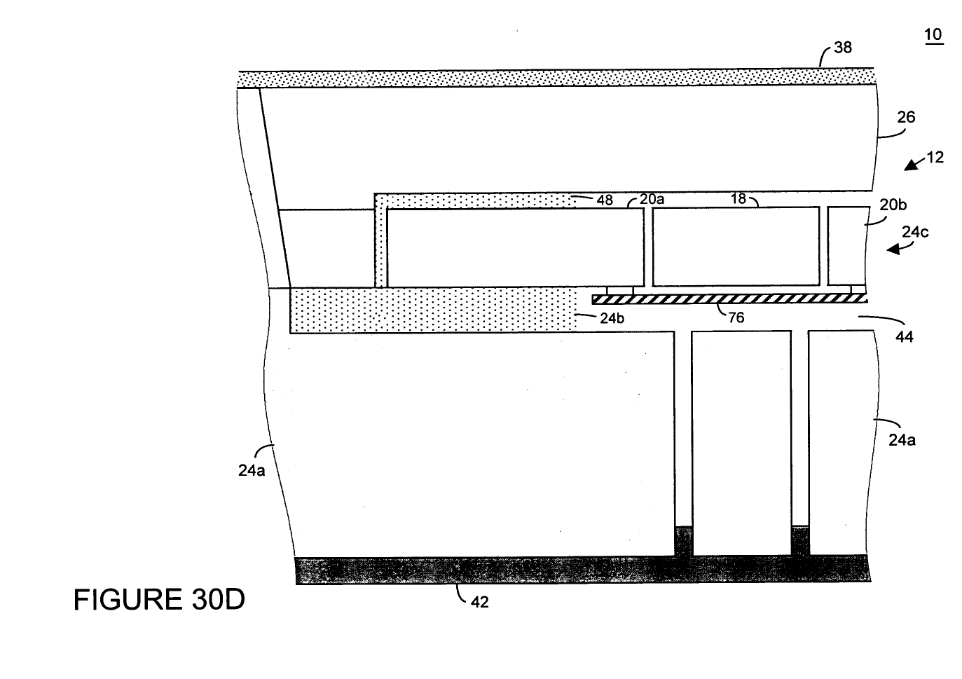

The microelectromechanical system of the present inventions may also include internal electrical connection or wiring which interconnects portions of micromachined mechanical structure (for example, a plurality of fixed electrodes). For example, with reference to FIGS. 30A-30D, internal electrical connection or wiring 76 may electrically connect fixed electrodes 20a and 20b. The internal electrical connection or wiring 76 may be implemented in any and all of the embodiments described and/or illustrated herein.

It should be noted that while many of the embodiments described and illustrated herein include one micromachined mechanical structure, the microelectromechanical system may include a plurality of micromachined mechanical structures. The micromachined mechanical structures may be one or more transducers, resonators, or sensors (for example, accelerometers, gyroscopes, pressure sensors, tactile sensors and/or temperature sensors). The micromachined mechanical structures may be disposed in the same or different chambers. Where the micromachined mechanical structure(s) reside in a single or common chamber and exposed to an environment within that chamber. Under this circumstance, the environment contained in chamber 26 provides a mechanical damping for the mechanical structures of one or more micromachined mechanical structures (for example, an accelerometer, a pressure sensor, a tactile sensor and/or temperature sensor).

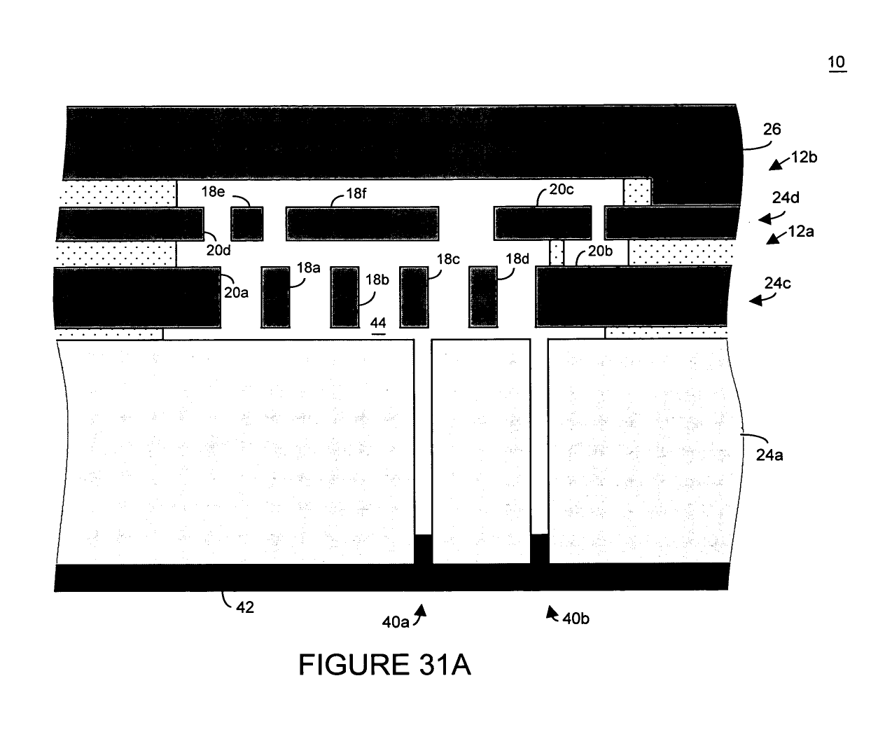

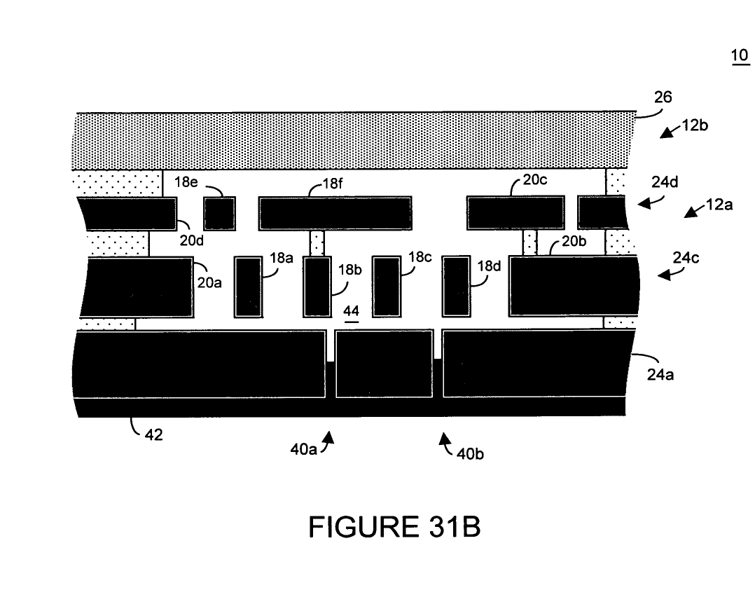

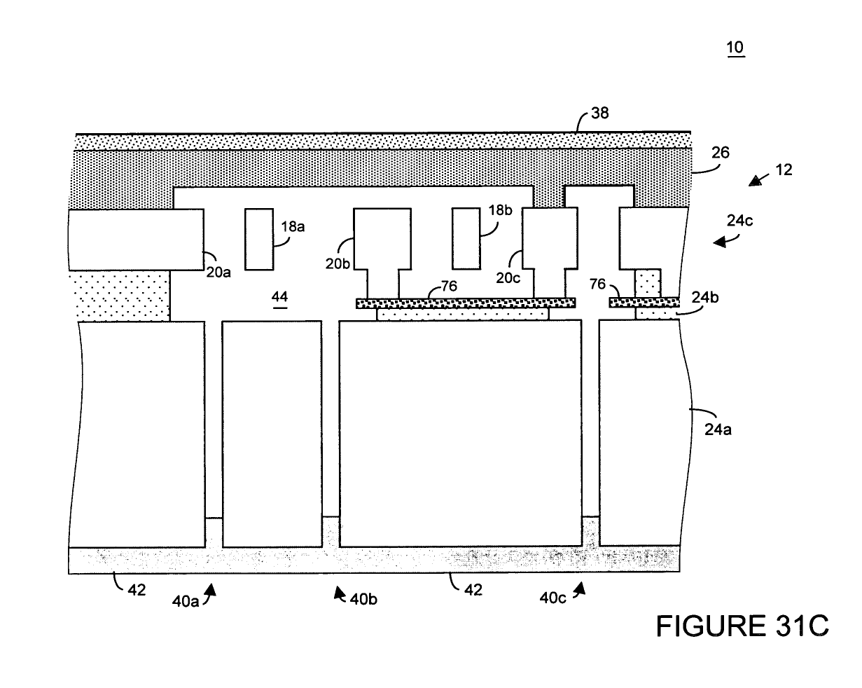

Moreover, the mechanical structures of the one or more transducers or sensors may themselves include multiple layers that are vertically and/or laterally stacked or interconnected. (See, for example, micromachined mechanical structures 12a and 12b of FIGS. 31A and 31B; mechanical structure 12 of FIG. 31C). Under this circumstance, the mechanical structures are fabricated using one or more processing steps to provide the vertically and/or laterally stacked and/or interconnected multiple layers.

Notably, although many of the illustrations include one micromachined mechanical structure, the microelectromechanical system of any and all of the embodiments described and illustrated herein may include a plurality of micromachined mechanical structures, whether (i) such mechanical structures are fabricated using one or more processing steps to provide the vertically and/or laterally stacked and/or interconnected multiple layers, and/or (ii) such mechanical structures are disposed in a common chamber or multiple chambers. For the same of brevity, such discussion will not be repeated.

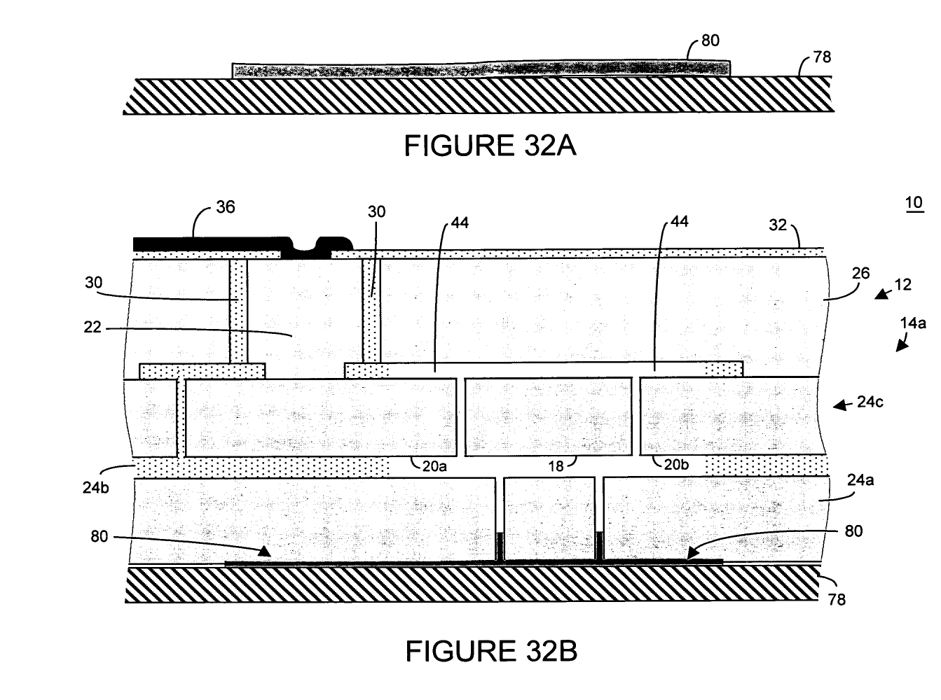

In another set of embodiments, after releasing the micromachined mechanical structure(s), the backside vents or holes of the microelectromechanical system may be sealed or closed during a packaging process, for example, via application of a die attach material (for example, a solder, bonding material and/or an adhesive material) which secures the die of the microelectromechanical system to a package (for example, a lead frame, BGA (such as, for example, a micro BGA)). With reference to FIGS. 32A and 32B, in one embodiment, microelectromechanical system 10 is disposed on and attached to package 78 (for example, a lead frame type) via die attach material 80 (for example, a solder, bonding material, glue and/or adhesive). The die attach material 80 seals or closes backside vents or holes 40. Notably, die attach material 80 may be a suitable material for outgas anti-stiction agent. Indeed, an anti-stiction agent may be applied to microelectromechanical system 10 prior to attachment to package 78 or concurrently therewith.

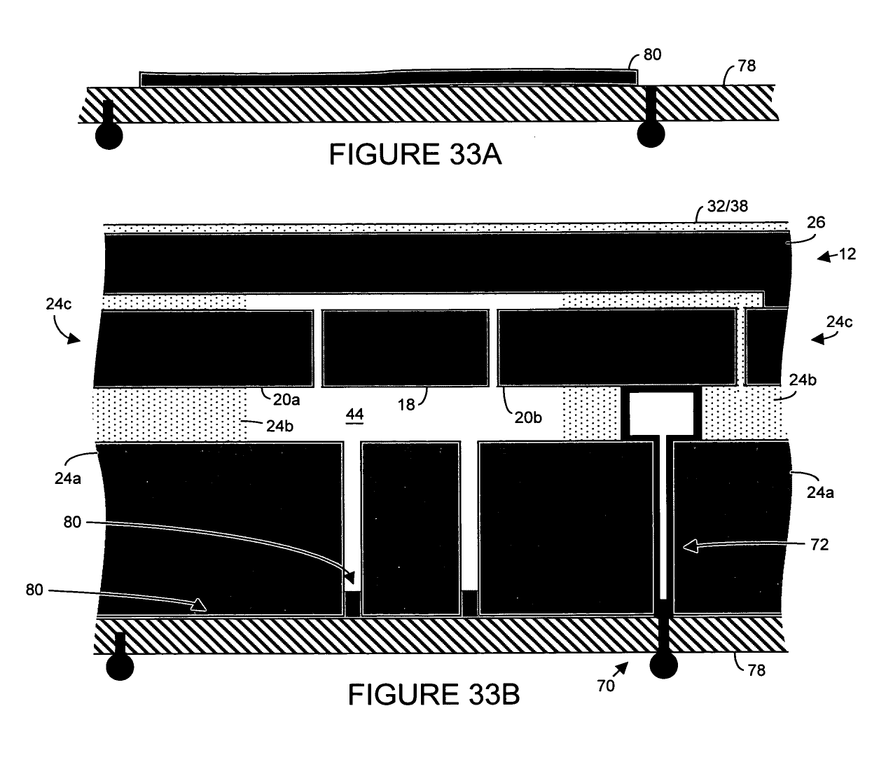

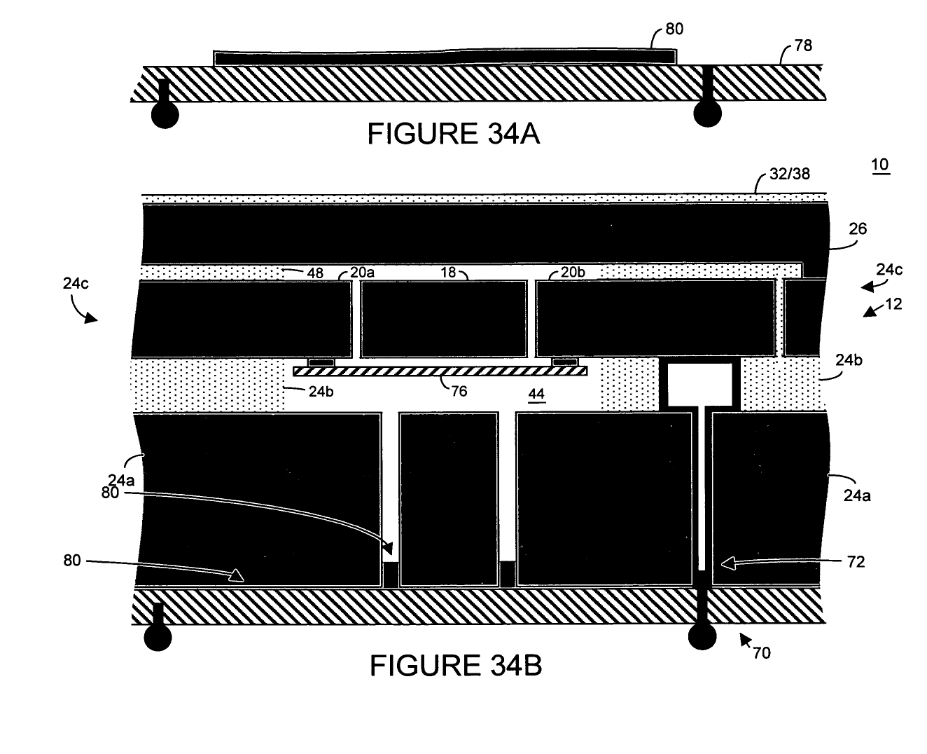

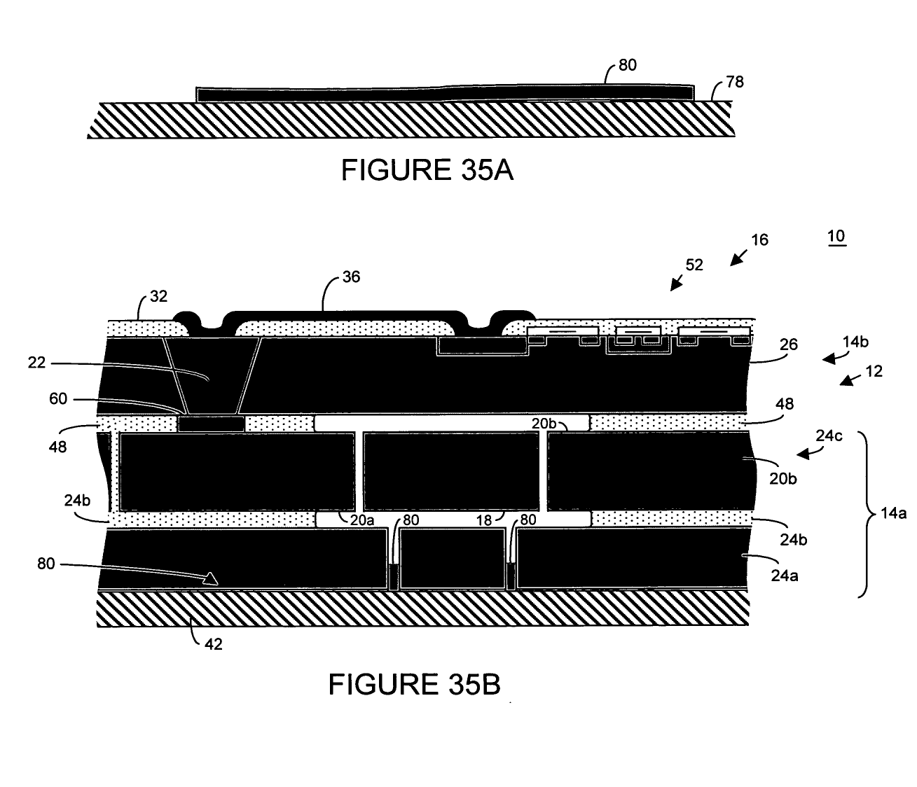

The backside vents or holes 40 of any microelectromechanical systems 10 of the present inventions may be sealed or closed using die attach material 80 (for example, a solder, bonding material and/or an adhesive material) which secures the die of the microelectromechanical system to a package (for example, a lead frame or BGA). (See, for example, FIGS. 33A, 33B, 34A, 34B, 35A and 35B). For the same of brevity, such discussion will not be repeated.

There are many inventions described and illustrated herein. While certain embodiments, features, materials, configurations, attributes and advantages of the inventions have been described and illustrated, it should be understood that many other, as well as different and/or similar embodiments, features, materials, configurations, attributes, structures and advantages of the present inventions that are apparent from the description, illustration and claims (are possible by one skilled in the art after consideration and/or review of this disclosure). As such, the embodiments, features, materials, configurations, attributes, structures and advantages of the inventions described and illustrated herein are not exhaustive and it should be understood that such other, similar, as well as different, embodiments, features, materials, configurations, attributes, structures and advantages of the present inventions are within the scope of the present inventions.

Each of the aspects of the present inventions, and/or embodiments thereof, may be employed alone or in combination with one or more of such aspects and/or embodiments. For the sake of brevity, those permutations and combinations will not be discussed separately herein. As such, the present inventions are not limited to any single aspect or embodiment thereof nor to any combinations and/or permutations of such aspects and/or embodiments. Moreover, each of the aspects of the present inventions, and/or embodiments thereof, may be employed alone or in combination with one or more of such other aspects and/or embodiments.

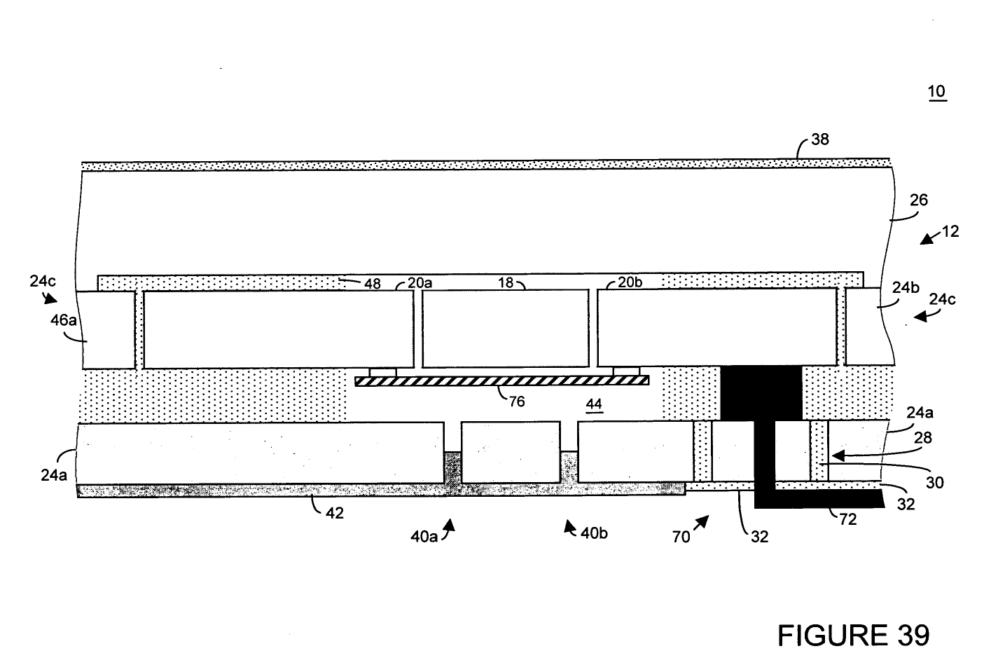

For example, in those instances where a contact or the like is disposed in the substrate, the contact may be electrically isolated from certain portions of the substrate using trenches and/or insulative materials. (See, for example, FIG. 39). In this exemplary embodiment, conductive layer 72 is electrically isolated from a significant portion of substrate 24a via insulative material 30, disposed in trenches 28, and insulation layer 32. Notably, such a configuration facilitates integration of circuitry in or on substrate 24a, disposed in a separate substrate, and/or in one or more substrates that are connected to substrate 24a (like as illustrated in FIGS. 13, 17 and 24 except such circuitry is disposed in or on substrate 24a). In this regard, microelectromechanical device 10 may include micromachined mechanical structure 12 and circuitry 16 as a monolithic-like structure including mechanical structure 12 and circuitry 16 in one substrate.

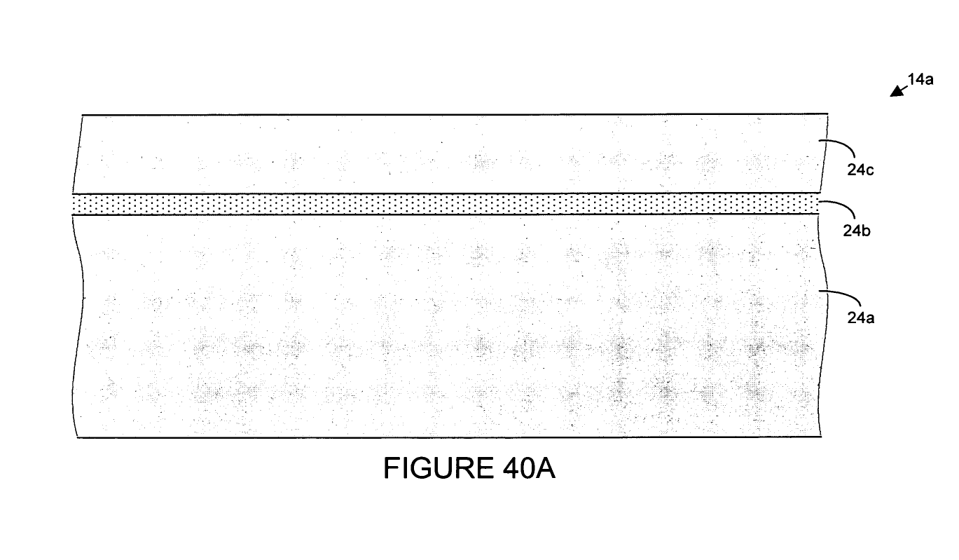

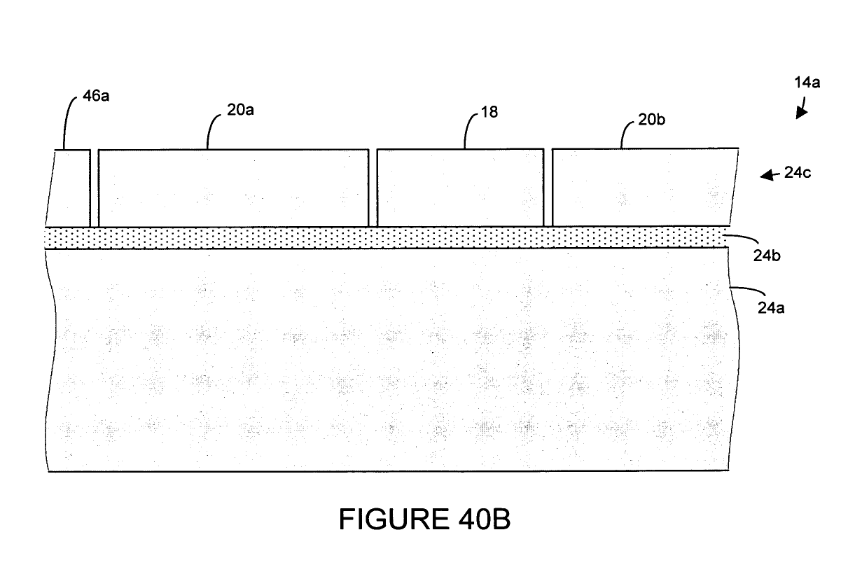

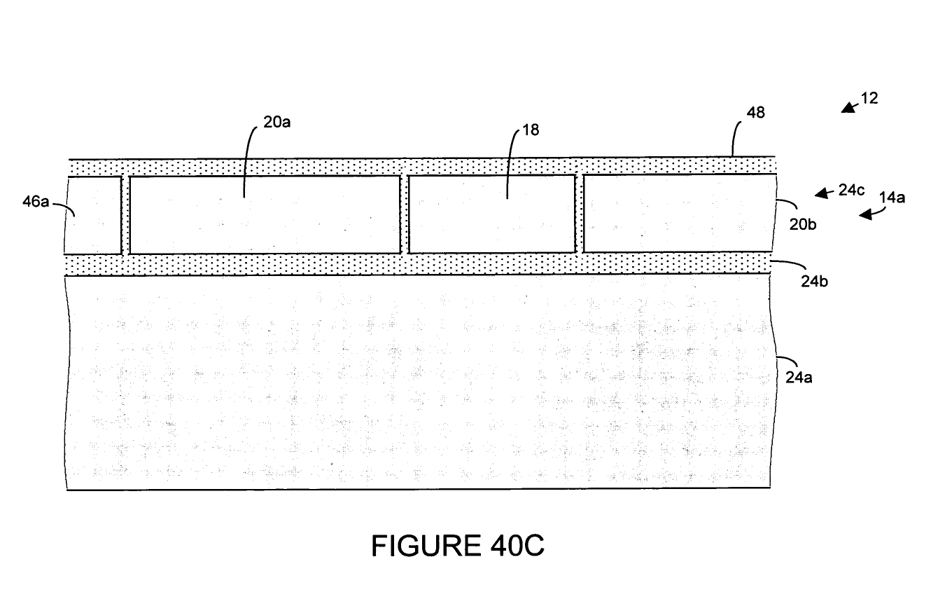

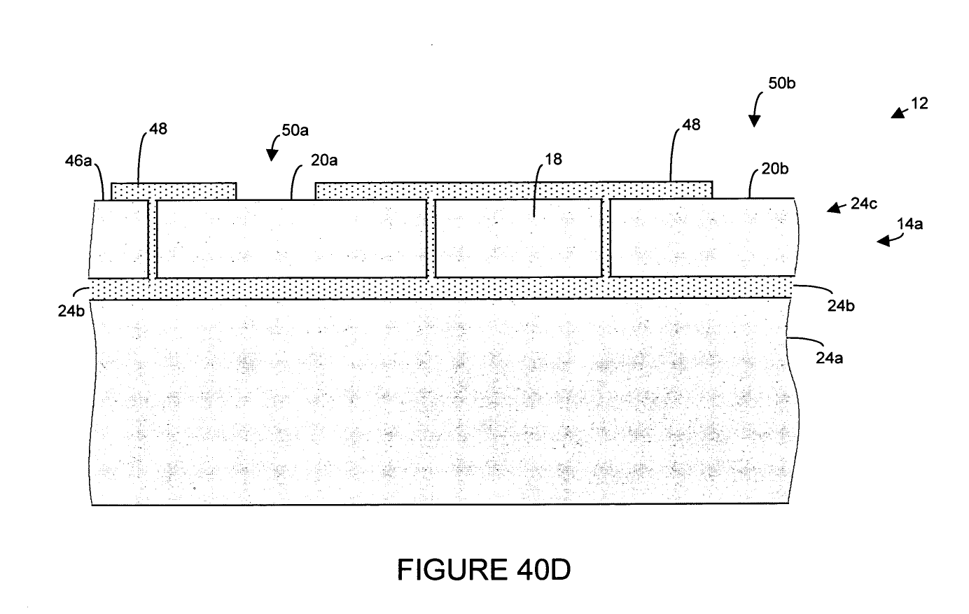

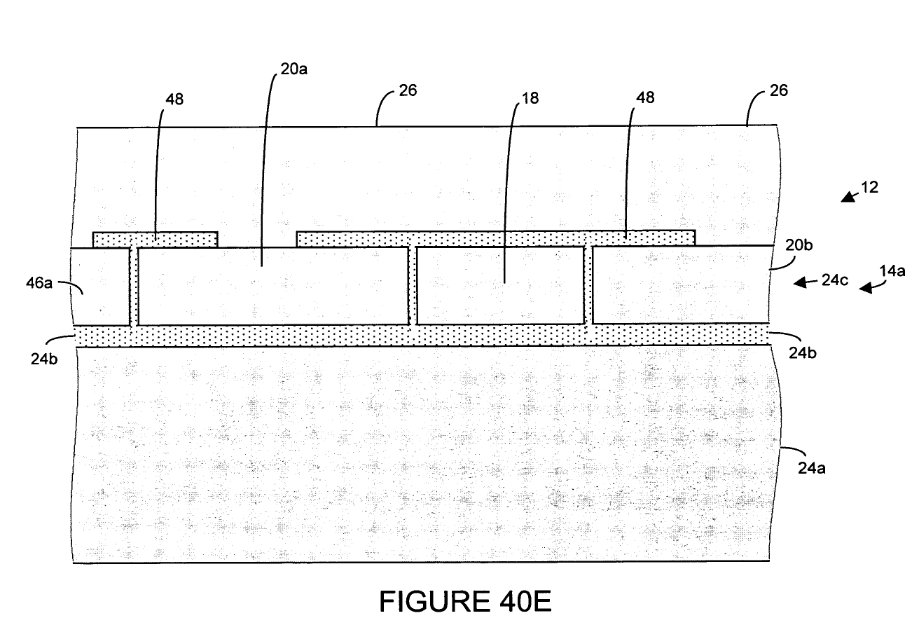

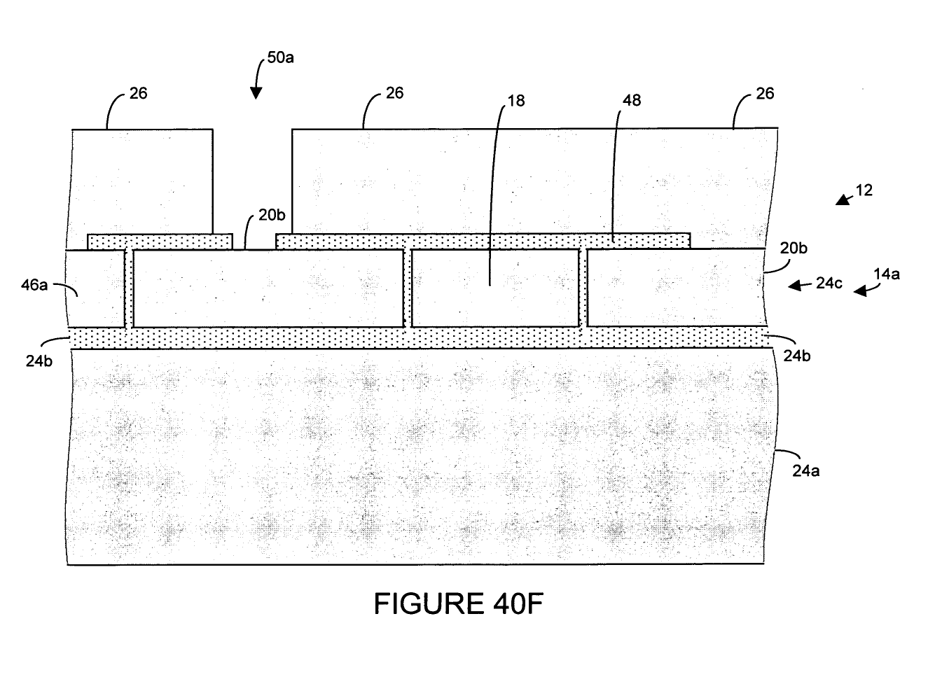

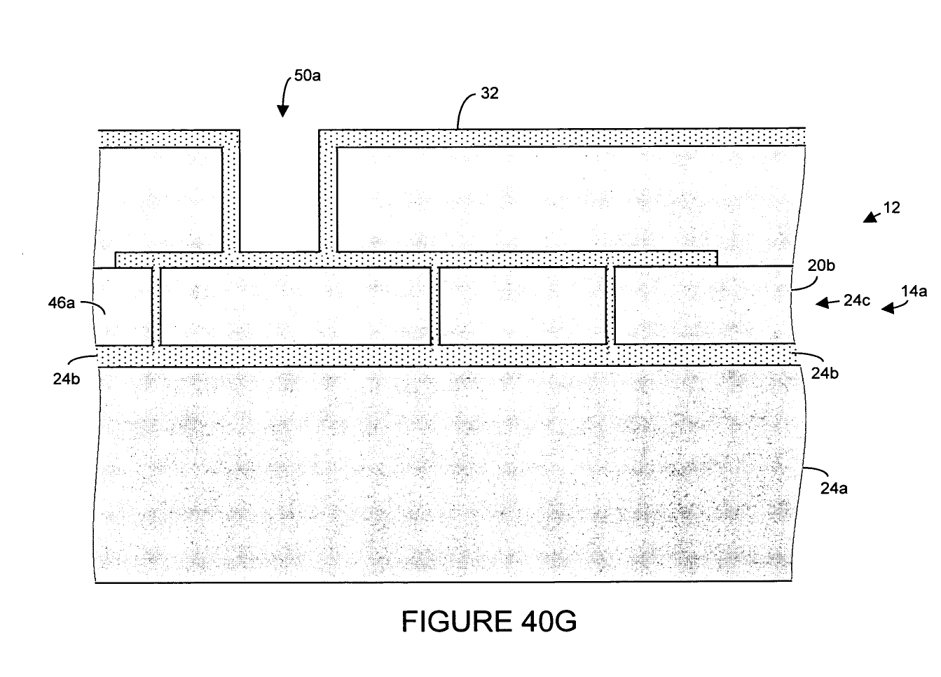

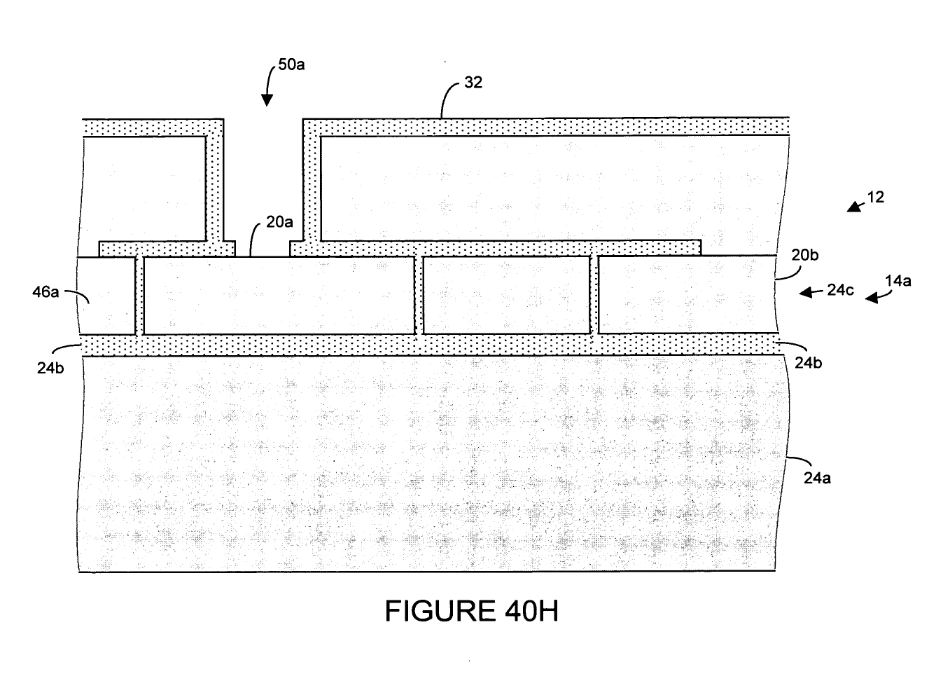

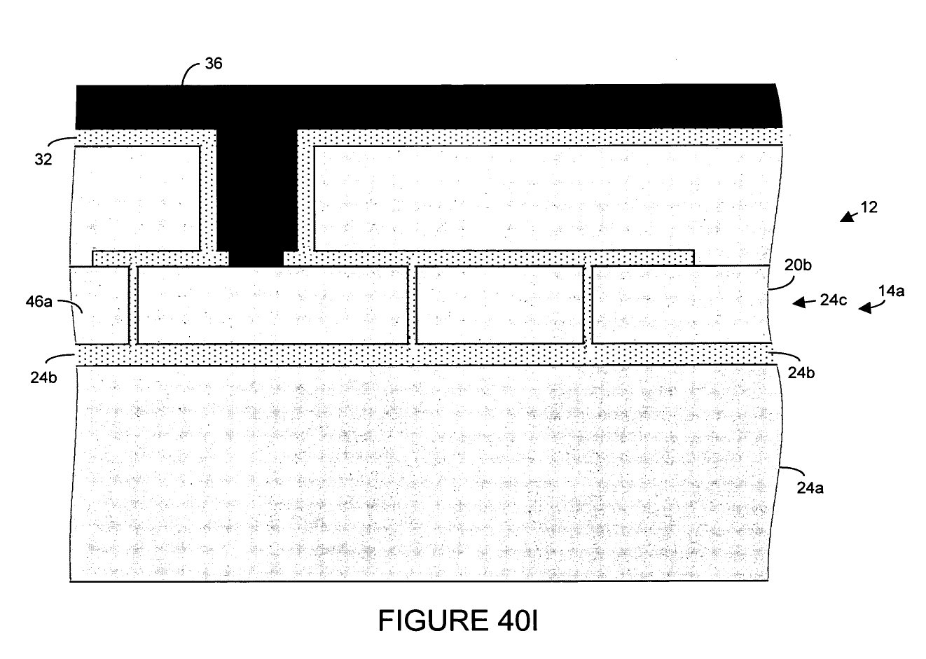

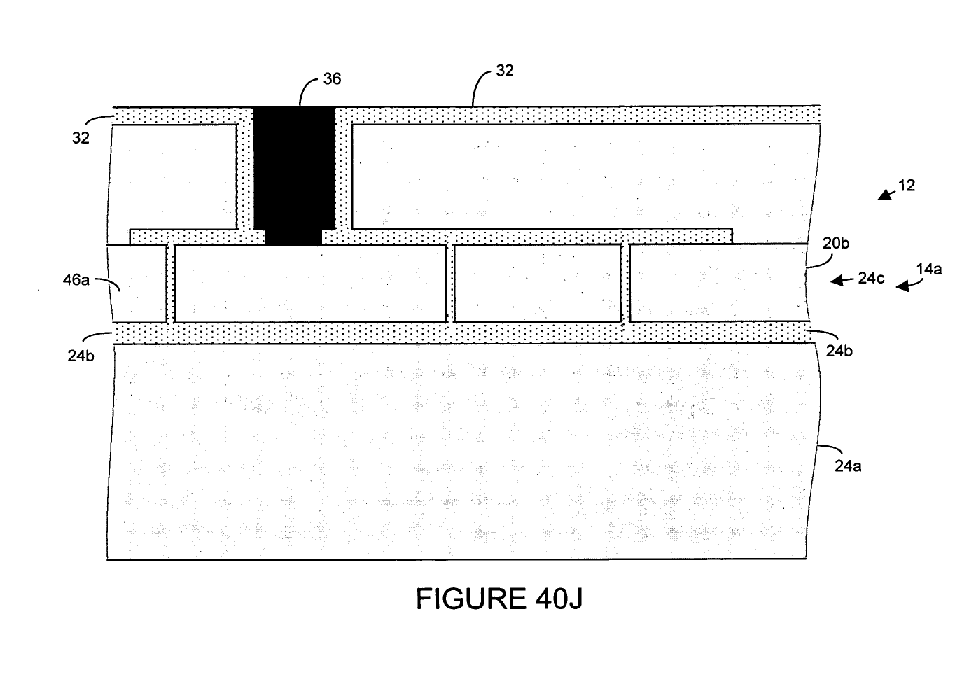

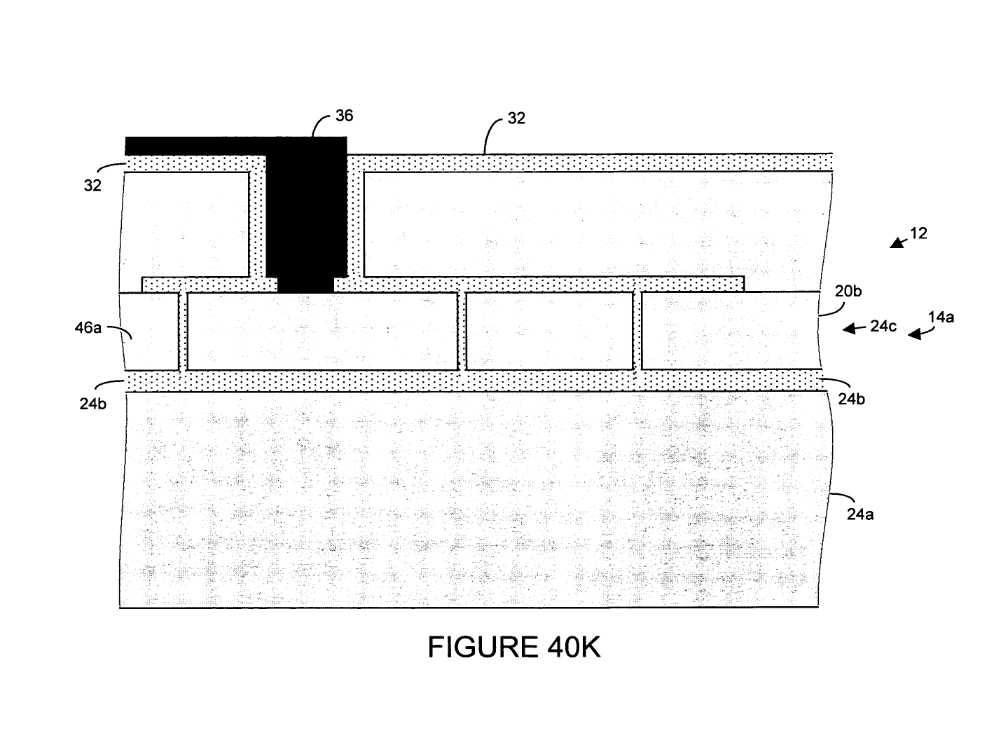

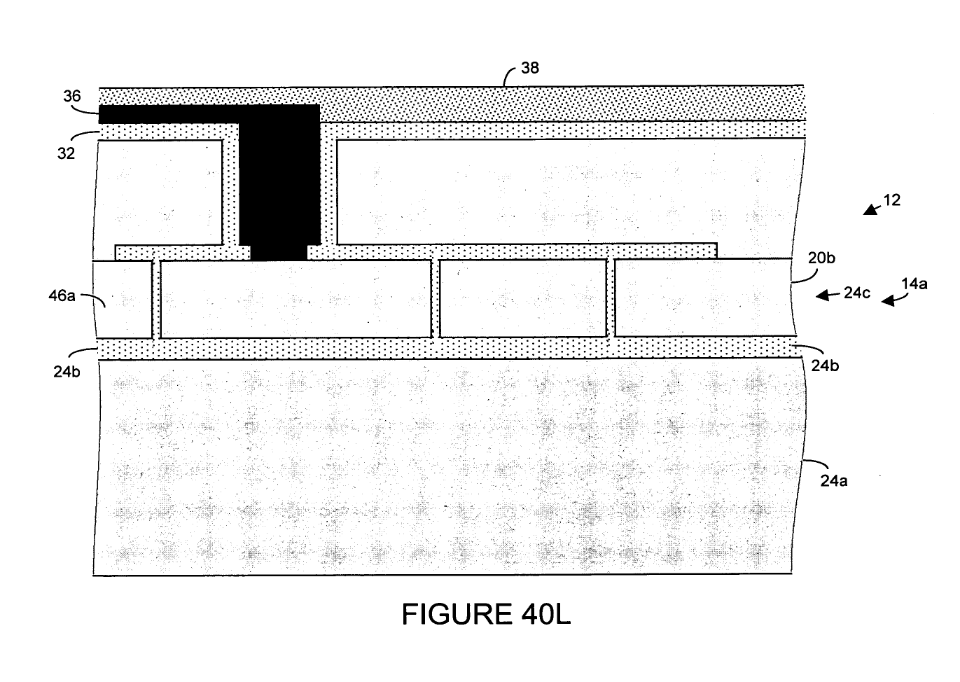

Indeed, the contact may be isolated with or without trenches and/or insulative material. For example, in the context of one exemplary embodiment, with reference to FIGS. 40A-40F, after certain processing (which was discussed in detail in connection with FIGS. 4A-4E), an opening 50a may be formed. Thereafter, an insulation material 32 (for example, a silicon nitride or silicon dioxide) may be deposited (see FIG. 40G) and, using selective etching (for example, focused reactive ion etching), a certain portion of material 32 overlying fixed electrode 20b may be removed while a significant and/or sufficient amount of insulation material 32 remains on the sidewalls of cover 26 within opening 50a (see FIG. 40H). A conductive layer 36 (for example, a metal or doped semiconductor material) may be deposited which provides electrical contact to fixed electrode 20b (see FIG. 40I), thereafter planarized (see FIG. 40J), and a conductive path deposited (see FIG. 40K). As described above, passivation layer 38 may thereafter be deposited. (See FIG. 40L).

Further, the processing flows described and illustrated herein are exemplary. These flows, and the order thereof, may be modified. All process flows, and orders thereof, to provide microelectromechanical system 10 and/or micromachined mechanical structure 12, whether now known or later developed, are intended to fall within the scope of the present inventions. (See, for example, FIGS. 38A-38E).

In addition, substrates 14a may be processed to a predetermined and/or suitable thickness before and/or after other processing during the fabrication of microelectromechanical system 10 and/or micromachined mechanical structure 12. For example, in one embodiment, first substrate 14a may be a relatively thick wafer which is ground (and polished) before or after substrate 14b is secured to a corresponding substrate (for example, bonded) and processed to form, for example, micromachined mechanical structure 12, before or after deposition, formation and/or growth of cover 26.

As mentioned above, where cover 26 is a substrate which is fixed, for example, via bonding, to substrate 14a (or material disposed thereon), all forms of bonding, whether now known or later developed, are intended to fall within the scope of the present invention. For example, bonding techniques such as fusion bonding, anodic-like bonding, silicon direct bonding, soldering (for example, eutectic soldering), thermo compression, thermo-sonic bonding, laser bonding and/or glass reflow bonding, and/or combinations thereof.

Further, as indicated above, the present inventions may be implemented in conjunction with any of the embodiments described and illustrated in U.S. Non-Provisional patent application Ser. No. 11/336,521, which was filed by Partridge et al. on Jan. 20, 2006 and entitled “Wafer Encapsulated Microelectromechanical Structure and Method of Manufacturing Same” (hereinafter “the Wafer Encapsulated Microelectromechanical Structure patent Application”). In this regard, the release and encapsulation techniques of the present inventions may be implemented in conjunction with any of the substrate bonding architectures, structures, processes and/or configurations described and illustrated in the Wafer Encapsulated Microelectromechanical Structure patent Application. The entire contents of the Wafer Encapsulated Microelectromechanical Structure patent Application, including, for example, the inventions, features, attributes, architectures, configurations, materials, techniques and advantages described and illustrated therein, are incorporated by reference herein. For the sake of brevity, those discussions will not be repeated; rather those discussions (text and illustrations), including the discussions relating to the process and/or structure, are incorporated by reference herein in its entirety.

Notably, any of the embodiments described and illustrated herein may employ a bonding material and/or a bonding facilitator material (disposed between substrates, for example, the second and third substrates) to, for example, enhance the attachment of or the “seal” between the substrates (for example, between the first and second substrates 14a and 14b, address/compensate for planarity considerations between substrates to be bonded (for example, compensate for differences in planarity between bonded substrates), and/or to reduce and/or minimize differences in thermal expansion (that is materials having different coefficients of thermal expansion) of the substrates and materials therebetween (if any). Such materials may be, for example, solder, metals, frit, adhesives, BPSG, PSG, or SOG, or combinations thereof.

Further, with respect to any of the embodiments described herein, circuitry 16 may be integrated in or on substrate 14, disposed in a separate substrate, and/or in one or more substrates that are connected to substrate 14a (for example, in one or more of the encapsulation wafer(s)). (See, for example, FIGS. 13, 17 and 24). In this regard, microelectromechanical device 10 may include micromachined mechanical structure 12 and circuitry 16 as a monolithic-like structure including mechanical structure 12 and circuitry 16 in one substrate.

The micromachined mechanical structure 12 and/or circuitry 16 may also reside on separate, discrete substrates. (See, for example, FIGS. 36 and 37A-37F). In this regard, in one embodiment, such separate discrete substrate may be bonded to or on substrate 14, before, during and/or after fabrication of micromachined mechanical structure 12 and/or circuitry 16.

It should be further noted that while the present inventions are described in the context of microelectromechanical systems including micromechanical structures or elements, the present inventions are not limited in this regard. Rather, the inventions described herein are applicable to other electromechanical systems including, for example, nanoelectromechanical systems. Thus, the present inventions are pertinent, as mentioned above, to electromechanical systems, for example, gyroscopes, resonators, temperatures sensors, accelerometers and/or other transducers.

Moreover, the present inventions are not limited to any particular design, layout and/or architecture of the micromechanical structure(s) and/or element(s) thereof. That is, the micromechanical structure(s) and/or element(s) thereof may employ any type of design, architecture and/or control, whether now known or later developed; and all such microelectromechanical designs, architectures and/or control techniques are intended to fall within the scope of the present inventions. The microelectromechanical structure may be one or more structures—whether or not physically, mechanically and/or electrically interconnected. Again, all designs, layouts, configurations, architectures and/or control techniques of the micromechanical structure(s) and/or element(s) thereof, whether now known or later developed, are intended to fall within the scope of the present inventions.

The term “depositing” and other forms (i.e., deposit, deposition and deposited) in the claims, means, among other things, depositing, creating, forming and/or growing a layer of material using, for example, a reactor (for example, an epitaxial, a sputtering or a CVD-based reactor (for example, APCVD, LPCVD, or PECVD)).

It should be further noted that the term “circuit” may mean, among other things, a single component or a multiplicity of components (whether in integrated circuit form or otherwise), which are active and/or passive, and which are coupled together to provide or perform a desired function. The term “circuitry” may mean, among other things, a circuit (whether integrated or otherwise), a group of such circuits, one or more processors, one or more state machines, one or more processors implementing software, or a combination of one or more circuits (whether integrated or otherwise), one or more state machines, one or more processors, and/or one or more processors implementing software.

The above embodiments of the present inventions are merely exemplary embodiments. They are not intended to be exhaustive or to limit the inventions to the precise forms, techniques, materials and/or configurations disclosed. Many modifications and variations are possible in light of the above teaching. It is to be understood that other embodiments may be utilized and operational changes may be made without departing from the scope of the present inventions. As such, the foregoing description of the exemplary embodiments of the inventions has been presented for the purposes of illustration and description. It is intended that the scope of the inventions not be limited to the description above.

1-45. (canceled)

46. A microelectromechanical device comprising:
a first substrate;
a chamber;
a micromachined mechanical structure partially disposed in the chamber;
a sacrificial layer disposed on top of or beneath the micromachined mechanical structure;
a cover disposed over both the micromachined mechanical structure and the first substrate, wherein a surface of the cover forms a wall of the chamber; and
one or more backside vents formed in the first substrate and providing access to at least a portion of the micromachined mechanical structure,
wherein the at least a portion of the micromachined mechanical structure is released by removing at least a portion of the sacrificial layer.

47. The microelectromechanical device of claim 46, wherein the micromachined mechanical structure is disposed over the first substrate or formed from at least a portion of the first substrate.

48. The microelectromechanical device of claim 46, further comprising a seal material disposed over or within the one or more backside vents to seal the chamber.

49. The microelectromechanical device of claim 48, wherein the seal material includes a plurality of layers.

50. The microelectromechanical device of claim 49, wherein at least two layers of the plurality of layers comprise different materials.

51. The microelectromechanical device of claim 48, further comprising a sealing layer screen over the first substrate that is:
disposed on the first substrate prior to releasing at least a portion of the micromachined mechanical structure and prior to disposing the seal material over or within the one or more backside vents; and
adapted to prevent the seal material from entering the chamber when the at least a portion of the micromachined mechanical structure is released.

52. The microelectromechanical device of claim 51, wherein the sealing layer screen includes a porous or amorphous material.

53. The microelectromechanical device of claim 51, wherein the sealing layer screen includes one or more vents having diameter smaller than a diameter of the one or more backside vents in the first substrate.

54. The microelectromechanical device of claim 51, wherein the micromachined mechanical structure is disposed directly over at least a portion of the sealing layer screen.

55. The microelectromechanical device of claim 48, further comprising a gas or vapor disposed in the chamber at a predetermined pressure.

56. The microelectromechanical device of claim 55, wherein the gas or vapor is adapted to provide predetermined reactions in the chamber.

57. The microelectromechanical device of claim 55, wherein the gas or vapor is adapted to provide predetermined characteristics to at least a portion of the micromachined mechanical structure notwithstanding subsequent processing steps applied to the microelectromechanical device.

58. The microelectromechanical device of claim 57, wherein the gas or vapor provides an anti-stiction characteristic to the at least a portion of the micromachined mechanical structure.

59. The microelectromechanical device of claim 46, wherein the cover comprises a second substrate that is physically bonded to the first substrate.

60. The microelectromechanical device of claim 59, wherein the cover is bonded using fusion bonding, anodic-like bonding, silicon direct bonding, soldering, thermo compression, thermo-sonic, laser bonding, or glass reflow.

61. The microelectromechanical device of claim 46, further comprising electronic circuitry in or on the cover.

62. The microelectromechanical device of claim 46, further comprising electronic circuitry in or on the first substrate.

63. The microelectromechanical device of claim 46, further comprising a contact in the first substrate to electrically couple the first substrate to a fixed electrode of the micromachined mechanical structure.

64. The microelectromechanical device of claim 63, further comprising a trench that includes insulative material formed in the first substrate and around at least a portion of the contact.

65. The microelectromechanical device of claim 46, further comprising a contact in the cover to electrically couple the cover to a fixed electrode of the micromachined mechanical structure.

66. The microelectromechanical device of claim 65, further comprising a trench that includes insulative material formed in the cover and around at least a portion of the contact.

67. The microelectromechanical device of claim 46, wherein the thickness of the first substrate is reduced.

68. The microelectromechanical device of claim 46, further comprising a die attach material disposed over or within the one or more backside vents to seal the chamber.

69. The microelectromechanical device of claim 68, wherein the die attach material comprises a solder, a bonding material, a glue, or an adhesive material to attach the first substrate to a package.

70. The microelectromechanical device of claim 46, further comprising:
a gas or vapor disposed in the chamber at a predetermined pressure and adapted to provide either predetermined reactions in the chamber or predetermined characteristics to the at least a portion of the micromachined mechanical structure notwithstanding subsequent processing steps applied to the microelectromechanical device;
a seal material disposed over or within the one or more backside vents to seal the chamber; and
a sealing layer screen over the first substrate that is:
disposed on the first substrate prior to releasing at least a portion of the micromachined mechanical structure and prior to disposing the seal material over or within the one or more backside vents, and
adapted to prevent the seal material from entering the chamber when the at least a portion of the micromachined mechanical structure is released.

71. A method for manufacturing a microelectromechanical device, the method comprising:
forming a micromachined mechanical structure on top of a substrate;
providing a top sacrificial layer over the micromachined mechanical structure;
providing a cover over the top sacrificial layer;
forming one or more backside vents in the substrate; and
removing the top sacrificial layer through the one or more backside vents to release at least a portion of the micromachined mechanical structure, thereby forming a chamber, wherein a surface of the cover forms a wall of the chamber and at least a portion of the micromachined mechanical structure is disposed in the chamber.

72. The method of claim 71, wherein the micromachined mechanical structure is disposed over the substrate or formed from at least a portion of the substrate.

73. The method of claim 71, further comprising the step of applying a seal material over or within the one or more backside vents to seal the chamber.

74. The method of claim 73, wherein applying the seal material includes applying a plurality of layers.

75. The method of claim 73, further comprising the step of forming a sealing layer screen over the substrate prior to releasing the at least a portion of the micromachined mechanical structure and prior to applying the seal material over or within the one or more backside vents, wherein the sealing layer screen is adapted to prevent the seal material from entering the chamber when the at least a portion of the micromachined mechanical structure is released.

76. The method of claim 75, wherein the sealing layer screen includes a porous or amorphous material.

77. The method of claim 75, wherein the sealing layer screen includes one or more vents having a diameter smaller than a diameter of the one or more backside vents formed in the substrate.

78. The method of claim 73, further comprising the step of disposing a gas or vapor in the chamber at a predetermined pressure.

79. The method of claim 78, wherein the gas or vapor is adapted to provide predetermined reactions in the chamber.

80. The method of claim 78, wherein the gas or vapor is adapted to provide predetermined characteristics to at least a portion of the micromachined mechanical structure notwithstanding subsequent processing steps applied to the microelectromechanical device.

81. The method of claim 80, wherein the gas or vapor provides an anti-stiction characteristic to the at least a portion of the micromachined mechanical structure.

82. The method of claim 78, wherein the predetermined pressure of the gas or vapor is achieved by annealing the microelectromechanical device.

83. The method of claim 71, further comprising the step of forming electronic circuitry in or on the cover.

84. The method of claim 71, further comprising the step of forming electronic circuitry in or on the substrate.

85. The method of claim 71, further comprising the step of forming a contact in the substrate to electrically couple the substrate to a fixed electrode of the micromachined mechanical structure.

86. The method of claim 85, further comprising the step of forming a trench that includes an insulative material in the substrate and around at least a portion of the contact.

87. The method of claim 71, further comprising the step of forming a contact in the cover to electrically couple the substrate to a fixed electrode of the micromachined mechanical structure.

88. The method of claim 87, further comprising the step of forming a trench that includes an insulative material in the cover and around at least a portion of the contact.

89. The method of claim 71, further comprising the step of reducing the thickness of the substrate.

90. The method of claim 71, further comprising the step of applying a die attach material over or within the one or more backside vents to seal the chamber.

91. The method of claim 90, wherein the die attach material comprises a solder, a bonding material, a glue, or an adhesive material to attach the substrate to a package.

92. The method of claim 71, wherein the cover comprises tensile material.

93. The method of claim 71, wherein the cover comprises a second substrate physically bonded to the top sacrificial layer.

94. The method of claim 93, wherein the cover is bonded using fusion bonding, anodic-like bonding, silicon direct bonding, soldering, thermo compression, thermo-sonic, laser bonding, or glass reflow.

95. The method of claim 93, further comprising the step of forming a second micromachined mechanical structure in the cover prior to physically bonding the cover to the top sacrificial layer.

96. A method for manufacturing a microelectromechanical device, the method comprising:
providing a base sacrificial layer on a substrate;
providing a semiconductor layer on the base sacrificial layer;
forming a micromachined mechanical structure from at least a portion of the semiconductor layer;
providing a cover over the micromachined mechanical structure;
forming one or more backside vents in the substrate; and
removing the base sacrificial layer through the one or more backside vents to release at least a portion of the micromachined mechanical structure, thereby forming a chamber, wherein at least a portion of the micromachined mechanical structure is disposed in the chamber.

97. The method of claim 96, further comprising the step of applying a seal material over or within the one or more backside vents to seal the chamber.

98. The method of claim 97, wherein applying the seal material includes applying a plurality of layers.

99. The method of claim 97, further comprising the step of forming a sealing layer screen over the substrate prior to releasing the at least a portion of the micromachined mechanical structure and prior to applying the seal material over or within the one or more backside vents, wherein the sealing layer screen is adapted to prevent the seal material from entering the chamber when the at least a portion of the micromachined mechanical structure is released.

100. The method of claim 99, wherein the sealing layer screen includes a porous or amorphous material.

101. The method of claim 99, wherein the sealing layer screen includes one or more vents having a diameter smaller than a diameter of the one or more backside vents formed in the substrate.

102. The method of claim 97, further comprising the step of disposing a gas or vapor in the chamber at a predetermined pressure.

103. The method of claim 102, wherein the gas or vapor is adapted to provide predetermined reactions in the chamber.

104. The method of claim 102, wherein the gas or vapor is adapted to provide predetermined characteristics to at least a portion of the micromachined mechanical structure notwithstanding subsequent processing steps applied to the microelectromechanical device.

105. The method of claim 104, wherein the gas or vapor provides an anti-stiction characteristic to the at least a portion of the micromachined mechanical structure.

106. The method of claim 102, wherein the predetermined pressure of the gas or vapor is achieved by annealing the microelectromechanical device.

107. The method of claim 96, further comprising the step of forming electronic circuitry in or on the cover.

108. The method of claim 96, further comprising the step of forming electronic circuitry in or on the substrate.

109. The method of claim 96, further comprising the step of forming a contact in the substrate to electrically couple the substrate to a fixed electrode of the micromachined mechanical structure.

110. The method of claim 109, further comprising the step of forming a trench that includes an insulative material in the substrate and around at least a portion of the contact.

111. The method of claim 96, further comprising the step of forming a contact in the cover to electrically couple the substrate to a fixed electrode of the micromachined mechanical structure.

112. The method of claim 111, further comprising the step of forming a trench that includes an insulative material in the cover and around at least a portion of the contact.

113. The method of claim 96, further comprising the step of reducing the thickness of the substrate.

114. The method of claim 96, further comprising the step of applying a die attach material over or within the one or more backside vents to seal the chamber.

115. The method of claim 114, wherein the die attach material comprises a solder, a bonding material, a glue, or an adhesive material to attach the substrate to a package.

116. The method of claim 96, wherein the cover comprises tensile material.

117. The method of claim 96, wherein the cover comprises a second substrate physically bonded to the micromachined mechanical structure.

118. The method of claim 117, wherein the cover is bonded using fusion bonding, anodic-like bonding, silicon direct bonding, soldering, thermo compression, thermo-sonic, laser bonding, or glass reflow.

119. The method of claim 117, further comprising the step of forming a second micromachined mechanical structure in the cover prior to physically bonding the cover to the micromachined mechanical structure.

120. The method of claim 96, further comprising the steps of:
providing a top sacrificial layer over the micromachined mechanical structure prior to providing the cover over the micromachined mechanical structure;
removing the top sacrificial layer through the one or more backside vents to release at least a portion of the micromachined mechanical structure, wherein a surface of the cover forms a wall of the chamber;
disposing a gas or vapor in the chamber at a predetermined pressure and adapted to provide either predetermined reactions in the chamber or predetermined characteristics to at least a portion of the micromachined mechanical structure notwithstanding subsequent processing steps applied to the microelectromechanical device;
applying a seal material over or within the one or more backside vents to seal the chamber; and
forming a sealing layer screen over the substrate prior to releasing at least a portion of the micromachined mechanical structure and prior to applying the seal material over or within the one or more backside vents, wherein the sealing layer screen is adapted to prevent the seal material from entering the chamber when the at least a portion of the micromachined mechanical structure is released.
